(19) United States
(12) Patent Application Publication
(10) Pub. No.: US 2020/0119199 A1
(43) Pub. Date: Apr. 16, 2020

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Naoki OKUNO, Yamato (JP); Yuta ENDO, Atsugi (JP); Yuki IMOTO, Sagamihara (JP)

(21) Appl. No.: 16/609,925

(22) PCT Filed: May 15, 2018
(86) PCT No.: PCT/IB2018/053366

§ 371 Date: Oct. 31, 2019

(30) Foreign Application Priority Data
May 26, 2017 (JP) 2017-104378
Feb. 22, 2018 (JP) 2018-029399

(51) Int. Cl. H01L 29/786; H01L 29/66; H01L 21/02; H01L 21/477

(52) U.S. Cl. CPC H01L 29/7869; H01L 21/477; H01L 21/02631; H01L 29/66969

(57) ABSTRACT

A semiconductor device having favorable characteristics is provided.

In a semiconductor device including a transistor, the transistor includes a first oxide, a second oxide over the first oxide, an insulator over the second oxide, and a conductor over the insulator. The first oxide includes a channel formation region and a first region and a second region positioned so that the channel formation region is sandwiched therebetween. The second oxide is provided so as to be in contact with the channel formation region, part of the first region, and part of the second region. The first region and the second region have lower concentrations of oxygen than the channel formation region.

### TECHNICAL FIELD

One embodiment of the present invention relates to a semiconductor device and a method for manufacturing the semiconductor device. Another embodiment of the present invention relates to a semiconductor wafer, a module, and an electronic device.

In this specification and the like, a semiconductor device generally means a device that can function by utilizing semiconductor characteristics. As well as a semiconductor element such as a transistor, a semiconductor circuit, an arithmetic device, and a memory device are each an embodiment of a semiconductor device. In some cases, it can be said that a display device (e.g., a liquid crystal display device and a light-emitting display device), a projection device, a lighting device, an electro-optical device, a power storage device, a memory device, a semiconductor circuit, an imaging device, an electronic device, and the like each include a semiconductor device.

Note that one embodiment of the present invention is not limited to the above technical field. One embodiment of the invention disclosed in this specification and the like relates to an object, a method, or a manufacturing method. Alternatively, one embodiment of the present invention relates to a process, a machine, manufacture, or a composition of matter.

### BACKGROUND ART

In recent years, semiconductor devices have been developed and an LSI, a CPU, or a memory are mainly used. A CPU is an aggregation of semiconductor elements in which an electrode which is a connection terminal is formed, which includes a semiconductor integrated circuit (at least a transistor and a memory) separated from a semiconductor wafer.

A semiconductor circuit (an IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is applied to a wide range of electronic devices such as an integrated circuit (IC) or an image display device (also simply referred to as a display device). A silicon-based semiconductor material is widely known as a semiconductor thin film applicable to the transistor; in addition, an oxide semiconductor has been attracting attention as another material.

It is known that a transistor using an oxide semiconductor has an extremely low leakage current in a non-conduction state. For example, a low-power-consumption CPU or the like utilizing a characteristic of low leakage current of the transistor using an oxide semiconductor has been disclosed (see Patent Document 1).

A self-aligned transistor has been proposed as the transistor using an oxide semiconductor. A method in which, for the self-aligned transistor, a metal film is formed over a source region and a drain region and heat treatment is performed on the metal film so that the resistance of the metal film is increased and the resistance of the source region and the drain region is reduced is disclosed (see Patent Document 2).

In recent years, demand for an integrated circuit in which transistors and the like are integrated with high density has risen with reductions in the size and weight of an electronic device. In addition, improvement in the productivity of a semiconductor device including an integrated circuit is required.

### REFERENCE

### Patent Document

[Patent Document 1] Japanese Published Patent Application No. 2012-257187

[Patent Document 2] Japanese Published Patent Application No. 2011-228622

### SUMMARY OF THE INVENTION

### Problems to be Solved by the Invention

In Patent Document 2, to reduce the resistance of the source region and the drain region, the metal film is formed over the source region and the drain region and heat treatment is performed on the metal film in an oxygen atmosphere. By the heat treatment, a constituent element of the metal film enters the source region and the drain region of an oxide semiconductor film as a dopant, whereby the resistance of the source region and the drain region is reduced. The heat treatment in an oxygen atmosphere causes oxidization of a conductive film, whereby the resistance of the conductive film is increased. However, since the heat treatment is performed in an oxygen atmosphere, the metal film has a low effect of extracting oxygen from the oxide semiconductor film.

Patent Document 2 discloses the concentration of oxygen in a channel formation region, and does not refer to the concentration of impurities such as water or hydrogen. That is, purification of the channel formation region (reduction in impurities such as water or hydrogen, typically, dehydration or dehydrogenation) is not performed; thus, there is a problem in that a transistor tends to have normally-on characteristics. Note that normally-on characteristics of a transistor means a state where a channel exists and current flows through a transistor even when no voltage is applied to a gate. In contrast, normally-off characteristics of a transistor means a state where current does not flow through a transistor without application of voltage to a gate.

In view of the above problems, an object of one embodiment of the present invention is to provide a semiconductor device having favorable electrical characteristics by stably reducing the resistance of a source region and a drain region of a transistor and increasing the purity of a channel formation region.

Another object of one embodiment of the present invention is to provide a semiconductor device that can be miniaturized or highly integrated. An object of one embodiment of the present invention is to provide a semiconductor device having favorable electrical characteristics. An object of one embodiment of the present invention is to provide a semiconductor device with high productivity.

An object of one embodiment of the present invention is to provide a semiconductor device capable of retaining data for a long time. An object of one embodiment of the present invention is to provide a semiconductor device capable of high-speed data writing. An object of one embodiment of the present invention is to provide a semiconductor device with high design flexibility. An object of one embodiment of the present invention is to provide a semiconductor device in which power consumption can be reduced. An object of one embodiment of the present invention is to provide a novel semiconductor device.

Note that the description of these objects do not disturb the existence of other objects. Note that one embodiment of the present invention does not need to achieve all the objects. Other objects will be apparent from and can be derived from the description of the specification, the drawings, the claims, and the like.

One embodiment of the present invention is a semiconductor device including a transistor, which includes a first oxide, a second oxide over the first oxide, an insulator over the second oxide, and a conductor over the insulator. The first oxide includes a channel formation region and a first region and a second region positioned so that the channel formation region is sandwiched therebetween. The second oxide is provided so as to be in contact with the channel formation region, part of the first region, and part of the second region. The first region and the second region have lower concentrations of oxygen than the channel formation region.

In addition, one embodiment of the present invention is a semiconductor device including a transistor, a first insulator covering the transistor, and a first conductor and a second conductor electrically connected to the transistor, and the transistor includes a first oxide, a first layer and a second layer containing a metal element and oxygen over the first oxide, a second oxide over the first oxide, the first layer, and the second layer, a second insulator over the second oxide, and a third conductor over the second insulator. The first oxide includes a channel formation region and a first region and a second region positioned so that the channel formation region is sandwiched therebetween. The first region is provided so as to be in contact with the first layer. The second region is provided so as to be in contact with the second layer. The second oxide is provided so as to be in contact with the channel formation region, part of the first layer, and part of the second layer. The first insulator and the first layer include a first opening exposing the first region. The first conductor is provided in the first opening and electrically connected to the first region. The first insulator and the second layer include a second opening exposing the second region. The second conductor is provided in the second opening and electrically connected to the second region. The first region and the second region have lower concentrations of oxygen than the channel formation region.

In the above, the first oxide preferably includes In, an element M (M is Al, Ga, Y, or Sn), and Zn.

In the above, in the first oxide, the proportion of the number of atoms of In is preferably higher than that of the element M in an atomic ratio.

In the above, the first region and the second region may each contain at least one of aluminum, ruthenium, titanium, tantalum, chromium, and tungsten.

In the above, the first region and the second region may each further contain nitrogen.

In the above, the channel formation region preferably has a lower concentration of hydrogen than the first region and the second region.

In the above, the transistor is preferably a normally-off transistor.

In the above, the metal element preferably contains at least one of aluminum, ruthenium, titanium, tantalum, chromium, and tungsten.

In the above, the first layer and the second layer may each further contain nitrogen.

In the above, the film thicknesses of the first layer and the second layer are each preferably greater than or equal to 0.5 nm and less than 5 nm.

Moreover, one embodiment of the present invention is a method for manufacturing a semiconductor device in which a first layer containing a metal element is formed over a first oxide; the first oxide is processed into an island shape using the first layer as a mask; the first layer over the first oxide which is processed into an island shape is processed to expose a first region of the first oxide and form a second layer over a second region of the oxide and a third layer over a third region of the oxide; first heat treatment is performed at least on the first oxide, the second layer, and the third layer in an atmosphere containing nitrogen to extract oxygen contained in the second region to the second layer and extract oxygen contained in the third region to the third layer; a second oxide is formed over the first oxide; an insulator is formed over the second oxide; and a conductor is formed over the insulator.

In the above, the first layer is preferably formed by a sputtering method, using one or both of argon and nitrogen.

In the above, the first layer and the second layer may be removed after the first heat treatment.

In the above, second heat treatment may be further performed after the first heat treatment.

According to one embodiment of the present invention, it is possible to provide a semiconductor device having favorable electrical characteristics by stably reducing the resistance of a source region and a drain region of a transistor and increasing the purity of a channel formation region.

Alternatively, according to one embodiment of the present invention, it is possible to provide a semiconductor device that can be miniaturized or highly integrated. According to one embodiment of the present invention, it is possible to provide a semiconductor device having favorable electrical characteristics. According to one embodiment of the present invention, it is possible to provide a semiconductor device with high productivity.

According to one embodiment of the present invention, it is possible to provide a semiconductor device capable of retaining data for a long time. According to one embodiment of the present invention, it is possible to provide a semiconductor device capable of high-speed data writing. According to one embodiment of the present invention, it is possible to provide a semiconductor device with high design flexibility. According to one embodiment of the present invention, it is possible to provide a semiconductor device in which power consumption can be reduced. According to one embodiment of the present invention, it is possible to provide a novel semiconductor device.

Note that the description of these effects do not disturb the existence of other effects. Note that one embodiment of the present invention does not necessarily achieve all the effects. Other effects will be apparent from and can be derived from the description of the specification, the drawings, the claims, and the like.

### BRIEF DESCRIPTION OF THE DRAWINGS

FIG. 1 A top view and cross-sectional views illustrating a structure of a transistor of one embodiment of the present invention.

FIG. 2 A top view and cross-sectional views illustrating a structure of a transistor of one embodiment of the present invention.

FIG. 3 Cross-sectional views illustrating structures of transistors of one embodiment of the present invention.

FIG. 4 A top view and cross-sectional views illustrating a method for manufacturing a transistor of one embodiment of the present invention.

FIG. 5 A top view and cross-sectional views illustrating a method for manufacturing a transistor of one embodiment of the present invention.

FIG. 6 A top view and cross-sectional views illustrating a method for manufacturing a transistor of one embodiment of the present invention.

FIG. 7 A top view and cross-sectional views illustrating a method for manufacturing a transistor of one embodiment of the present invention.

FIG. 8 A top view and cross-sectional views illustrating a method for manufacturing a transistor of one embodiment of the present invention.

FIG. 9 A top view and cross-sectional views illustrating a method for manufacturing a transistor of one embodiment of the present invention.

FIG. 10 Atop view and cross-sectional views illustrating a method for manufacturing a transistor of one embodiment of the present invention.

FIG. 11 Atop view and cross-sectional views illustrating a method for manufacturing a transistor of one embodiment of the present invention.

FIG. 12 Atop view and cross-sectional views illustrating a method for manufacturing a transistor of one embodiment of the present invention.

FIG. 13 Atop view and cross-sectional views illustrating a method for manufacturing a transistor of one embodiment of the present invention.

FIG. 14 Cross-sectional views illustrating a structure of a memory device of one embodiment of the present invention.

FIG. 15 A cross-sectional view illustrating a structure of a memory device of one embodiment of the present invention.

FIG. 16 A circuit diagram and a cross-sectional view of a memory device of one embodiment of the present invention.

FIG. 17 A cross-sectional view illustrating a structure of a memory device of one embodiment of the present invention.

FIG. 18 A cross-sectional view illustrating a structure of a memory device of one embodiment of the present invention.

FIG. 19 A circuit diagram showing a configuration example of an inverter circuit and a timing chart showing an operation example thereof.

FIG. 20 A block diagram showing a configuration example of a memory device of one embodiment of the present invention.

FIG. 21 Circuit diagrams each showing a configuration example of a memory device of one embodiment of the present invention.

FIG. 22 A circuit diagram showing a configuration example of a memory device of one embodiment of the present invention.

FIG. 23 A block diagram showing a configuration example of a memory device of one embodiment of the present invention.

FIG. 24 A block diagram and a circuit diagram showing a configuration example of a memory device of one embodiment of the present invention.

FIG. 25 A block diagram showing a configuration example of a semiconductor device of one embodiment of the present invention.

FIG. 26 A block diagram and a circuit diagram showing a configuration example of a semiconductor device of one embodiment of the present invention, and a timing chart showing an operation example of the semiconductor device.

FIG. 27 A block diagram showing a configuration example of a semiconductor device of one embodiment of the present invention.

FIG. 28 A circuit diagram showing a configuration example of a semiconductor device of one embodiment of the present invention and a timing chart showing an operation example of the semiconductor device.

FIG. 29 A block diagram showing a configuration example of an AI system of one embodiment of the present invention.

FIG. 30 Block diagrams showing application examples of an AI system of one embodiment of the present invention.

FIG. 31 A schematic perspective view showing a configuration example of an IC incorporating an AI system of one embodiment of the present invention.

FIG. 32 A diagram illustrating an electronic device of one embodiment of the present invention and a block diagram showing a structure example of the electronic device.

FIG. 33 Diagrams illustrating an electronic device of one embodiment of the present invention.

FIG. 34 A graph showing sheet resistance of samples in Example.

FIG. 35 Views showing cross-sectional STEM images of samples in Example.

### MODE FOR CARRYING OUT THE INVENTION

Hereinafter, embodiments will be described with reference to drawings. Note that the embodiments can be implemented with many different modes, and it will be readily appreciated by those skilled in the art that modes and details can be changed in various ways without departing from the spirit and scope. Thus, the present invention should not be interpreted as being limited to the following description of the embodiments.

In the drawings, size, layer thickness, or a region is exaggerated for clarity in some cases. Therefore, the size, the layer thickness, or the region is not limited to the illustrated scale. Note that the drawings are schematic views illustrating ideal examples, and the present invention is not limited to shapes, values, or the like shown in the drawings. In the drawings, the same portions or portions having similar functions are denoted by the same reference numerals in different drawings, and explanation thereof will not be repeated. Furthermore, the same hatching pattern is applied to portions having similar functions, and the portions are not denoted by reference numerals in some cases.

Note that the ordinal numbers such as first, second, and the like in this specification and the like are used for convenience and do not denote the order of steps or the stacking order of layers. Therefore, for example, “first” can be replaced with “second”, “third”, or the like as appropriate for description. In addition, the ordinal numbers used in this specification and the like are, in some cases, not the same as the ordinal numbers which specify one embodiment of the present invention.

In this specification, terms for describing arrangement, such as “over” and “under”, are used for convenience in describing a positional relation between components with reference to drawings. The positional relation between components is changed as appropriate according to a direction in which each component is described. Thus, description can be rephrased appropriately according to the situation, without being limited by the terms used in the specification.

In this specification and the like, a transistor is an element having at least three terminals of a gate, a drain, and a source. A channel formation region is included between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when a transistor of opposite polarity is employed or when a direction of current is changed in circuit operation, for example. Therefore, the terms of source and drain can be used interchangeably in this specification and the like.

Note that a channel length refers to, for example, the distance between a source (a source region or a source electrode) and a drain (a drain region or a drain electrode) in a region where a semiconductor (or a portion where current flows in a semiconductor when a transistor is in an on state) and a gate electrode overlap with each other or a region where a channel is formed in a top view of the transistor. Note that in one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

A channel width refers to, for example, the length of a portion where a source and a drain face each other in a region where a semiconductor (or a portion where current flows in a semiconductor when a transistor is in an on state) and a gate electrode overlap with each other or a region where a channel is formed. Note that in one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter, also referred to as an “effective channel width”) is different from a channel width shown in a top view of a transistor (hereinafter, also referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is large in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

Thus, in this specification, an apparent channel width is referred to as a “surrounded channel width (SCW)” in some cases. Furthermore, in this specification, the simple term of channel width refers to a surrounded channel width or an apparent channel width in some cases. Alternatively, in this specification, the simple term of channel width refers to an effective channel width in some cases. Note that values of a channel length, a channel width, an effective channel width, an apparent channel width, a surrounded channel width, and the like can be determined, for example, by analyzing a cross-sectional TEM image or the like.

Note that in the case where field-effect mobility, a current value per channel width, and the like of a transistor are obtained by calculation, the calculation is performed using a surrounded channel width in some cases. In that case, a value different from one calculated using an effective channel width is obtained in some cases.

In this specification and the like, “electrically connected” includes the case where connection is made through an “object having any electric function”. Here, there is no particular limitation on the “object having any electric function” as long as electric signals can be transmitted and received between the connected components. Examples of the “object having any electric function” include a switching element such as a transistor, a resistor, an inductor, a capacitor, and other elements with a variety of functions as well as an electrode and a wiring.

Note that in this specification and the like, a nitride oxide refers to a compound that contains more nitrogen than oxygen. Furthermore, an oxynitride refers to a compound that contains more oxygen than nitrogen. Note that the content of each element can be measured by Rutherford Backscattering Spectrometry (RBS), for example.

In this specification and the like, the term “film” and the term “layer” can be interchanged with each other. For example, the term “conductive layer” can be changed into the term “conductive film” in some cases. For another example, the term “insulating film” can be changed into the term “insulating layer” in some cases.

In this specification and the like, “parallel” indicates a state where two straight lines are placed at an angle of greater than or equal to −10° and less than or equal to 10°. Thus, the case where the angle is greater than or equal to −5° and less than or equal to 5° is also included. In addition, “substantially parallel” indicates a state where two straight lines are placed at an angle of greater than or equal to −30° and less than or equal to 30°. Moreover, “perpendicular” indicates a state where two straight lines are placed at an angle of greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle of greater than or equal to 60° and less than or equal to 120°.

In this specification, in the case where a crystal is a trigonal crystal or a rhombohedral crystal, the crystal is regarded as a hexagonal crystal system.

Note that in this specification, a barrier layer refers to a film having a function of suppressing the penetration of oxygen and impurities such as hydrogen; in the case where the barrier layer has conductivity, it is referred to as a conductive barrier layer in some cases.

In this specification and the like, a transistor having normally-on characteristics is a transistor that is on when no potential (0 V) is applied by a power source. For example, the normally-on characteristics of a transistor mean, in some cases, electrical characteristics in which the threshold voltage of the transistor becomes negative when a voltage applied to a gate of the transistor (V_{g}) is 0 V.

In this specification and the like, a metal oxide means an oxide of a metal in a broad expression. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in the case where an OS FET is stated, it can also be referred to as a transistor including a metal oxide or an oxide semiconductor.

In this specification and the like, the term of normally off means that current per micrometer of channel width flowing through a transistor when no voltage is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

### Embodiment 1

### <Structure of Transistor>

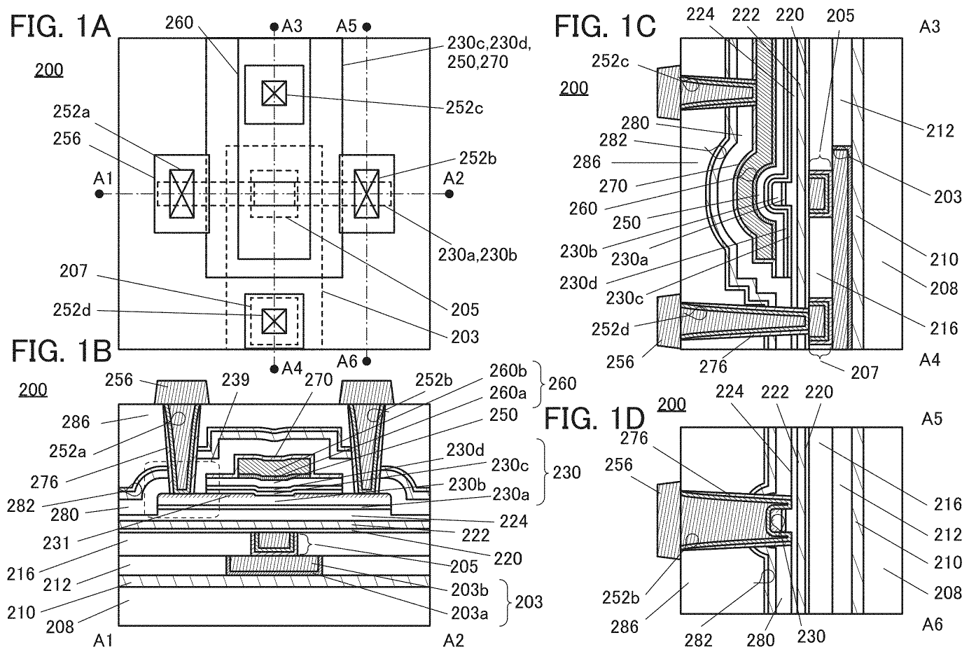

FIG. 1(A) is a top view of a transistor of one embodiment of the present invention. FIG. 1(B) is a cross-sectional view of a portion indicated by a dashed-dotted line A1-A2 in FIG. 1(A), i.e. a cross-sectional view of the transistor in the channel length direction. FIG. 1(C) is a cross-sectional view of a portion indicated by a dashed-dotted line A3-A4 in FIG. 1(A), i.e. a cross-sectional view of a channel formation region of the transistor in the channel width direction. FIG. 1(D) is a cross-sectional view of a portion indicated by a dashed-dotted line A5-A6 in FIG. 1(A), i.e. a cross-sectional view of a source region or a drain region of the transistor in the channel width direction. For clarity of the drawing, some components are not illustrated in the top view of FIG. 1(A). Note that the channel length direction of a transistor means the direction in which carriers move between a source (source region or source electrode) and a drain (drain region or drain electrode) in a plane parallel to a substrate, and the channel width direction means the direction perpendicular to the channel length direction in the plane parallel to a substrate.

A semiconductor device of one embodiment of the present invention includes a transistor 200; an insulator 280, an insulator 282 (an insulator 282a and an insulator 282b), and an insulator 286 functioning as interlayer films; a barrier layer 276 covering each side surface of an opening provided in the insulator 280 and the insulator 282; a conductor 252 (a conductor 252a, a conductor 252b, a conductor 252c, and a conductor 252) embedded in the opening provided in the insulator 280, the insulator 282, and the insulator 286 functioning as the interlayer film through the barrier layer 276; and a conductor 256 electrically connected to the conductor 252.

Note that in the semiconductor device, the conductor 252 and the conductor 256 function as plugs or wirings. Note that in this specification and the like, a wiring and a plug electrically connected to the wiring may be a single component. That is, there are cases where part of a conductor functions as a wiring and part of a conductor functions as a plug.

The transistor 200 includes a conductor 260 (a conductor 260a and a conductor 260b) functioning as a first gate electrode; a conductor 205 functioning as a second gate electrode; a barrier layer 270 covering the conductor 260; an insulator 250 functioning as a first gate insulating layer; an insulator 220, an insulator 222, and an insulator 224 functioning as a second gate insulating layer; and an oxide 230 (an oxide 230a, an oxide 230b, an oxide 230c, and an oxide 230d) including a region where a channel is formed.

Moreover, a conductor 203 (a conductor 203a and a conductor 203b) electrically connected to the conductor 205 functioning as the second gate electrode of the transistor 200 may be provided. In that case, the conductor 203 functions as a gate wiring. The conductor 203 is electrically connected to a conductor 252d through a conductor 207 provided in the same layer as the conductor 205. That is, the conductor 205 is electrically connected to the conductor 252d through the conductor 203 and the conductor 207. In contrast, when the conductor 203 is not provided, it is only necessary that the conductor 205 function as a gate electrode and a gate wiring.

By changing a potential applied to the conductor 205 not in synchronization with but independently of a potential applied to the conductor 260, the threshold voltage of the transistor 200 can be controlled. In particular, by applying a negative potential to the conductor 205, the threshold voltage of the transistor 200 can be substantially shifted in the positive direction. In addition, when the threshold voltage of the transistor 200 is higher than 0 V, the off-state current can be reduced. Accordingly, a drain current when a voltage applied to the conductor 260 is 0 V can be reduced. In addition, when the potential applied to the conductor 205 is substantially equal to the potential applied to the conductor 260, the on-state current of the transistor can be increased and leakage current in a non-conduction state (off-state current) can be reduced.

In the transistor 200, a metal oxide functioning as an oxide semiconductor (hereinafter, also referred to as an oxide semiconductor) is preferably used as the oxide 230. Since a transistor using an oxide semiconductor has an extremely low leakage current in a non-conduction state, a semiconductor device with low power consumption can be provided. Moreover, an oxide semiconductor can be deposited by a sputtering method or the like, and thus can be used for a transistor included in a highly integrated semiconductor device.

On the other hand, the transistor using an oxide semiconductor is likely to have its electrical characteristics changed by impurities and oxygen vacancies in the oxide semiconductor; accordingly, the reliability is decreased in some cases. Furthermore, hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, part of hydrogen is bonded to oxygen, which is bonded to a metal atom, whereby an electron serving as a carrier is generated. Accordingly, a transistor using an oxide semiconductor containing hydrogen is likely to have normally-on characteristics. Thus, it is preferable that hydrogen in the oxide semiconductor be reduced as much as possible.

The oxide 230 includes low-resistance regions. Regions 231 are each a low-resistance region in which the concentration of oxygen is lower than that of the region of the transistor 200 where the channel is formed. A layer containing a metal element may be formed in contact with the oxide 230 in order to reduce the concentration of oxygen in the region 231, which will be described in detail later. Moreover, the layer containing a metal element is subjected to heat treatment after formed, whereby the concentration of oxygen in the region 231 is further reduced. Furthermore, the region 231 preferably has a high content of indium (In) contained in the oxide 230. A high content of indium (In) is preferable because the resistance of the region 231 is further reduced. It is preferable to form, in the region 231, a metal compound layer containing the metal element contained in the layer containing the metal element and a component of the oxide 230. The metal compound layer is preferably formed in the region 231 because the resistance of the region 231 is reduced.

In addition, the regions 231 may be formed by addition of an element that forms an oxygen vacancy or an element that is bonded to an oxygen vacancy to the oxide 230. For the addition of the element, for example, an ion implantation method by which an ionized source gas is subjected to mass separation and then added, an ion doping method by which an ionized source gas is added without mass separation, a plasma immersion ion implantation method, or plasma treatment can be used.

It can be considered that when the element is added to the oxide 230, a bond between a metal element and an oxygen atom in the oxide 230 is broken, and an oxygen vacancy is generated in the oxide 230. When impurities such as hydrogen are trapped by the oxygen vacancy, carriers are generated, and the resistance of the oxide 230, that is, the resistance of the region 231 is reduced. Impurities such as hydrogen exist in the oxide 230 in some cases. In this case, the impurities may exist without being connected to a metal element or an oxygen atom.

Examples of an element that forms an oxygen vacancy or an element that is bonded to an oxygen vacancy in the oxide 230 include boron and phosphorus. Hydrogen, carbon, nitrogen, fluorine, sulfur, chlorine, titanium, or the like can be used as well as boron and phosphorus. Other examples of the above elements include metal elements such as aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum. One or more elements selected from the above elements may be added to the oxide 230. Among the above-described elements, boron or phosphorus is preferable as the element to be added. Since an apparatus in a manufacturing line for amorphous silicon or low-temperature polysilicon can be used for the addition of boron or phosphorus, capital investment can be reduced. It is only necessary that the concentration of any of the above elements be measured by secondary ion mass spectrometry (SIMS) or the like.

Heat treatment is preferably performed after addition of the above element. The heat treatment probably allows effective bonding of the element added to the oxide 230 with oxygen in the oxide 230, so that more oxygen vacancies are formed. Impurities such as hydrogen are trapped by the oxygen vacancy, whereby the resistance value of the region 231 of the oxide 230 is further reduced. Note that the heat treatment may be performed just after the addition of the element, after formation of insulators, conductors, and the like, or after processing. That is, a plurality of steps may be performed between the addition of the element and the heat treatment.

Moreover, the insulator 280 functioning as an interlayer film is preferably an insulator containing oxygen, such as a silicon oxide film or a silicon oxynitride film.

It is particularly preferable that the insulator 280 provided in the vicinity of the transistor 200 be an insulator containing oxygen, such as a silicon oxide film or a silicon oxynitride film. It is particularly preferable to use, for the insulator 280, an oxide that contains more oxygen than that in the stoichiometric composition. That is, in the insulator 280, a region including oxygen in excess of that in the stoichiometric composition (hereinafter also referred to as an excess-oxygen region) is preferably formed. In particular, when an insulator including an excess-oxygen region is provided for an interlayer film in the vicinity of the transistor 200, oxygen vacancies in a channel formation region of the oxide 230 included in the transistor 200 are reduced, whereby the reliability can be improved.

As the insulator including an excess-oxygen region, specifically, an oxide material from which part of oxygen is released by heating is preferably used. An oxide that releases oxygen by heating is an oxide film of which the amount of released oxygen converted into oxygen atoms is greater than or equal to 1.0×10¹⁸ atoms/cm³, preferably greater than or equal to 3.0×10²⁰ atoms/cm³ in TDS (Thermal Desorption Spectroscopy) analysis. Note that the temperature of the film surface in the TDS analysis is preferably in a range higher than or equal to 100° C. and lower than or equal to 700° C., or higher than or equal to 100° C. and lower than or equal to 500° C.

For example, a material containing silicon oxide or silicon oxynitride can be used. Alternatively, a metal oxide can be used. Note that in this specification, silicon oxynitride refers to a material that contains oxygen at a higher proportion than nitrogen, and silicon nitride oxide refers to a material that contains nitrogen at a higher proportion than oxygen.

For the insulator 282a, a metal oxide that is formed by a sputtering method is preferably used, and for example, aluminum oxide is preferably used. With such an insulator 282a, oxygen can be supplied to the insulator 280 through a surface of the insulator 280 that is in contact with the insulator 282a, so that the insulator 280 can be in an oxygen-excess state. By heat treatment or the like, excess oxygen is supplied to the region of the oxide 230 where a channel is formed (referred to as a channel formation region) through the insulator 280, and the insulator 250 or the insulator 224 in contact with the insulator 280. Thus, oxygen vacancies in the channel formation region of the oxide 230 can be reduced.

In the case where the insulator 280 includes an excess-oxygen region, the insulator 282 (the insulator 282a and the insulator 282b) preferably has a barrier property against oxygen, hydrogen, and water. When the insulator 282 has a barrier property against oxygen, oxygen in the excess-oxygen region is not diffused to the insulator 286 side but supplied to the oxide 230 efficiently. In addition, the insulator 282 may have a stacked-layer structure; a metal oxide may be formed by a sputtering method and then another metal oxide may further be formed over the metal oxide by an ALD method. The film formed by an ALD method is preferable because the coverage is high and the metal oxide can be formed with a uniform thickness even on a side surface caused by unevenness, a step portion, or the like, which improves a barrier property against oxygen, hydrogen, and water.

The insulator 282 having such a stacked-layer structure is preferable because of having a function of supplying excess oxygen to the insulator 280 and a barrier property against oxygen, hydrogen, and water.

Here, a barrier property refers to a function of inhibiting the diffusion of impurities typified by hydrogen and water, and oxygen. For example, the diffusion of hydrogen is inhibited in an atmosphere at 350° C., preferably at 400° C. In the case where TDS measurement is performed on a structure including a first film that releases hydrogen and any second film stacked thereover, for example, the second film is regarded to have a barrier property against hydrogen when the amount of released hydrogen is detected to be less than or equal to 5.0×10¹⁴/cm² at 400° C. or lower. Note that a film in which the amount of released hydrogen is detected to be preferably less than or equal to 3.4×10¹⁴/cm² at 400° C. or lower, further preferably less than or equal to 7.1×10¹⁴/cm² at 500° C. or lower is preferable. Moreover, a film in which the amount of released hydrogen is detected to be still further preferably less than or equal to 1.4×10¹⁵/cm² at 600° C. or lower is preferable.

Note that, as well as the insulator 282, the insulator 222 included in the transistor 200 preferably has a barrier property against oxygen, hydrogen, and water, which will be described in detail later. When the insulator 222 has a barrier property against oxygen, oxygen in the excess-oxygen region is not diffused to the insulator 220 side but can be supplied to the oxide 230 efficiently.

For example, a single layer or a stacked layer of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) is preferably used for the insulator 282. In particular, an insulating film having a barrier property against oxygen or hydrogen, such as aluminum oxide or hafnium oxide, is preferably used. When formed using such a material, the insulator 282 functions as a layer which prevents release of oxygen from the oxide 230 and entry of an impurity such as hydrogen from the outside.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. Silicon oxide, silicon oxynitride, or silicon nitride may be stacked over the above insulator.

A material similar to that for the insulator 280 can be used for the insulator 286. Note that the insulator 280, the insulator 282, and the insulator 286 may each have a stacked-layer structure of two or more layers. In that case, the stacked layers are not necessarily formed from the same material and may be formed from different materials. Note that the insulator 280 covering the transistor 200 may function as a planarization film that covers an uneven shape thereunder.

In addition, the transistor 200 is electrically connected to another component through the plug or the wiring such as the conductor 252 and the conductor 256 embedded in the insulator 280, the insulator 282, and the insulator 286, in some cases. At this time, when the conductor 252 is in contact with the insulator 280, excess oxygen contained in the insulator 280 might be absorbed by the conductor 252.

Depending on the shape of the plug or the wiring provided in the semiconductor device or the number of plugs or wirings, excess oxygen contained in the insulator 280 becomes insufficient and oxygen vacancies in the oxide 230 included in the transistor 200 are not compensated, which might result in a reduction in the reliability of the semiconductor device. Thus, when the excess-oxygen region is formed in the insulator 280, it is necessary to design the semiconductor device taking the amount of oxygen absorbed by the conductor 252 into consideration.

Hydrogen, which is an impurity, contained in another component formed in the vicinity of the transistor 200 is diffused to a component in contact with a conductor used as the plug or the wiring through the conductor, in some cases.

Thus, it is preferable to provide the barrier layers 276 between the conductor 252 and the insulator 280 having the excess-oxygen region and the insulator 282 having a barrier property. It is particularly preferable that the barrier layers 276 be provided to be in contact with the insulator 282 having a barrier property. Furthermore, it is also preferable that the barrier layers 276 be in contact with part of the insulator 286. When the barrier layers 276 extend up to the insulator 286, the diffusion of oxygen and impurities can be inhibited more.

That is, when the barrier layers 276 are provided, absorption of excess oxygen contained in the insulator 280 by the conductor 252 can be inhibited. Accordingly, a reduction in the reliability of the semiconductor device can be inhibited because excess oxygen for compensating for oxygen vacancies in the oxide 230 included in the transistor 200 is not absorbed by the conductor 252 and thus compensation for the oxygen vacancies in the oxide 230 included in the transistor 200 is not hindered.

Furthermore, with the barrier layers 276, the diffusion of hydrogen, which is an impurity, can be inhibited. For example, with the barrier layers 276, the diffusion of hydrogen contained in components, which are formed closer to the insulator 286 side than to the insulator 282, to the insulator 280 in contact with the transistor 200 through the conductor 252 can be inhibited.

In addition, with the barrier layers 276, the insulator 280 can contain excess oxygen at an appropriate amount regardless of the shape or the position of the plug or the wiring provided in the semiconductor device or the number of plugs or wirings. Since oxygen defects are less likely to be formed when the diffusion of hydrogen is inhibited, generation of carriers can be inhibited. Thus, excess oxygen can be supplied to the transistor 200 stably, which enables the transistor 200 to have stable electrical characteristics. Moreover, the design flexibility of the semiconductor device can be increased.

Furthermore, with the barrier layers 276, the range of choices for the materials of the conductor used as the plug or the wiring can be expanded. The use of a metal material having an oxygen absorbing property and high conductivity for the conductor 252, for example, can provide a semiconductor device with low power consumption. As specific examples, a material having a low oxidation resistance and high conductivity, such as tungsten or aluminum, can be used. Moreover, for example, a conductor that can be easily deposited and processed can be used.

As a material for the conductor 252, a single layer or a stacked layer of a conductive material such as a metal material, an alloy material, a metal nitride material, or a metal oxide material can be used. For example, it is preferable to use a high-melting-point material that has both heat resistance and conductivity, such as tungsten or molybdenum. Alternatively, a low-resistance conductive material such as aluminum or copper is preferably used. The use of a low-resistance conductive material can reduce wiring resistance.

Note that for the conductor 252, a single layer or a stacked layer of tantalum nitride, which is a conductor having a barrier property against hydrogen and oxygen, or tungsten that has high conductivity may be used, for example. For example, when a stacked layer of tantalum nitride and tungsten is used for the conductor 252, the diffusion of impurities from the outside can be inhibited while the conductivity as a wiring remains. Moreover, titanium nitride may be formed over tantalum nitride and tungsten may be formed using the titanium nitride as a seed layer. Furthermore, when, as the conductor 252, a conductor containing at least one of tungsten, aluminum, and titanium is formed in contact with the oxide 230, the resistance of the oxide 230 in the vicinity of the conductor is reduced in some cases. The above conductor is preferably used for a first layer of the conductor 252 because contact resistance between the conductor 252 and the oxide 230 is reduced. For example, a stacked-layer structure including tungsten in a first layer, titanium nitride in a second layer, and tungsten in a third layer is preferable for the conductor 252 in terms of contact resistance.

A metal oxide can be used for the barrier layers 276, for example. In particular, an insulating film having a barrier property against oxygen or hydrogen, such as aluminum oxide, hafnium oxide, or gallium oxide, is preferably used. Alternatively, silicon nitride formed by a chemical vapor deposition (CVD) method may be used.

Thus, a semiconductor device having stable electrical characteristics can be provided. In addition, a highly reliable semiconductor device can be provided. Moreover, a semiconductor device with low power consumption can be provided. Furthermore, the design flexibility of a semiconductor device can be increased.

### <Transistor Structure 1>

An example of the transistor 200 will be described below.

The transistor 200 of this embodiment includes an insulator 212 and the conductor 203 positioned so as to be embedded in the insulator 212 over an insulator 208 positioned over a substrate (not illustrated) and an insulator 210 positioned over the insulator 208. As a method for forming the conductor 203 and the insulator 212, what is called a damascene process in which an opening such as a groove or a slit is formed in the insulator 212 and the conductor 203 is formed in the opening may be employed. Alternatively, the insulator 212 may be formed so as to cover the conductor 203 and an unnecessary portion of the insulator 212 may be removed.

In this embodiment, for the conductor 203, a metal film containing an element selected from molybdenum, titanium, tantalum, tungsten, aluminum, copper, chromium, neodymium, and scandium; a metal nitride film containing any of the above elements as its component (a tantalum nitride film, a titanium nitride film, a molybdenum nitride film, or a tungsten nitride film); or the like can be used. In particular, a metal nitride film such as tantalum nitride is preferable because it has a barrier property against hydrogen or oxygen and is difficult to oxidize (has a high oxidation resistance). Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

For example, it is preferable that a conductor having a barrier property against hydrogen, such as tantalum nitride or titanium nitride, be used for the conductor 203a, and tungsten, which has high conductivity, be stacked thereover as the conductor 203b. The use of the combination can inhibit the diffusion of hydrogen, which is contained in the insulator 208 and an element located closer to the substrate side than to the insulator 208, to the oxide 230 side while the conductivity as a wiring remains. In the case where the insulator 210 has an opening and the conductor 203 is electrically connected to an element located closer to the substrate side than the insulator 210, such a combination is particularly preferable because the above effect can be expected when the insulator 210 and the conductor 203a have barrier properties against hydrogen. Note that a two-layer structure of the conductor 203a and the conductor 203b is illustrated in FIG. 1; however, the structure is not limited thereto and may be a single-layer structure or a stacked-layer structure of three or more layers. For example, between a conductor having a barrier property and a conductor having a high conductivity, a conductor which is highly adhesive to the conductor having a barrier property and the conductor having high conductivity may be formed. For example, it is preferable to use tantalum nitride for the conductor 203a and a stacked layer of titanium nitride and tungsten for the conductor 203b.

An insulator 216 and the conductor 205 positioned so as to be embedded in the insulator 216 are provided over the conductor 203 and the insulator 212. The conductor 205 and the insulator 216 can be formed in a manner similar to that of the conductor 203 and the insulator 212.

Like the insulator 280, each of the insulator 222 and the insulator 224 is preferably an insulator containing oxygen, such as a silicon oxide film or a silicon oxynitride film. It is particularly preferable that an excess-oxygen region be formed in the insulator 224. When an insulator including an excess-oxygen region is provided for peripheral materials of the transistor 200 in the case of using an oxide semiconductor in the transistor 200, oxygen vacancies in the oxide 230 included in the transistor 200 are reduced, whereby the reliability can be improved.

Moreover, in the case where the insulator 224 includes an excess-oxygen region, the insulator 222 preferably has a barrier property against oxygen, hydrogen, and water. When the insulator 222 has a barrier property against oxygen, oxygen in the excess-oxygen region is not diffused to the insulator 220 side but can be supplied to the oxide 230 efficiently. Moreover, reaction of the conductor 205 and the conductor 203 with oxygen in the excess-oxygen region of the insulator 224 can be inhibited.

For example, it is preferable to use, for the insulator 222, a single layer or a stacked layer of an insulator containing what is called a high-k material such as aluminum oxide, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, or a nitride containing silicon and hafnium. In particular, an insulating film having a barrier property against oxygen or hydrogen, such as aluminum oxide or hafnium oxide, is preferably used. When formed using such a material, the insulator 222 functions as a layer which prevents release of oxygen from the oxide 230 and entry of an impurity such as hydrogen from the outside.

Note that the insulator 220, the insulator 222, and the insulator 224 may each have a stacked-layer structure of two or more layers. In that case, the stacked layers are not necessarily formed from the same material and may be formed from different materials.

The oxide 230 includes the oxide 230a, the oxide 230b over the oxide 230a, the oxide 230c over the oxide 230b, and the oxide 230d over the oxide 230c. When the transistor 200 is turned on, current flows (a channel is formed) mainly through (in) the oxide 230b and the oxide 230c. Meanwhile, although current sometimes flows through the vicinities of the interfaces (mixed regions in some cases) of the oxide 230a and the oxide 230d with the oxide 230b and the oxide 230c, the other regions sometimes function as insulators. Note that one of the oxide 230c and the oxide 230d is not necessarily provided.

As illustrated in FIG. 1(C), the oxide 230c and the oxide 230d are preferably provided so as to cover side surfaces of the oxide 230a and the oxide 230b. The oxide 230c and the oxide 230d, which are provided between the insulator 280 and the oxide 230b including the region where the channel is formed, can inhibit diffusion of impurities such as hydrogen, water, and halogen from the insulator 280 to the oxide 230b.

The oxide 230a, the oxide 230b, the oxide 230c, and the oxide 230d are formed with a metal oxide such as an In-M-Zn oxide (the element M is one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like). Furthermore, as the oxide 230, an In—Ga oxide or an In—Zn oxide may be used.

### <<Metal Oxide>>

A metal oxide functioning as an oxide semiconductor (hereinafter also referred to as an oxide semiconductor) is preferably used as the oxide 230. A metal oxide that can be used as the oxide 230 of the present invention will be described below.

A metal oxide preferably contains at least indium or zinc. It is particularly preferable to contain indium and zinc. Moreover, aluminum, gallium, yttrium, tin, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, and the like may be contained.

Here, the case where the metal oxide is an In-M-Zn oxide that contains indium, an element M, and zinc is considered. Note that the elementMis aluminum, gallium, yttrium, tin, or the like. Other elements that can be used as the element M include boron, titanium, iron, nickel, germanium, zirconium, molybdenum, lanthanum, cerium, neodymium, hafnium, tantalum, tungsten, magnesium, and the like. Note that a plurality of the above-described elements may be combined as the element M.

Note that in this specification and the like, a metal oxide containing nitrogen is also collectively referred to as a metal oxide in some cases. A metal oxide containing nitrogen may be referred to as a metal oxynitride.

### [Composition of Metal Oxide]

The composition of a CAC (Cloud-Aligned composite)-OS that can be used for a transistor disclosed in one embodiment of the present invention will be described.

Note that in this specification and the like, CAAC (c-axis aligned crystal) or CAC (Cloud-Aligned Composite) might be stated. Note that CAAC refers to an example of a crystal structure, and CAC refers to an example of a function or a material composition.

A CAC-OS or a CAC-metal oxide has a conducting function in part of the material and has an insulating function in another part of the material; as a whole, the CAC-OS or the CAC-metal oxide has a function of a semiconductor. Note that in the case where the CAC-OS or the CAC-metal oxide is used in an active layer of a transistor, the conducting function is a function of allowing electrons (or holes) serving as carriers to flow, and the insulating function is a function of not allowing electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

Moreover, the CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, the conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide includes components having different bandgaps. For example, the CAC-OS or the CAC-metal oxide includes a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, high current driving capability in an on state of the transistor, that is, a high on-state current and high field-effect mobility can be obtained.

In other words, the CAC-OS or the CAC-metal oxide can also be referred to as a matrix composite or a metal matrix composite.

### [Structure of Metal Oxide]

Oxide semiconductors (metal oxides) can be classified into single crystal oxide semiconductors and the others, non-single-crystal oxide semiconductors. Examples of the non-single-crystal oxide semiconductors include a CAAC-OS (c-axis-aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that it is difficult to observe a clear crystal grain boundary (also referred to as a grain boundary) even in the vicinity of distortion in the CAAC-OS. That is, formation of a crystal grain boundary is inhibited by the distortion of a lattice arrangement. This is because the CAAC-OS can tolerate distortion owing to non-dense arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter In layer) and a layer containing the element M, zinc, and oxygen (hereinafter (M,Zn) layer) are stacked. Note that indium and the element M can be replaced with each other, and when the element M in the (M,Zn) layer is replaced with indium, the layer can also be referred to as an (InN,Zn) layer. Furthermore, when indium in the In layer is replaced with the element M, the layer can be referred to as an (In,M) layer.

The CAAC-OS is a metal oxide with high crystallinity. In contrast, in the CAAC-OS, a reduction in electron mobility due to the crystal grain boundary is less likely to occur because it is difficult to observe a clear crystal grain boundary. Furthermore, entry of impurities, formation of defects, or the like might decrease the crystallinity of a metal oxide; thus, it can be said that the CAAC-OS is a metal oxide that has small amounts of impurities and defects (e.g., oxygen vacancies (also referred to as V_{O})). Thus, a metal oxide including the CAAC-OS is physically stable. Therefore, the metal oxide including the CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

Note that indium-gallium-zinc oxide (hereinafter referred to as IGZO) that is a kind of metal oxide containing indium, gallium, and zinc has a stable structure in some cases by being formed of the above-described nanocrystals. In some cases, IGZO has a stable structure when formed of smaller crystals (e.g., the above-described nanocrystals) rather than larger crystals (here, crystals with a size of several millimeters or several centimeters) because crystal growth tends to hardly occur particularly in the air.

The a-like OS is a metal oxide having a structure between those of the nc-OS and an amorphous oxide semiconductor. The a-like OS includes a void or a low-density region. That is, the a-like OS has low crystallinity as compared with the nc-OS and the CAAC-OS.

An oxide semiconductor can have various structures which show different properties. Two or more of the amorphous oxide semiconductor, the polycrystalline oxide semiconductor, the a-like OS, the nc-OS, and the CAAC-OS may be included in an oxide semiconductor of one embodiment of the present invention.

### [Transistor Including Metal Oxide]

Next, the case where the metal oxide is used for a channel formation region of a transistor will be described.

Note that when the metal oxide is used for a channel formation region of a transistor, a transistor with high field-effect mobility can be achieved. In addition, the transistor having high reliability can be achieved.

Furthermore, a metal oxide with a low carrier density is preferably used for the transistor. In the case where the carrier density of a metal oxide film is reduced, the concentration of impurities in the metal oxide film is reduced so that the density of defect states is reduced. In this specification and the like, a state with a low impurity concentration and a low density of defect states is referred to as a highly purified intrinsic or substantially highly purified intrinsic state. For example, it is only necessary that the carrier density of the metal oxide be lower than 8×10¹¹/cm³, preferably lower than 1×10¹¹/cm³, and further preferably lower than 1×10¹⁰/cm³, and higher than or equal to 1×10⁻⁹/cm³.

Moreover, a highly purified intrinsic or substantially highly purified intrinsic metal oxide film has a low density of defect states and accordingly has a low density of trap states in some cases.

Charge trapped by the trap states in the metal oxide takes a long time to disappear and behaves like fixed charge in some cases. Thus, a transistor having a metal oxide with high density of trap states in a channel formation region has unstable electrical characteristics in some cases.

Thus, it is effective to reduce the concentration of impurities in the metal oxide to make the electrical characteristics of the transistor stable. In addition, it is preferable to also reduce the concentration of impurities in an adjacent film to reduce the concentration of impurities in the metal oxide. Examples of impurities include hydrogen, nitrogen, an alkali metal, an alkaline earth metal, iron, nickel, and silicon.

### [Impurities]

Here, the influence of each impurity in the metal oxide will be described.

When silicon or carbon that is one of the Group 14 elements is contained in the metal oxide, defect states are formed in the metal oxide. Thus, the concentration of silicon or carbon in the metal oxide and the concentration of silicon or carbon around an interface with the metal oxide (the concentration obtained by secondary ion mass spectrometry (SIMS)) is set to be lower than or equal to 2×10¹⁸ atoms/cm³, preferably lower than or equal to 2×10¹⁷ atoms/cm³.

Furthermore, when the metal oxide contains an alkali metal or an alkaline earth metal, defect states are formed and carriers are generated in some cases. Thus, a transistor in which a metal oxide containing an alkali metal or alkaline earth metal is used in a channel formation region is likely to have normally-on characteristics. Therefore, it is preferable to reduce the concentration of an alkali metal or an alkaline earth metal in the metal oxide. Specifically, the concentration of an alkali metal or an alkaline earth metal in the metal oxide, which is obtained by SIMS, is set to be lower than or equal to 1×10¹⁸ atoms/cm³, preferably lower than or equal to 2×10¹⁶ atoms/cm³.

Furthermore, when containing nitrogen, the metal oxide easily becomes n-type by generation of electrons serving as carriers and an increase in carrier density. As a result, a transistor in which a metal oxide containing nitrogen is used in a channel formation region is likely to have normally-on characteristics. Thus, nitrogen in the channel formation region in the metal oxide is preferably reduced as much as possible. For example, the concentration of nitrogen in the metal oxide, which is measured by SIMS, is set to be lower than 5×10¹⁹ atoms/cm³, preferably lower than or equal to 5×10¹⁸ atoms/cm³, further preferably lower than or equal to 1×10¹⁸ atom/cm³, still further preferably lower than or equal to 5×10¹⁷ atoms/cm³.

Furthermore, hydrogen contained in the metal oxide reacts with oxygen bonded to a metal atom to be water, and thus forms an oxygen vacancy in some cases. Entry of hydrogen into the oxygen vacancy generates an electron serving as a carrier in some cases. Furthermore, in some cases, part of hydrogen is bonded to oxygen, which is bonded to a metal atom, whereby an electron serving as a carrier is generated. Accordingly, a transistor using a metal oxide containing hydrogen is likely to have normally-on characteristics.

Hydrogen contained in the metal oxide forms shallow defect states (sDOS: shallow level Density of States) in the metal oxide in some cases. Shallow defect states refer to interface states near the conduction band minimum. Shallow defect states probably exist near the boundary between a high-density region and a low-density region in the metal oxide. Here, the high-density region and the low-density region in the metal oxide are distinguished by the amounts of hydrogen contained in the regions. That is, the high-density region contains more hydrogen than the low-density region. It is probable that near the boundary between the high-density region and the low-density region in the metal oxide, stress distortion between the regions easily causes minute cracks, oxygen vacancies and dangling bonds of indium are generated near the cracks, and impurities such as hydrogen and water are localized there to form shallow defect states.

The high-density region in the metal oxide sometimes has higher crystallinity than the low-density region. Furthermore, the high-density region in the metal oxide sometimes has higher film density than the low-density region. When the metal oxide has a composition including indium, gallium, and zinc, the high-density region contains indium, gallium, and zinc and the low-density region contains indium and zinc, in some cases. In other words, the proportion of gallium in the low-density region is lower than that in the high-density region in some cases.

Note that the above shallow defect states probably result from oxygen vacancies. An increase in the number of oxygen vacancies in the metal oxide probably leads to an increase in deep defect states (dDOS: deep-level Density of States) as well as an increase in the shallow defect states. This is because deep defect states also result from oxygen vacancies. Note that deep defect states refer to defect states that are located around the center of the band gap.

Therefore, a reduction in the number of oxygen vacancies in the metal oxide can lead to a reduction in both shallow defect states and deep defect states. Furthermore, shallow defect states can possibly be controlled to some extent by adjusting the temperature at the time of deposition of the metal oxide. Specifically, the temperature at the time of deposition of the metal oxide is set at around 170° C., preferably around 130° C., further preferably room temperature, whereby shallow defect states can be reduced.

Shallow defect states in a metal oxide affect the electrical characteristics of the transistor that uses the metal oxide as a semiconductor. That is, owing to shallow defect states, the drain current I_{d} changes gently with respect to the gate voltage V_{g} in the drain current—gate voltage (I_{d}−V_{g}) characteristics of the transistor, worsening the S value (also referred to as subthreshold swing, or SS), which is a criterion for judging the rising characteristics of a transistor from an off state to an on state. This is probably because of trapping of electrons by shallow defect states.

Thus, it is preferable that hydrogen in the metal oxide be reduced as much as possible. Specifically, the concentration of hydrogen in the metal oxide, which is obtained by SIMS, is set to be lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When a metal oxide whose impurities are sufficiently reduced is used for a channel formation region of a transistor, stable electrical characteristics can be provided.

### <Low-Resistance Region>

The oxide 230 includes the low-resistance regions. The regions 231 are each a low-resistance region in which the concentration of oxygen is lower than that of the region of the transistor 200 where the channel is formed.

To reduce the concentration of oxygen in the region 231, for example, it is preferable to provide a metal layer containing a metal element, a nitride layer containing a metal element, or an oxide layer containing a metal element (a layer containing a metal element) over the oxide semiconductor. By providing the layer, some oxygen in the interface between the layer and the oxide semiconductor or in the oxide semiconductor positioned in the vicinity of the interface may be absorbed by the layer or the like and an oxygen vacancy may be formed, so that the resistance in the vicinity of the interface might be reduced.

After the metal layer containing a metal element, the nitride layer containing a metal element, or the oxide layer containing a metal element (the layer containing a metal element) is provided over the oxide semiconductor, heat treatment is preferably performed in an atmosphere containing nitrogen. By the heat treatment in an atmosphere containing nitrogen, the concentrations of oxygen in the region 231 is further reduced.

In addition, the region 231 may be formed by addition of an element that forms an oxygen vacancy or an element that is bonded to an oxygen vacancy to the oxide 230. For the addition of the element, for example, an ion implantation method by which an ionized source gas is subjected to mass separation and then added, an ion doping method by which an ionized source gas is added without mass separation, a plasma immersion ion implantation method, or plasma treatment can be used.

One of the low-resistance regions 231 functions as a source of the transistor 200 and the other functions as a drain. In addition, a region sandwiched between the pair of regions 231 functions as a channel formation region of the transistor 200.

As the metal element, it is preferable to use aluminum, ruthenium, titanium, tantalum, chromium, tungsten, or the like. Aluminum, titanium, tantalum, tungsten, or the like is further preferably used. Thus, as the metal layer containing a metal element, a layer containing aluminum, titanium, tantalum, tungsten, or an alloy containing two or more of these metal elements is preferable. In addition, as the nitride layer containing a metal element, a layer containing aluminum nitride, titanium nitride, tantalum nitride, tungsten nitride, a nitride containing titanium and aluminum (TiAlNₓ or TiAlₓN_{y} (hereinafter x and y are any numbers)), a nitride containing tantalum and aluminum (TaAlNₓ or TaAlₓA_{y}), or the like is preferable. Note that a layer containing a nitride containing three or more of the above metal elements may also be used. Moreover, as the oxide layer containing a metal element, a layer containing aluminum oxide, titanium oxide, tantalum oxide, tungsten oxide, an oxide containing titanium and aluminum (TiAlOₓ or TiAlₓO_{y}), an oxide containing tantalum and aluminum (TaAlOₓ or TaAlₓO_{y}), or the like is preferable.

In the case where hydrogen in the oxide semiconductor diffuses into a low-resistance region of the oxide semiconductor and enters an oxygen vacancy in the low-resistance region, the hydrogen becomes relatively stable. It is known that hydrogen in the oxygen vacancy in the oxide semiconductor is released from the oxygen vacancy by heat treatment at 250° C. or higher, diffuses into a low-resistance region of the oxide semiconductor, enters an oxygen vacancy in the low-resistance region, and becomes relatively stable. Thus, by the heat treatment, the resistance of the low-resistance region of the oxide semiconductor or a region where the metal compound is formed tends to be further reduced, and the oxide semiconductor whose resistance is not reduced tends to be highly purified (reduction of impurities such as water or hydrogen) and the resistance tends to be increased. That is, the concentration of hydrogen in the channel formation region of the transistor 200 is reduced and gets lower than the concentration of hydrogen in the region 231. Furthermore, the concentration of hydrogen in the region 231 is increased in some cases.

Moreover, when the above metal element is added to the oxide semiconductor, a metal compound is formed and the resistance is reduced in some cases. A layer containing the above metal element may be formed over the oxide semiconductor by a sputtering method to add the metal element to the oxide semiconductor.

Alternatively, a compound layer (hereinafter also referred to as another layer) may be formed at an interface between the oxide semiconductor and the metal layer containing a metal element, the nitride layer containing a metal element, or the oxide layer containing a metal element (the layer containing a metal element). The compound layer may be formed in the layer containing a metal element and being in contact with the oxide layer, or may be formed in the oxide layer which is in contact with the layer containing a metal element. Note that the compound layer (another layer) is assumed to be a layer containing a metal compound containing the component of the layer containing a metal element and the component of the oxide semiconductor. For example, as the compound layer, a layer in which the metal element of the oxide semiconductor and the metal element added are alloyed may be formed. Furthermore, the compound layer may contain nitrogen or oxygen. The alloyed layer is relatively stable, and thus a highly reliable semiconductor device can be provided.

The above metal element is preferably added to the region 231 because the resistance of the region 231 is further reduced. Moreover, the above compound layer is preferably formed in the region 231 because the resistance of the region 231 is further reduced. Furthermore, the above compound layer is preferably formed over the region 231 because contact resistance between the oxide 230 and the conductor 252a or the conductor 252b, which will be described later, can be reduced.

It is preferable to remove the layer containing a metal element after the resistance of the region 231 is reduced. The layer containing a metal element is preferably removed because unevenness due to the layer containing a metal element over the oxide 230b is reduced and planarity of the insulator 250 and the conductor 260 formed thereover is improved. The planarity of a conductive film 260A to be the conductor 260 is preferably improved over the oxide 230b because, when the conductive film 260A is processed by a lithography method, alignment accuracy is improved and thus a desired mask can be formed and desired processing can be performed. Furthermore, in the case where the layer containing a metal element has a characteristic of absorbing hydrogen, hydrogen in the oxide 230 is absorbed by the layer containing a metal element. Thus, hydrogen, which is an impurity in the oxide 230, can be reduced. The layer containing a metal element is preferably removed because hydrogen absorbed from the oxide 230 can also be removed. Meanwhile, the layer containing a metal element is not necessarily removed in the case where the thickness of the layer containing a metal element hardly affect the planarity and coverage of the insulator 250 and the conductor 260. This case is preferable because a step of removing the layer containing a metal element can be omitted. For example, the layer containing a metal element is preferably provided to have a thickness of greater than or equal to 0.5 nm and less than or equal to 5 nm, preferably greater than or equal to 1 nm and less than or equal to 2 nm.

For example, a single layer or a stacked layer of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) can be used for the insulator 250. Alternatively, aluminum oxide, bismuth oxide, germanium oxide, niobium oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the above insulators.

Because of being thermally stable, silicon oxide or silicon oxynitride is combined with an insulator with a high dielectric constant, so that the stacked-layer structure can be thermally stable and have a high dielectric constant, for example.

In addition, it is preferable to use, for the insulator 250 as well as the insulator 224, an oxide insulator that contains more oxygen than that in the stoichiometric composition. When such an insulator containing excess oxygen is provided in contact with the oxide 230, oxygen vacancies in the oxide 230 can be reduced.

Furthermore, as the insulator 250, an insulating film having a barrier property against oxygen and hydrogen, such as aluminum oxide, aluminum oxynitride, gallium oxide, gallium oxynitride, yttrium oxide, yttrium oxynitride, hafnium oxide, hafnium oxynitride, or silicon nitride, can be used. When formed using such a material, the insulator 250 functions as a layer which prevents release of oxygen from the oxide 230 and entry of an impurity such as hydrogen from the outside.

Note that the insulator 250 may have a stacked-layer structure similar to that of the insulator 220, the insulator 222, and the insulator 224. When the insulator 250 includes an insulator in which a necessary amount of electrons is trapped by electron trap states, the threshold voltage of the transistor 200 can be shifted in the positive direction. The transistor 200 having the structure is a normally-off transistor which is in a non-conduction state (also referred to as an off state) even when the gate voltage is 0 V.

The conductor 260 functioning as a gate electrode can be formed using, for example, a metal selected from aluminum, chromium, copper, tantalum, titanium, molybdenum, and tungsten; an alloy containing any of the above metals as its component; or an alloy containing any of the above metals in combination. In particular, a metal nitride film of tantalum nitride or the like is preferable because it has a barrier property against hydrogen or oxygen and its oxidation resistance is high. Furthermore, one or more metals selected from manganese and zirconium may be used. Alternatively, a semiconductor typified by polycrystalline silicon doped with an impurity element such as phosphorus, or silicide such as nickel silicide may be used.

The conductor 260 may have a stacked-layer structure including the conductor 260a and the conductor 260b over the conductor 260a. The conductor 260a is formed by a thermal CVD method, an MOCVD (Metal Organic CVD) method, or an atomic layer deposition (ALD) method, for example. In particular, the conductor 260a is preferably formed by an ALD method. Damage to the insulator 250 at the time of the deposition can be reduced when the conductor 260a is formed by an ALD method or the like. Furthermore, the conductor 260a is preferably deposited by an ALD method or the like because coverage can be improved. Thus, the transistor 200 having high reliability can be provided.

Next, the conductor 260b is formed by a sputtering method. At that time, since the conductor 260a is provided over the insulator 250, influence of damage caused during deposition of the conductor 260b on the insulator 250 can be reduced. Since the deposition rate in a sputtering method is higher than that in an ALD method, the productivity can be improved with a high yield.

Alternatively, a conductive oxide may be used for the conductor 260a. For example, the metal oxide that can be used as the oxide 230a or the oxide 230b can be used. In particular, an In—Ga—Zn-based oxide with an atomic ratio of [In]:[Ga]:[Zn]=4:2:3 to 4:2:4.1 or the vicinity thereof, which has high conductivity, is preferably used. When such a conductor 260a is provided, penetration of oxygen to the conductor 260b can be inhibited, and an increase in electric resistance value of the conductor 260b due to oxidation can be prevented.

When the above conductive oxide is deposited by a sputtering method, oxygen can be added to the insulator 250, so that oxygen can be supplied to the oxide 230b. Thus, oxygen vacancies in the channel formation region of the oxide 230 can be reduced.

In the case where the conductive oxide as described above is used for the conductor 260a, a stacked layer of titanium nitride and tungsten is preferably formed by a sputtering method as the conductor 260b. When the titanium nitride is formed in an atmosphere containing nitrogen, nitrogen is added to the conductor 260a, so that the resistance of the conductor 260a is further reduced.

The barrier layer 270 may be provided so as to cover the conductor 260. In the case where an oxide material from which oxygen is released is used for the insulator 280, the barrier layer 270 is formed using a substance having a barrier property against oxygen. With such a structure, oxygen in the excess-oxygen region included in the insulator 280 can be prevented from reacting with the conductor 260 and oxidizing the conductor 260.

A metal oxide can be used for the barrier layer 270, for example. In particular, an insulating film having a barrier property against oxygen or hydrogen, such as aluminum oxide, hafnium oxide, an oxide containing hafnium and aluminum (hafnium aluminate), or gallium oxide, is preferably used. Alternatively, silicon nitride formed by a CVD method may be used. It is only necessary that the barrier layer 270 be formed to a thickness with which the oxidation of the conductor 260 is prevented.

With the barrier layer 270, the range of choices for the materials of the conductor 260 can be expanded. For example, a material having a low oxidation resistance and high conductivity, such as tungsten or aluminum, can be used for the conductor 260. Moreover, for example, a conductor that can be easily deposited and processed can be used.

In addition, the oxidation of the conductor 260 can be inhibited, and oxygen released from the insulator 224 and the insulator 280 can be supplied to the oxide 230 efficiently. Furthermore, a conductor that has high conductivity is used for the conductor 260, whereby the transistor 200 with low power consumption can be provided.

With the above structure, a semiconductor device that includes a transistor including an oxide semiconductor and having a high on-state current can be provided. Alternatively, a semiconductor device that includes a transistor including an oxide semiconductor and having a low off-state current can be provided. Alternatively, a semiconductor device that has small variation in electrical characteristics and high reliability can be provided. Alternatively, a semiconductor device with reduced power consumption can be provided.

### <Constituent Material for Semiconductor Device>

Constituent materials that can be used for a semiconductor device will be described below.

### <<Substrate>>

As a substrate over which the transistor 200 is formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate containing silicon carbide, silicon germanium, gallium arsenide, indium phosphide, zinc oxide, or gallium oxide. Moreover, a semiconductor substrate in which an insulator region is included in the above semiconductor substrate, for example, an SOI (Silicon On Insulator) substrate or the like is used. Examples of the conductor substrate include a graphite substrate, a metal substrate, an alloy substrate, and a conductive resin substrate. Alternatively, a substrate including a metal nitride, a substrate including a metal oxide, or the like is used. Moreover, an insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. Examples of the element provided over the substrate include a capacitor, a resistor, a switching element, a light-emitting element, and a memory element.

A flexible substrate may be used as the substrate. Note that as a method of providing a transistor over a flexible substrate, there is a method in which the transistor is fabricated over a non-flexible substrate and then the transistor is separated and transferred to a substrate which is a flexible substrate. In that case, a separation layer is preferably provided between the non-flexible substrate and the transistor. In addition, the substrate may have elasticity. Furthermore, the substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. Moreover, when the substrate has a small thickness, even in the case of using glass or the like, the substrate may have elasticity or a property of returning to its original shape when bending or pulling is stopped. Thus, an impact or the like applied to a semiconductor device over the substrate, which is caused by dropping or the like, can be reduced. That is, a durable semiconductor device can be provided.

For the substrate which is a flexible substrate, metal, an alloy, a resin, glass, or fiber thereof can be used, for example. Note that as the substrate, a sheet, a film, a foil or the like that contains a fiber may be used. The substrate which is a flexible substrate preferably has a lower coefficient of linear expansion because deformation due to an environment is inhibited. For the substrate which is a flexible substrate, a material whose coefficient of linear expansion is lower than or equal to 1×10⁻³/K, lower than or equal to 5×10⁻⁵/K, or lower than or equal to 1×10⁻⁵/K may be used, for example. Examples of the resin include polyester, polyolefin, polyamide (e.g., nylon or aramid), polyimide, polycarbonate, and acrylic. In particular, aramid is preferable for the substrate which is a flexible substrate because of its low coefficient of linear expansion.

### <<Insulator>>

Examples of an insulator include an oxide, a nitride, an oxynitride, a nitride oxide, a metal oxide, a metal oxynitride, and a metal nitride oxide, each of which has an insulating property.

When a high-k material having a high dielectric constant is used for the insulator functioning as the gate insulator, miniaturization and high integration of the transistor can be achieved. In contrast, when a material having a low dielectric constant is used for the insulator functioning as an interlayer film, the parasitic capacitance generated between wirings can be reduced. Therefore, a material is preferably selected depending on the function of an insulator.

Moreover, examples of the insulator having a high dielectric constant include aluminum oxide, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

In particular, silicon oxide and silicon oxynitride are thermally stable. Accordingly, a stacked-layer structure which is thermally stable and has a low dielectric constant can be obtained by combination with a resin, for example. Examples of the resin include polyester, polyolefin, polyamide (e.g., nylon or aramid), polyimide, polycarbonate, and acrylic. A stacked-layer structure which is thermally stable and has a high dielectric constant can be obtained by combining silicon oxide and silicon oxynitride with an insulator having a high dielectric constant.

In addition, when a transistor using an oxide semiconductor is surrounded by an insulator having a function of inhibiting the penetration of oxygen and impurities such as hydrogen, the transistor can have stable electrical characteristics.

As the insulator having a function of inhibiting the penetration of oxygen and impurities such as hydrogen, a single layer or a stacked layer of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting the penetration of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

For example, an insulator that has a function of inhibiting the penetration of oxygen and impurities such as hydrogen may be used for the insulator 222, the insulator 210, and an insulator 287. Note that an insulator containing an oxide of one or both of aluminum and hafnium can be used for the insulator 222 and the insulator 210. Aluminum oxide, hafnium oxide, an oxide containing aluminum and hafnium (hafnium aluminate), or the like is preferably used for the insulator containing an oxide of one or both of aluminum and hafnium.

As the insulator 220, the insulator 224, and the insulator 250, a single layer or a stacked layer of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, the insulators preferably contain silicon oxide, silicon oxynitride, or silicon nitride.

For example, when aluminum oxide, gallium oxide, hafnium aluminate, or hafnium oxide in each of the insulator 224 and the insulator 250 functioning as gate insulators, is in contact with the oxide 230, entry of silicon contained in silicon oxide or silicon oxynitride into the oxide 230 can be inhibited. In contrast, when silicon oxide or silicon oxynitride in each of the insulator 224 and the insulator 250 is in contact with the oxide 230, trap centers might be formed at the interface between aluminum oxide, gallium oxide, hafnium aluminate, or hafnium oxide and silicon oxide or silicon oxynitride. The trap centers can shift the threshold voltage of the transistor in the positive direction by trapping electrons in some cases.

The insulator 212, the insulator 216, the insulator 280, and the insulator 286 each preferably include an insulator having a low dielectric constant. For example, the insulator 212, the insulator 216, the insulator 280, and the insulator 286 each preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulator 212, the insulator 216, the insulator 280, and the insulator 286 each preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. Because of being thermally stable, silicon oxide or silicon oxynitride is combined with a resin, so that the stacked-layer structure can be thermally stable and have a high dielectric constant, for example. Examples of the resin include polyester, polyolefin, polyamide (e.g., nylon or aramid), polyimide, polycarbonate, and acrylic.

As the barrier layer 270, an insulator having a function of inhibiting the penetration of oxygen and impurities such as hydrogen may be used. For the barrier layer 270, a metal oxide such as aluminum oxide, hafnium oxide, hafnium aluminate, magnesium oxide, gallium oxide, germanium oxide, yttrium oxide, zirconium oxide, lanthanum oxide, neodymium oxide, or tantalum oxide; silicon nitride oxide; or silicon nitride may be used, for example.

### <<Conductor>>

For the conductors, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

Furthermore, a stack of a plurality of conductive layers formed with the above materials may be used. For example, a stacked-layer structure combining a material containing the above-described metal element and a conductive material containing oxygen may be employed. Furthermore, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

Note that when an oxide is used for the channel formation region of the transistor, a stacked-layer structure combining a material containing the above-described metal element and a conductive material containing oxygen is preferably used for the conductor functioning as the gate electrode. In this case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where a channel is formed. Furthermore, a conductive material containing the above-described metal element and nitrogen may be used. For example, a conductive material containing nitrogen, such as titanium nitride or tantalum nitride, may be used. Furthermore, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide where a channel is formed can be trapped in some cases. Alternatively, hydrogen entering from an external insulator or the like can be trapped in some cases.

For the conductor 260, the conductor 203, the conductor 205, the conductor 207, the conductor 252, and the conductor 256, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Furthermore, a semiconductor having high electrical conductivity, typified by polycrystalline silicon containing an impurity element such as phosphorus, or silicide such as nickel silicide may be used.

<Transistor Structure 2>

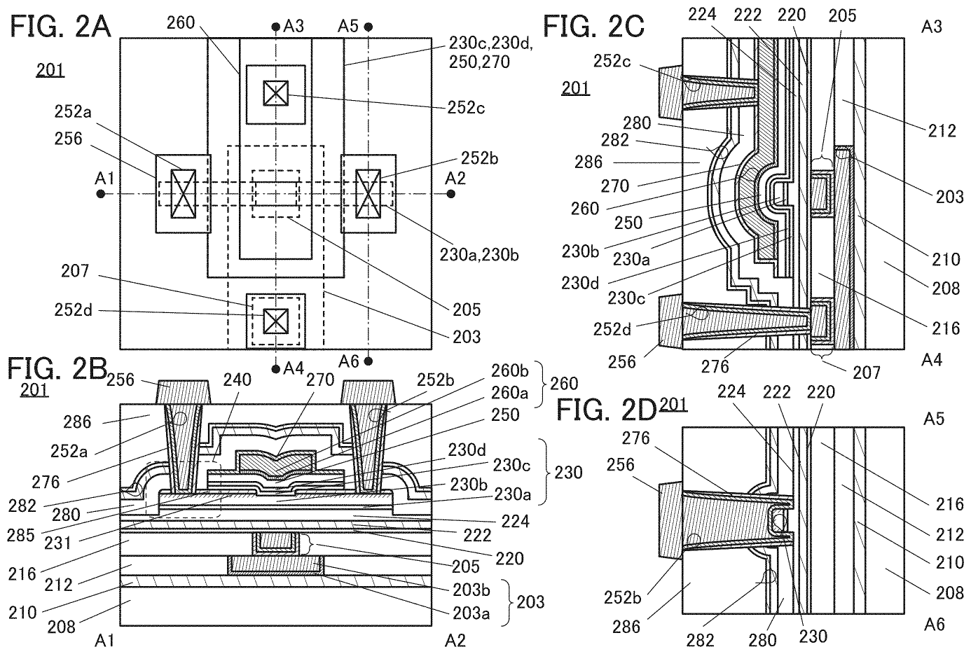

FIG. 2 illustrates a transistor of a different mode of the present invention. FIG. 2(A) is a top view of the transistor. FIG. 2(B) is a cross-sectional view of a portion indicated by dashed-dotted line A1-A2 in FIG. 2(A), i.e. a cross-sectional view of the transistor in the channel length direction. FIG. 2(C) is a cross-sectional view of a portion indicated by dashed-dotted line A3-A4 in FIG. 2(A), i.e. a cross-sectional view of a channel formation region of the transistor in the channel width direction. FIG. 2(D) is a cross-sectional view of a portion indicated by dashed-dotted line A5-A6 in FIG. 2(A), i.e. a cross-sectional view of a source region or a drain region of the transistor in the channel width direction. For simplification of the drawing, some components are not illustrated in the top view of FIG. 2(A).

As illustrated in FIG. 2(B), a transistor is different from the above transistor 200 in that layers 285 containing a metal element remain over the oxide 230b. The transistor is preferable because a step of removing the layers 285 is omitted, leading to simplification of the manufacturing process.

Each of the layers 285 is subjected to heat treatment after formed over the oxide 230b, whereby the resistance of the region 231 is reduced, which will be described in detail later. At this time, the resistance of the region 231 is probably reduced because oxygen contained in the region 231 is drawn to the layer 285 and diffused. Note that although FIG. 2(B) illustrates an example in which the region 231 is formed at the vicinity of an interface of the oxide 230b with the layer 285, this embodiment is not limited thereto. The region 231 may be extended from the interface between the oxide 230b and the layer 285 to the vicinity of an interface between the oxide 230b and the oxide 230a, or further extended to the oxide 230a.

In addition, a metal compound layer containing the metal element contained in the layer 285 and the component of the oxide 230 might be formed at the interface between the layer 285 and the oxide 230. The metal compound is preferably formed in the region 231 because the resistance of the region 231 is further reduced.

When the resistance of the region 231 is reduced, the layer 285 might be oxidized by extracting oxygen in the region 231. In the case where the layer 285 has conductivity after the resistance of the region 231 is reduced, the layer 285 can function as a source electrode or a drain electrode of the transistor 200. On the other hand, in the case where the layer 285 cannot obtain sufficient conductivity for an electrode due to oxidation or the like or the case where the layer 285 has an insulating property, at least part of the layer 285 needs to be removed in order to electrically connect the region 231 to the conductor 252a or the conductor 252b. In forming an opening in the insulator 280, the insulator 282, and the insulator 286, it is only necessary that an opening be also formed in the layer 285, and the conductor 252a or the conductor 252b be formed in the opening.

### <Transistor Structure 3>

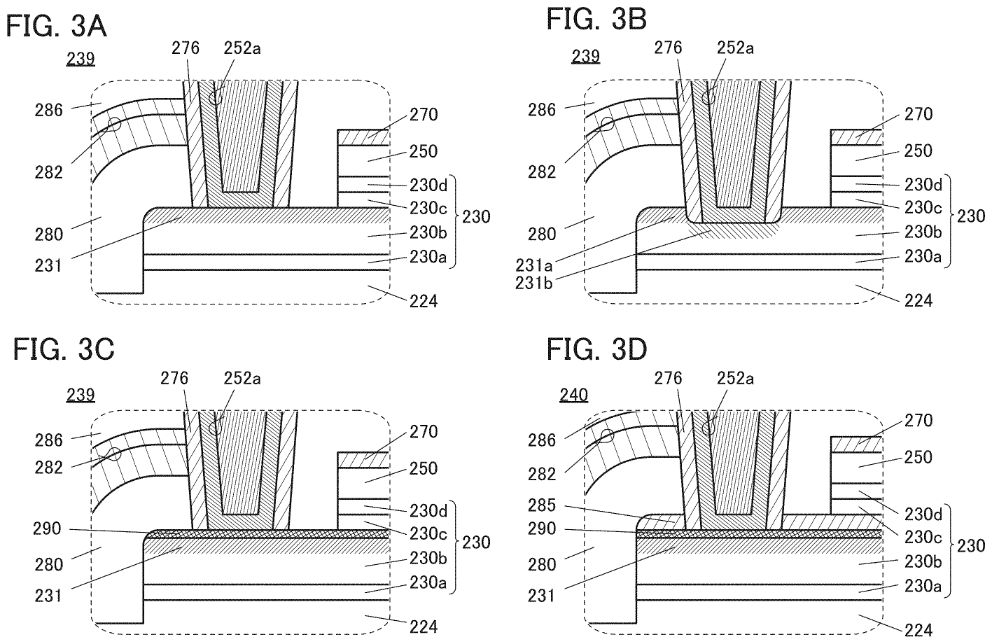

Connection portions between the oxide 230 and the conductor 252a or the conductor 252b in FIG. 1(B) and FIG. 2(B) are described with reference to FIG. 3(A) and FIG. 3(B). FIG. 3 is enlarged views of a region surrounded by a dashed line 239 in FIG. 1(B). Although description below will be made using the transistor 200 illustrated in FIG. 1, the same applies to the transistor 200 illustrated in FIG. 2.

The oxide 230b is exposed from the opening formed in the insulator 280, the insulator 282, and the insulating layer 286, and the conductor 252a formed in the opening is electrically connected to the oxide 230b. FIG. 3(A) illustrates a state where the conductor 252a and the oxide 230b are electrically connected to each other on the surface of or in the vicinity of the oxide 230b. The low-resistance region 231 is formed on the surface of the oxide 230b, and the conductor 252a is electrically connected to the region 231.

In FIG. 3(B), the oxide 230b is partly etched and a recessed portion is formed when the opening is formed in the insulator 280, the insulator 282, and the insulator 286. In addition, a state is illustrated where, in the recessed portion, the conductor 252a is formed so as to be in contact with a portion where a region 231a, a low-resistance region, is removed.

At this time, when the recessed portion of the oxide 230b is in contact with the conductor 252a, the resistance of the recessed portion might also be reduced and a region 231b is formed. The resistance of the region 231b in contact with the conductor 252a is reduced when the metal element used for the conductor 252a acts in a manner similar to that of the layer 285 containing a metal element. Thus, even when the region 231a is removed partly or entirely in the opening in formation of the opening, the resistance of the region 231b is reduced owing to the formation of the conductor 252a and treatment involving heating in a subsequent step; accordingly, contact resistance between the conductor 252a and the oxide 230 can be reduced.

### <Transistor Structure 4>

In the above transistor structures, examples in each of which a compound layer (another layer) is formed at an interface between the oxide 230 and the layer containing a metal element (the layer 285) are described with reference to FIG. 3(C) and FIG. 3(D). FIG. 3(C) is an enlarged view of a region surrounded by the dashed line 239 in FIG. 1(B). FIG. 3(D) is an enlarged view of a region surrounded by a dashed line 240 in FIG. 2(B).

As illustrated in FIG. 3(C), a compound layer 290 is formed on a top surface of the oxide 230b, and the conductor 252a (the conductor 252b) is electrically connected to the oxide 230 through the compound layer 290. The compound layer 290 contains the component contained in the oxide 230b and a metal element, and thus has conductivity. Moreover, the compound layer may contain one or both of oxygen and nitrogen, in addition to the above.

The compound layer 290 is formed in such a manner that a layer containing a metal element is formed in contact with the oxide 230 and then subjected to heat treatment. The heat treatment is preferably performed in an atmosphere containing nitrogen. The heat treatment may be performed in an inert gas atmosphere, an oxygen atmosphere, an oxidation gas atmosphere, or a mixed gas atmosphere of the above gases.

The layer containing a metal element is removed after the above heat treatment. Through the above process, the compound layer 290 is formed over the oxide 230b, and the oxide 230c is formed so as to cover part of the compound layer 290.

In contrast, in FIG. 3(D), the compound layer 290 is formed on the top surface of the oxide 230b, and the layer 285 containing a metal element is provided over the compound layer. The insulator 286, the insulator 282, the insulator 280, and the layer 285 have an opening exposing the compound layer 290, and the conductor 252a (the conductor 252b) provided in the opening is electrically connected to the oxide 230 through the compound layer 290. The compound layer 290 contains the component contained in the oxide 230b and part of the metal element contained in the layer 285, and thus has conductivity. Moreover, the compound layer may contain one or both of oxygen and nitrogen, in addition to the above.

The compound layer 290 might have a function of inhibiting penetration of oxygen. At this time, oxidation of the layer 285 due to oxygen contained in the oxide 230b is inhibited, and the layer 285 has conductivity in some cases.

In the case where the layer 285 has conductivity, the opening is not necessarily formed. In this case, the conductor 252a (the conductor 252b) is electrically connected to the oxide 230 through the layer 285 and the compound layer 290.

The compound layer 290 is formed in such a manner that the layer 285 is formed in contact with the oxide 230 and then subjected to heat treatment. The heat treatment is preferably performed in an atmosphere containing nitrogen. The heat treatment may be performed in an inert gas atmosphere, an oxygen atmosphere, an oxidation gas atmosphere, or a mixed gas atmosphere of the above gases. The layer 285 is oxidized through the heat treatment, and the conductivity is reduced in some cases. Moreover, the layer 285 might serve as an insulator.

Part of the layer 285 probably becomes a compound after reacting with the component contained in the oxide 230 through the above heat treatment. In addition, part of the oxide 230 might also become a compound after reacting with the component contained in the layer 285 through the vapor heat treatment. Through the above process, the compound layer 290 is formed at the interface between the oxide 230b and the layer 285.

### <Method for Manufacturing Semiconductor Device>

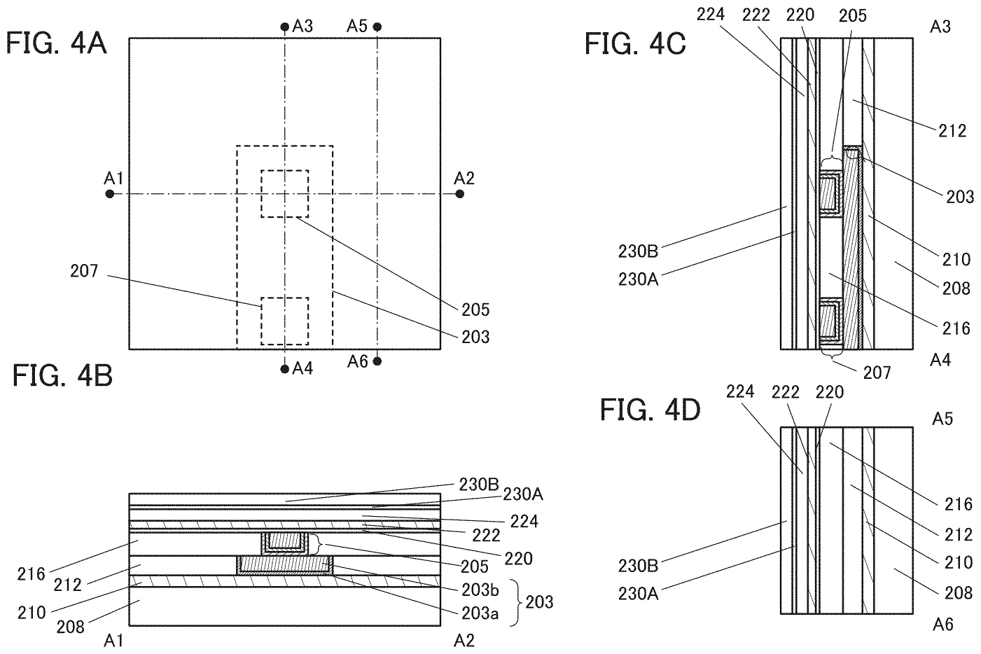

Next, a method for manufacturing a semiconductor device including the transistor 200 of the present invention will be described with reference to FIG. 4 to FIG. 13. In FIG. 4 to FIG. 13, (A) of each drawing is a top view. Moreover, (B) of each drawing is a cross-sectional view corresponding to a portion indicated by dashed-dotted line A1-A2 in (A). Furthermore, (C) of each drawing is a cross-sectional view corresponding to a portion indicated by dashed-dotted line A3-A4 in (A). Furthermore, (D) of each drawing is a cross-sectional view corresponding to a portion indicated by dashed-dotted line A5-A6 in (A).

First, a substrate (not illustrated) is prepared, and the insulator 208 is deposited over the substrate. The insulator 208 can be deposited by a sputtering method, a chemical vapor deposition (CVD) method, a molecular beam epitaxy (MBE) method, a pulsed laser deposition (PLD) method, an ALD (Atomic Layer Deposition) method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. In contrast, such plasma damage is not caused in the case of using a thermal CVD method that does not use plasma, and thus the yield of a semiconductor device can be increased. In addition, a thermal CVD method does not cause plasma damage during deposition, so that a film with few defects can be obtained.

An ALD method is also a deposition method which enables less plasma damage to an object. Also an ALD method does not cause plasma damage during deposition, so that a film with few defects can be obtained.

Unlike in a deposition method in which particles ejected from a target or the like are deposited, a CVD method and an ALD method are deposition methods in which a film is formed by reaction at a surface of an object. Thus, a CVD method and an ALD method are deposition methods that are less likely to be influenced by the shape of an object and thus have favorable step coverage. In particular, an ALD method has excellent step coverage and excellent thickness uniformity, and is thus suitable for the case of covering a surface of an opening with a high aspect ratio, for example. On the other hand, an ALD method has a relatively low deposition rate, and is thus preferably used in combination with another deposition method with a high deposition rate such as a CVD method, in some cases.

A CVD method or an ALD method enables control of composition of a film to be obtained with a flow rate ratio of the source gases. For example, by a CVD method or an ALD method, a film with a desired composition can be deposited by adjusting the flow ratio of the source gases. Moreover, by a CVD method or an ALD method, by changing the flow rate ratio of the source gases during the deposition, a film whose composition is continuously changed can be deposited. In the case of depositing while changing the flow rate ratio of the source gases, as compared with the case of depositing with the use of a plurality of deposition chambers, time taken for the deposition can be shortened because time taken for transfer and pressure adjustment is omitted. Thus, productivity of semiconductor devices can be improved in some cases.

In this embodiment, for the insulator 208, silicon oxide is deposited by a CVD method.

Next, the insulator 210 is formed over the insulator 208. In this embodiment, for the insulator 210, aluminum oxide is deposited by a sputtering method. The insulator 210 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Next, the insulator 212 is formed over the insulator 210. The insulator 212 can be formed by a sputtering method, a CVD method, an MBE method, a PLD method, an ALD method, or the like. In this embodiment, for the insulator 212, silicon oxide or silicon oxynitride is formed by a CVD method.

Subsequently, a resist mask is formed over the insulator 212 by a lithography method or the like. Then, an unnecessary portion of the insulator 212 is removed. After that, an opening can be formed by removal of the resist mask.

Here, a method for processing a film to be processed is described. To process a film to be processed finely, a variety of microfabrication techniques can be used. For example, it is possible to use a method in which a resist mask formed by a lithography process or the like is subjected to slimming treatment. Alternatively, the film to be processed may be etched in such a manner that a dummy pattern is formed by a lithography process or the like, the dummy pattern is provided with a sidewall and then removed, and the remaining sidewall is used as a resist mask. In order to achieve a high aspect ratio, anisotropic dry etching is preferably used for etching of the film to be processed. Alternatively, a hard mask formed of an inorganic film or a metal film may be used.

For light used to form the resist mask, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Moreover, exposure may be performed by liquid immersion light exposure technique. Furthermore, as the light used for the exposure, extreme ultra-violet (EUV) light or X-rays may be used. Furthermore, instead of the light used for the exposure, an electron beam can also be used. It is preferable to use extreme ultra-violet light, X-rays, or an electron beam because extremely minute processing can be performed. Note that in the case of performing exposure by scanning of a beam such as an electron beam, a photomask is not needed.

An organic resin film having a function of improving the adhesion between the film to be processed and a resist film may be formed before the resist film serving as a resist mask is formed. The organic resin film can be formed to provide a flat surface by covering a step under the film by, for example, a spin coating method, and thus can reduce variation in thickness of the resist mask provided over the organic resin film. In the case of fine processing, in particular, a material having a function as a film preventing reflection of light used for the exposure is preferably used for the organic resin film. Examples of the organic resin film having such a function include a BARC (Bottom Anti-Reflection Coating) film. It is only necessary that the organic resin film be removed at the same time as removal of the resist mask or after the resist mask is removed.

A hard mask formed of an insulator or a conductor may be used instead of the resist mask. In the case where a hard mask is used, a hard mask with a desired shape can be formed by forming an insulating film or a conductive film to be the material of the hard mask over the conductive film, forming a resist mask thereover, and then etching the material of the hard mask.

For the processing, a dry etching method or a wet etching method can be employed. The processing by a dry etching method is suitable for microfabrication.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, a structure may be employed in which different high-frequency power sources are applied to one of the parallel plate type electrodes. Alternatively, a structure may be employed in which high-frequency power sources with the same frequency are applied to the parallel plate type electrodes. Alternatively, a structure may be employed in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In the case where a hard mask is used for etching of the conductive film, the etching treatment may be performed after the resist mask used for formation of the hard mask is removed or while the resist mask remains. In the latter case, the resist mask might disappear during the etching. The hard mask may be removed by etching after the etching of the conductive film. In contrast, the hard mask does not need to be removed in the case where the material of the hard mask does not affect a subsequent step or the material of the hard mask can be utilized in the subsequent step.

Next, a conductive film to be the conductor 203a and the conductor 203b is formed over the opening and the insulator 212. The conductive film can be deposited by, for example, a sputtering method, an evaporation method, or a CVD method (including a thermal CVD method, an MOCVD method, a PECVD method, and the like). It is preferable to use a thermal CVD method, an MOCVD method, or an ALD method in order to reduce plasma damage.

Then, an unnecessary portion of the conductive film is removed. For example, part of the conductive film is removed by etch-back processing, chemical mechanical polishing (CMP) processing, or the like until the insulator 212 is exposed, whereby the conductor 203a and the conductor 203b are formed. In some cases, the conductor 203a and the conductor 203b are collectively referred to as a conductor 203. At this time, the insulator 212 can be used as a stopper layer, and the thickness of the insulator 212 is reduced in some cases.

Here, the CMP processing is a method for planarizing a surface of an object to be processed by a combination of chemical and mechanical actions. More specifically, the CMP processing is a method in which a polishing cloth is attached to a polishing stage, the polishing stage and the object to be processed are each rotated or swung while a slurry (an abrasive) is supplied between the object to be processed and the polishing cloth, and the surface of the object to be processed is polished by chemical reaction between the slurry and the surface of the object to be processed and by action of mechanical polishing between the polishing cloth and the object to be processed.

Note that the CMP processing may be performed only once or a plurality of times. When the CMP processing is performed a plurality of times, it is preferable that first polishing be performed at a high polishing rate and then final polishing be performed at a low polishing rate. In this manner, polishing processes with different polishing rates may be used in combination.

Next, the insulator 216 is formed over the insulator 212 and the conductor 203. The insulator 216 can be formed by a sputtering method, a CVD method, an MBE method, a PLD method, an ALD method, or the like. In this embodiment, for the insulator 216, silicon oxide or silicon oxynitride is formed by a CVD method.

Subsequently, openings are formed in the insulator 216 by a lithography method or the like. At this time, the openings are formed so that at least parts of the conductor 203 are exposed.

Then, the conductor 205 and the conductor 207 are formed so as to be embedded in the openings. The conductor 205 and the conductor 207 can be formed in a manner similar to that of the conductor 203. In this embodiment, the conductor 205 and the conductor 207 each having a three-layer structure are formed in such a manner that tantalum nitride, titanium nitride, and tungsten are formed by a sputtering method or a CVD method and their unnecessary portions are removed by CMP processing; however, this embodiment is not limited thereto. The conductor 205 and the conductor 207 may each have a single-layer structure, a two-layer structure, or a structure of four or more layers. For example, a conductor having a two-layer structure in which tantalum nitride or titanium nitride, and tungsten or copper are stacked may be used.

In the case where CMP processing is used to form the conductor 205 and the conductor 207, the insulator 216 might become thinner.

The method for forming the conductor 203, the conductor 205, and the conductor 207 is not limited to the above. The conductive film to be the conductor 203 may be formed over the insulator 210, the conductor 203 may be formed by processing the conductive film by a lithography method, the insulator 212 may be formed so as to cover the conductor 203, and an unnecessary portion of the insulator 212 may be removed. Similarly, the following method may also be employed. A conductive film to be the conductor 205 and the conductor 207 is formed over the insulator 212 and the conductor 203, the conductor 205 and the conductor 207 are formed by processing the conductive film by a lithography method, the insulator 216 is formed so as to cover the conductor 205, and an unnecessary portion of the insulator 216 is removed.

Next, the insulator 220 is deposited over the insulator 216, the conductor 205, and the conductor 207. The insulator 220 can be deposited by a sputtering method, a CVD method, an MBE method, a PLD method, an ALD method, or the like.

For the insulator 220, silicon oxide or silicon oxynitride can be used. The thickness of the insulator 220 is greater than or equal to 1 nm and less than or equal to 10 nm, preferably greater than or equal to 1 nm and less than or equal to 5 nm.

Next, the insulator 222 is deposited over the insulator 220. The insulator 222 can be deposited by a sputtering method, a CVD method, an MBE method, a PLD method, an ALD method, or the like.

An insulator containing an oxide of one or both of aluminum and hafnium is preferably used as the insulator 222. Aluminum oxide, hafnium oxide, an oxide containing aluminum and hafnium (hafnium aluminate), or the like is preferably used for the insulator containing an oxide of one or both of aluminum and hafnium. The insulator 222 is preferably formed by an ALD method. The insulator 222 deposited by an ALD method has a barrier property against oxygen, hydrogen, and water. When the insulator 222 has a barrier property against hydrogen and water, hydrogen and water contained in structure bodies provided around the transistor 200 are not diffused into the transistor 200, and generation of oxygen vacancies in the oxide 230 can be inhibited.

For the insulator 222, hafnium oxide is used, for example. The thickness of the insulator 222 is greater than or equal to 1 nm and less than or equal to 30 nm, preferably greater than or equal to 1 nm and less than or equal to 10 nm, further preferably greater than or equal to 1 nm and less than or equal to 5 nm.

Furthermore, in the formation of the insulator 222, the insulator 222 is formed while the substrate is heated, so that heat treatment for the substrate that is necessary in a subsequent step can be omitted. That is, the formation of the insulator 222 can also serve as heat treatment for the substrate.

Subsequently, heat treatment is preferably performed. The heat treatment may be performed at 250° C. or higher and 650° C. or lower, preferably 300° C. or higher and 500° C. or lower, further preferably 320° C. or higher and 450° C. or lower. The heat treatment is performed in a nitrogen or inert gas atmosphere, an oxygen atmosphere, or an atmosphere containing an oxidizing gas at 10 ppm or more, 1% or more, or 10% or more. The heat treatment may be performed under a reduced pressure. Alternatively, the heat treatment may be performed in such a manner that heat treatment is performed in a nitrogen or inert gas atmosphere, and then another heat treatment is performed in an oxygen atmosphere or an atmosphere containing an oxidizing gas at 10 ppm or more, 1% or more, or 10% or more in order to compensate for released oxygen.

Through the above heat treatment, impurities such as hydrogen and water contained in the insulator 220 and the insulator 222 can be removed, for example. Moreover, by performing heat treatment in an oxygen atmosphere or an atmosphere containing an oxidizing gas at 10 ppm or more, 1% or more, or 10% or more, oxygen can be supplied to the insulator 220 and the insulator 222 in some cases.

Alternatively, as the heat treatment, plasma treatment containing oxygen may be performed under a reduced pressure. The plasma treatment containing oxygen is preferably performed using an apparatus including a power source for generating high-density plasma using microwaves, for example. Alternatively, a power source for applying an RF (Radio Frequency) to a substrate side may be included. The use of high-density plasma enables high-density oxygen radicals to be produced, and application of the RF to the substrate side allows oxygen radicals generated by the high-density plasma to be efficiently introduced into the insulator 222. Alternatively, after plasma treatment containing an inert gas is performed with this apparatus, plasma treatment containing oxygen may be performed to compensate for released oxygen. Note that the above heat treatment is not necessarily performed in some cases.

This heat treatment can also be performed before deposition of the insulator 220 and after deposition of the insulator 220. Although the conditions for the above-described heat treatment can be used for the heat treatment, heat treatment before and after deposition of the insulator 220 is preferably performed in an atmosphere containing nitrogen.

In this embodiment, the heat treatment is performed in such a manner that treatment is performed at 400° C. in a nitrogen atmosphere for one hour after the deposition of the insulator 222, and then another treatment is successively performed at 400° C. in an oxygen atmosphere for one hour.

Next, the insulator 224 is deposited over the insulator 222. The insulator 224 can be deposited by a sputtering method, a CVD method, an MBE method, a PLD method, an ALD method, or the like. For the insulator 224, silicon oxide or silicon oxynitride can be used, for example. The thickness of the insulator 224 is greater than or equal to 1 nm and less than or equal to 30 nm, preferably greater than or equal to 1 nm and less than or equal to 10 nm, further preferably greater than or equal to 1 nm and less than or equal to 5 nm.

In the case where heat treatment is not performed after the formation of the insulator 222, the insulator 222 and the insulator 224 may be successively formed. Moreover, the insulator 220, the insulator 222, and the insulator 224 may be successively formed.

The above heat treatment may be performed after the insulator 224 is deposited. Through the heat treatment, impurities such as hydrogen and water contained in the insulator 224 can be removed, for example.

Next, an oxide film 230A to be the oxide 230a and an oxide film 230B to be the oxide 230b are formed over the insulator 224 (see FIG. 4).

The oxide film 230A and the oxide film 230B can be formed by a sputtering method, a CVD method, an MBE method, a PLD method, an ALD method, or the like.

In the case where the oxide film 230A and the oxide film 230B are formed by a sputtering method, for example, oxygen or a mixed gas of oxygen and a rare gas is used as a sputtering gas. By increasing the proportion of oxygen contained in the sputtering gas, the amount of excess oxygen in the oxide films to be deposited can be increased. Moreover, in the case where the above oxide films are formed by a sputtering method, the above In-M-Zn oxide target can be used.

In particular, part of oxygen contained in the sputtering gas is supplied to the insulator 224 in some cases, at the formation of the oxide film 230A. Note that it is only necessary that the proportion of oxygen contained in the sputtering gas for the oxide film 230A be higher than or equal to 70%, preferably higher than or equal to 80%, and further preferably 100%.

The thickness of the oxide film 230A is greater than or equal to 1 nm and less than or equal to 20 nm, preferably greater than or equal to 3 nm and less than or equal to 10 nm. In this embodiment, the oxide film 230A with a thickness of 5 nm is formed using a target of In:Ga:Zn=1:3:4 [atomic ratio] by a sputtering method. The thickness of the oxide film 230B is greater than or equal to 10 nm and less than or equal to 50 nm, preferably greater than or equal to 10 nm and less than or equal to 30 nm, further preferably greater than or equal to 15 nm and less than or equal to 25 nm. In this embodiment, the oxide film 230B with a thickness of 15 nm is deposited using a target with In:Ga:Zn=4:2:4.1 [atomic ratio] by a sputtering method. Note that the oxide films are preferably formed by appropriate selection of deposition conditions and an atomic ratio to have characteristics required for the oxide 230.

It is preferable that, after the formation of the oxide film 230A, the oxide film 230B be formed successively without being exposed to an air atmosphere. When a multi-chamber deposition apparatus is used for the formation of the oxide film 230A and the formation of the oxide film 230B, a substrate over which the oxide films are formed can be in a reduced-pressure atmosphere from the beginning of the formation of the oxide film 230A to the end of the formation of the oxide film 230B, so that the oxide film 230B can be formed over the oxide film 230A without exposing the surface of the oxide film 230A to an air atmosphere. By forming the oxide film 230A and the formation of the oxide film 230B successively, contamination of the interface between the oxide film 230A and the oxide film 230B can be prevented, and a semiconductor device using such oxide films can have favorable characteristics and high reliability.

In the case where the oxide film 230A and the oxide film 230B are formed by a sputtering method, for example, oxygen or a mixed gas of oxygen and a rare gas is used as a sputtering gas. By increasing the proportion of oxygen contained in the sputtering gas, the amount of excess oxygen in the oxide films to be deposited can be increased. Moreover, in the case where the above oxide films are formed by a sputtering method, the above In-M-Zn oxide target can be used.

In the case where the oxide film 230A and the oxide film 230B are formed by a sputtering method, an oxygen-deficient oxide semiconductor is formed when deposition is performed with the proportion of oxygen contained in the sputtering gas being higher than or equal to 1% and lower than or equal to 30%, preferably higher than or equal to 5% and lower than or equal to 20%. In a transistor using an oxygen-deficient oxide semiconductor, relatively high field-effect mobility can be obtained.

In this embodiment, the oxide film 230A is deposited using a target with In:Ga:Zn=1:3:4 [atomic ratio] by a sputtering method, and the oxide film 230B is deposited using a target with In:Ga:Zn=4:2:4.1 [atomic ratio] by a sputtering method. In addition, the oxide film 230A and the oxide film 230B are successively formed without being exposed to an air atmosphere with the use of a multi-chamber sputtering apparatus. Note that the oxide films are preferably formed by appropriate selection of deposition conditions and an atomic ratio to have characteristics required for the oxide 230.

Next, heat treatment may be performed. For the heat treatment, the conditions for the above-described heat treatment can be used. Through the heat treatment, impurities such as hydrogen and water in the oxide film 230A and the oxide film 230B can be removed, for example. In this embodiment, treatment is performed at 400° C. in a nitrogen atmosphere for one hour, and successively another treatment is performed at 400° C. in an oxygen atmosphere for one hour.

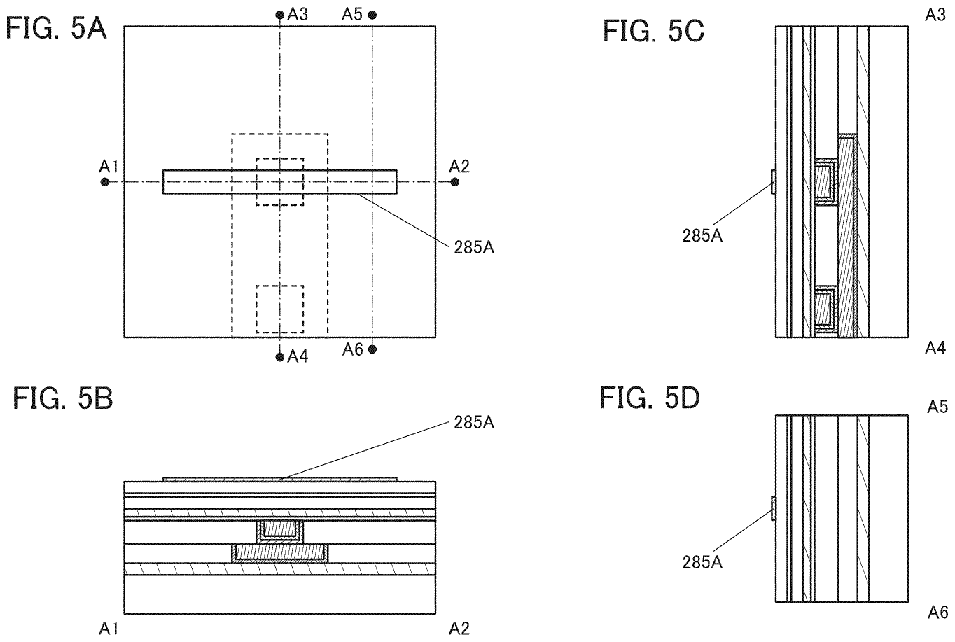

Subsequently, a film 285A containing a metal element is formed over the oxide film 230B (see FIG. 5). It is preferable that the film 285A be used as a hard mask in processing the oxide film 230A and the oxide film 230B. Note that the film 285A may have a thickness of greater than or equal to 0.5 nm and less than or equal to 5 nm, preferably greater than or equal to 1 nm and less than or equal to 3 nm. For the film 285A, a metal layer containing a metal element, a nitride layer containing a metal element, or an oxide layer containing a metal element (a layer containing a metal element) is used. For example, the film 285A is a film containing a metal element such as aluminum, ruthenium, titanium, tantalum, tungsten, or chromium. Note that the film 285A can be deposited by a sputtering method, a CVD method, an MBE method, a PLD method, an ALD method, or the like.

For example, the film 285A can be obtained in such a manner that a film is formed using a target containing titanium and aluminum by a sputtering method and processed into an island shape by a lithography method. The ratio of titanium to aluminum contained in the target at this time ranges from 1:4 to 4:1, preferably from 2:3 to 3:2, and further preferably 1:1. The gas used for forming the film 285A preferably contains nitrogen or oxygen. For example, a mixed gas of nitrogen and argon or a mixed gas of oxygen and argon is preferably used. The film 285A thus formed can be referred to as TiAlNₓ (or TiAlₓN_{y} (hereinafter x and y are any numbers)) or TiAlOₓ (or TiAlₓO_{y}) because titanium (Ti) and aluminum (Al) and further nitrogen (N) or oxygen (O) are contained.

For the film containing a metal element, the following can be used in addition to TiAlNₓ and TiAlOₓ: aluminum nitride or aluminum oxide containing aluminum; TaAlNₓ (or TaAlₓN_{y}) or TaAlOₓ (or TaAlₓO_{y}) containing tantalum (Ta) and aluminum; or the like.

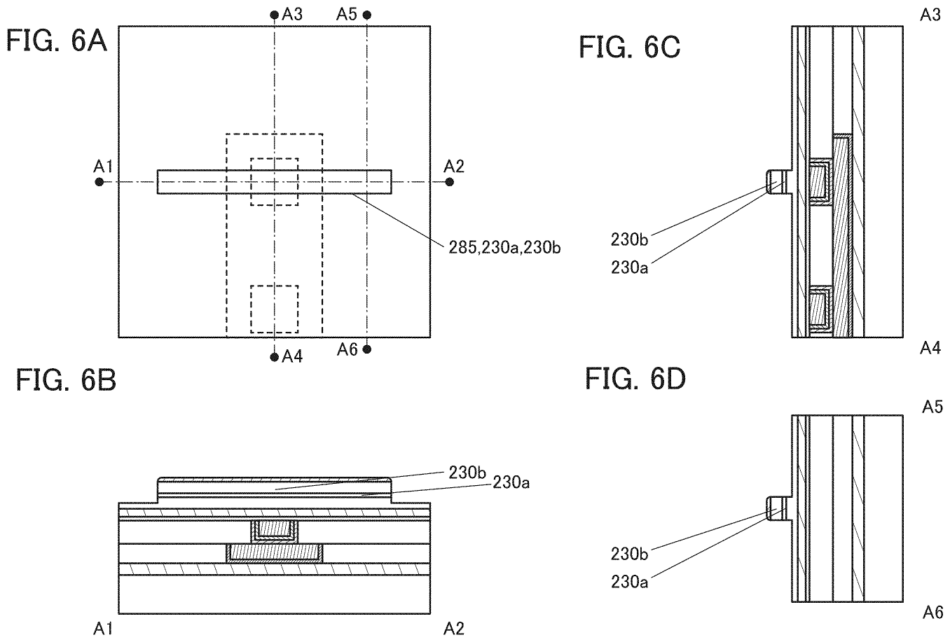

Subsequently, the oxide film 230A and the oxide film 230B are processed using the island-shaped film 285A as a mask to form the island-shaped oxide 230a and the island-shaped oxide 230b (see FIG. 6). At this time, a mask used for processing the film 285A may be used to process the oxide film 230A and the oxide film 230B, which is not illustrated.

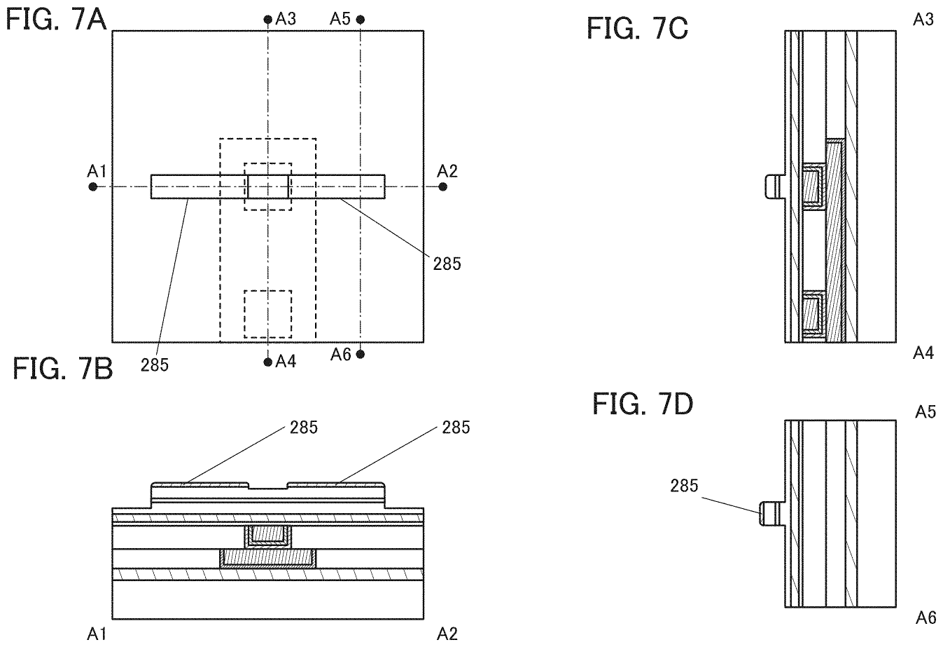

Then, the film 285A is processed by a lithography method to form the layers 285 over the oxide 230b (see FIG. 7).

Subsequently, heat treatment is performed. The heat treatment may be performed at 250° C. or higher and 650° C. or lower, preferably 300° C. or higher and 500° C. or lower, further preferably 320° C. or higher and 450° C. or lower. Note that the heat treatment is performed in a nitrogen or inert gas atmosphere. Moreover, the heat treatment may be performed under a reduced pressure.

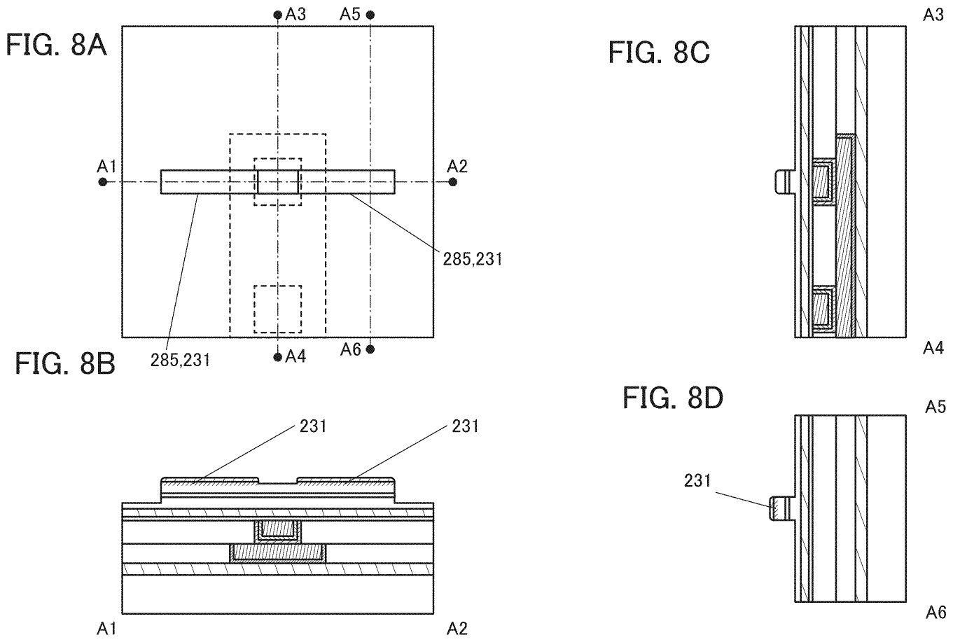

Through the heat treatment in an atmosphere containing nitrogen, oxygen contained in the oxide 230, in particular in each of the regions 231 in the vicinity of the interfaces with the layers 285, might be absorbed by the layer 285. As a result, the resistance of the region 231 is reduced (see FIG. 8). In contrast, in some cases, the layer 285, which is oxidized owing to oxygen absorbed from the region 231, becomes a high-resistant insulator. The layer 285 whose resistance is increased may be used as an interlayer film.

Although FIG. 8 illustrates an example in which the region 231 is formed in the vicinity of the interface of the oxide 230 with the layer 285, the present invention is not limited thereto. The region 231 may be formed in a region of the oxide 230b which overlaps with the layer 285. The region 231 may be formed in a region of the oxide 230a and the oxide 230b which overlaps with the layer 285. In other words, the region 231 may be extended from the interfaces between the oxide 230b and the layer 285 to an interface between the oxide 230b and the oxide 230a or from the interface between the oxide 230b and the layer 285 to an interface between the oxide 230a and the insulator 224.

Moreover, in the case where a region having conductivity remains in the layer 285, heat treatment in an oxidizing gas atmosphere oxidizes the region, whereby the layer 285 becomes a high-resistant insulator. The layer 285 that remains as an insulator can function as an interlayer film.

In that case, the heat treatment may be performed in such a manner that heat treatment is performed in a nitrogen or inert gas atmosphere, and then another heat treatment is performed in an atmosphere containing an oxidizing gas at 10 ppm or more, 1% or more, or 10% or more. The heat treatment may be performed at 250° C. or higher and 650° C. or lower, preferably 300° C. or higher and 500° C. or lower, further preferably 320° C. or higher and 450° C. or lower.

The layer 285 is partly oxidized owing to oxygen contained in the region 231 of the oxide 230 through the heat treatment in the nitrogen or inert gas atmosphere, and then the layer 285 is entirely oxidized through the heat treatment in the oxidizing gas atmosphere.

In the above step of forming the layer 285 or the heat treatment, oxygen contained in the region 231 is absorbed by the layer 285, whereby oxygen vacancies might be generated in the region 231. Entry of hydrogen in the oxide 230 to the oxygen vacancy increases the carrier density of the region 231. Thus, the region 231 becomes a low-resistance n-type region.

In the case where hydrogen in the oxide 230 diffuses into the regions 231 and enters oxygen vacancies existing in the region 231, the hydrogen becomes relatively stable. Hydrogen existing in the region of the transistor 200 where the channel is formed is diffused through heat treatment at 250° C. or higher, so that the hydrogen enters oxygen vacancies existing in the region 231 and becomes relatively stable. Thus, through the heat treatment, the resistances of the regions 231 are further reduced, and the channel formation region is highly purified (reduction of impurities such as water or hydrogen) and the resistance of the channel formation region is further increased.

Furthermore, the metal element which is a component of the layer 285 is diffused from the layer 285 into the oxide 230 or the metal element which is a component of the oxide 230 is diffused into the layer 285, and a metal compound is formed to have a low resistance at an interface between the oxide 230 and the layer 285. The metal compound formed at the interface between the oxide 230 and the layer 285 becomes relatively stable, so that a highly reliable semiconductor device can be provided. The metal compound is preferably formed in part of the region 231.

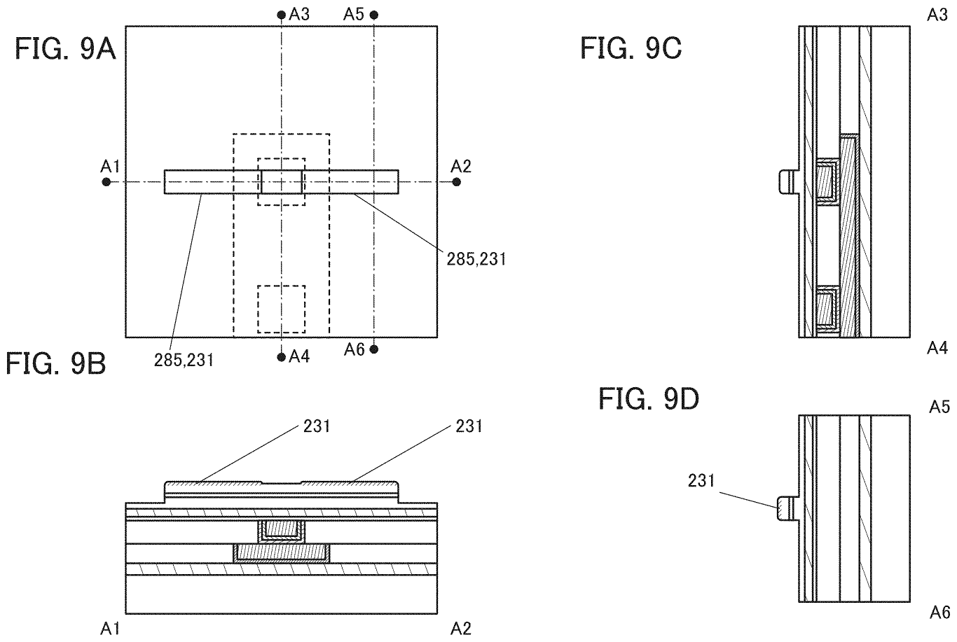

Next, the layer 285 is removed (see FIG. 9). For example, as a method for removing the layer 285, a dry etching method or a wet etching method can be used. The layer 285 are preferably removed because the unevenness on the oxide 230 is reduced and the planarity is improved. That is, the difference between the top surface of the region of the oxide 230b where the channel is formed and the top surface of the region 231 is smaller than the difference between the top surface of the region of the oxide 230b where the channel is formed and the top surface of the layer 285. Thus, the insulator 250 and the conductor 260 formed in subsequent steps are formed over the oxide 230 having improved planarity; therefore, defects such as coverage failure and concentration of electric field between the conductor 260 and the oxide 230 are inhibited. Moreover, removal of the layers 285 can remove hydrogen in the oxide 230 absorbed by the layers 285 at the same time. Thus, hydrogen, which is an impurity, in the transistor 200 can be reduced. The semiconductor device manufactured through such steps has favorable characteristics and improved reliability.

Note that the layer 285 is not necessarily removed. In the case where the resistance of the layer 285 is sufficiently low, the layer 285 can be used as a conductor functioning as a source electrode or a drain electrode. Furthermore, in the case where the layer 285 is an insulator, or have a high resistance value and cannot be used as the conductor, the layer 285 can be made to function as an interlayer film.

In addition, the region 231 may be formed by addition of the above-described element that forms an oxygen vacancy or element that is bonded to an oxygen vacancy to the oxide 230. For the addition of the element, for example, an ion implantation method by which an ionized source gas is subjected to mass separation and then added, an ion doping method by which an ionized source gas is added without mass separation, a plasma immersion ion implantation method, or plasma treatment can be used. At this time, the element can be selectively added to the region 231 in such a manner that a dummy gate is provided over the region of the oxide 230 where the channel is formed and the element is added using the dummy gate as a mask.

The dummy gate may be formed over the film 285A after the oxide 230a and the oxide 230b are formed, or may be formed so as to be in contact with the oxide 230b after the layer 285 is formed. Alternatively, after the region 231 is formed through the heat treatment after the formation of the layer 285, the dummy gate may be formed and the element may be added. Further alternatively, the formation of the region 231 using the layer 285 is not necessarily performed, and in that case, the film 285A is not necessarily formed. At this time, another mask is provided over the oxide film 230B so that the oxide 230a and the oxide 230b can be processed using the mask. The region 231 can be formed in such a manner that the oxide 230a and the oxide 230b are formed, the dummy gate is formed over the oxide 230b, and then the element is added.

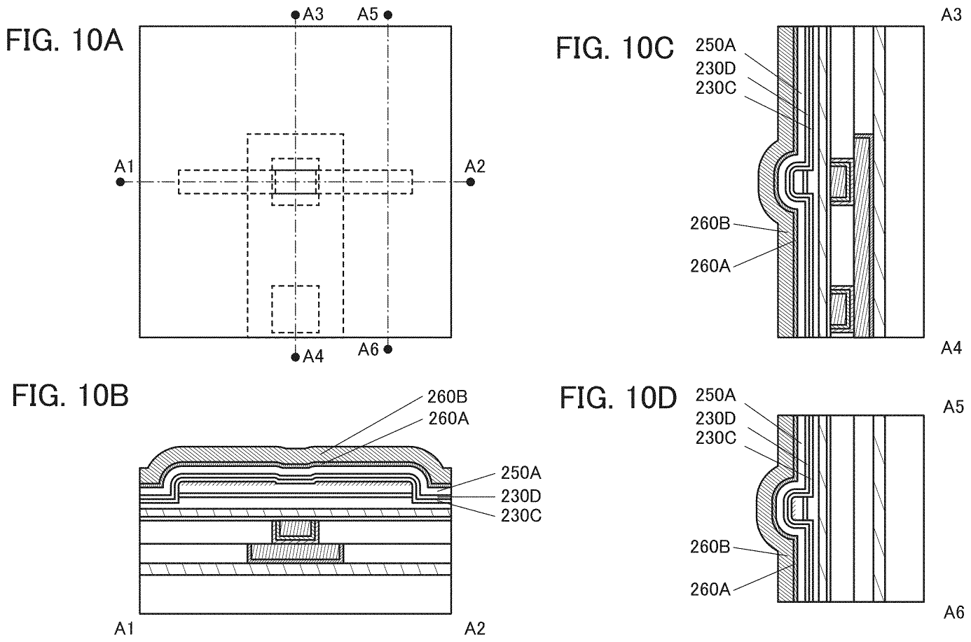

Next, an oxide film 230C, an oxide film 230D, an insulating film 250A, the conductive film 260A, and a conductive film 260B are formed (see FIG. 10).

For the oxide film 230C, for example, an oxide like the oxide 230b is used. In addition, for the oxide film 230D, an oxide containing excess oxygen is used like the oxide 230a. When an oxide containing excess oxygen is used for the oxide film 230D, oxygen can be supplied to the oxide 230b and the oxide 230c by subsequent heat treatment.

Furthermore, at the time of the formation of the oxide film 230C and the oxide film 230D, part of oxygen contained in the sputtering gas is supplied to the insulator 224 to form an excess-oxygen region in some cases, as in the case of the oxide 230a. Part of oxygen supplied to the insulator 224 reacts with hydrogen remaining in the insulator 224 to produce water, which is released from the insulator 224 by subsequent heat treatment. Thus, the concentration of hydrogen in the insulator 224 can be reduced.

Note that after the formation of the oxide film 230C and the oxide film 230D, one or both of oxygen doping treatment and heat treatment may be performed. By performing the heat treatment, oxygen contained in the oxide 230a and the oxide film 230D can be supplied to the oxide 230b and the oxide film C. By supplying oxygen to the oxide 230b and the oxide film C, oxygen vacancies in the oxide 230b and the oxide film C can be reduced. Thus, in the case where an oxygen-deficient oxide semiconductor is used as the oxide 230b and the oxide film C, and a semiconductor containing excess oxygen is preferably used as the oxide film D.

A top surface and side surfaces of the region of the oxide 230b where the channel is formed are covered with the oxide film 230C and the oxide film 230D. In such a manner, the oxide 230b can be surrounded by the oxide 230a, the oxide film 230C, and the oxide film 230D. By surrounding the oxide 230b by the oxide 230a, the oxide film 230C, and the oxide film 230D, diffusion of impurities generated in a subsequent step into the oxide 230b can be inhibited.

For example, silicon oxynitride is formed by a CVD method as the insulating film 250A. Note that the insulating film 250A is preferably an insulating layer containing excess oxygen. Moreover, the insulating film 250A may be subjected to oxygen doping treatment. Furthermore, heat treatment may be performed after the formation of the insulating film 250A.

As the conductive film 260A, titanium nitride is formed by a sputtering method, for example. In addition, as the conductive film 260B, tungsten is formed by a sputtering method, for example. Alternatively, an oxide film may be used for the conductive film 260A. A material similar to those of the oxide film 230B and the oxide film 230C are preferably formed by a sputtering method for the conductive film 260A, whereby oxygen can be supplied to the insulating film 250A. In that case, a stacked layer of titanium nitride and tungsten may be formed as the conductive film 260B.

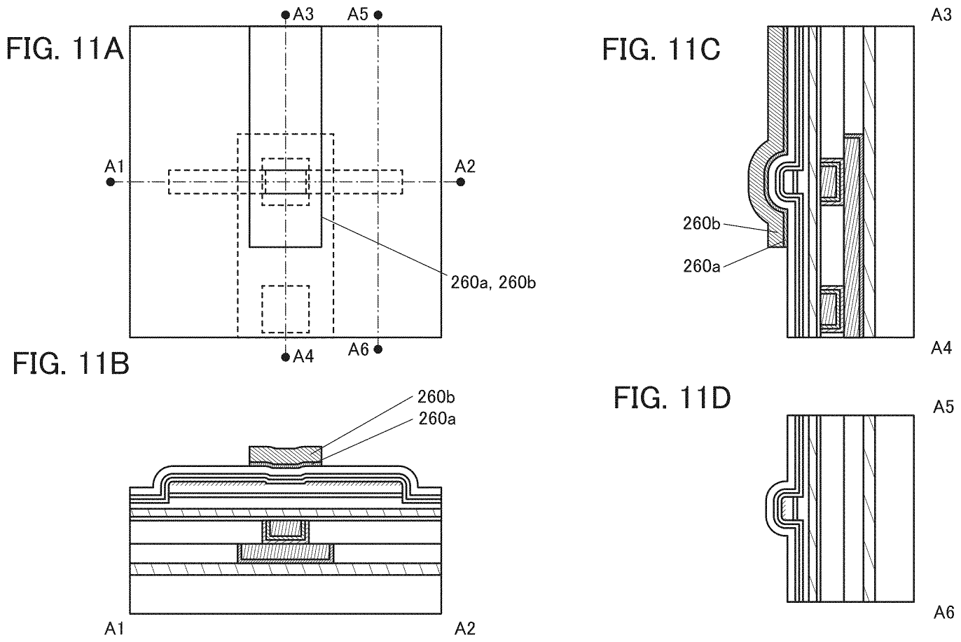

Next, a resist mask is formed over the conductive film 260B by a photolithography method. Part of the conductive film 260A and part of the conductive film 260B are selectively removed using the resist mask, so that the conductor 260 (the conductor 260a and the conductor 260b) is formed (see FIG. 11).

Then, an insulating film to be a barrier layer 270 is formed. For the insulating film, aluminum oxide, hafnium oxide, silicon nitride, or silicon oxide is formed by an ALD method, a CVD method, or a sputtering method, for example.

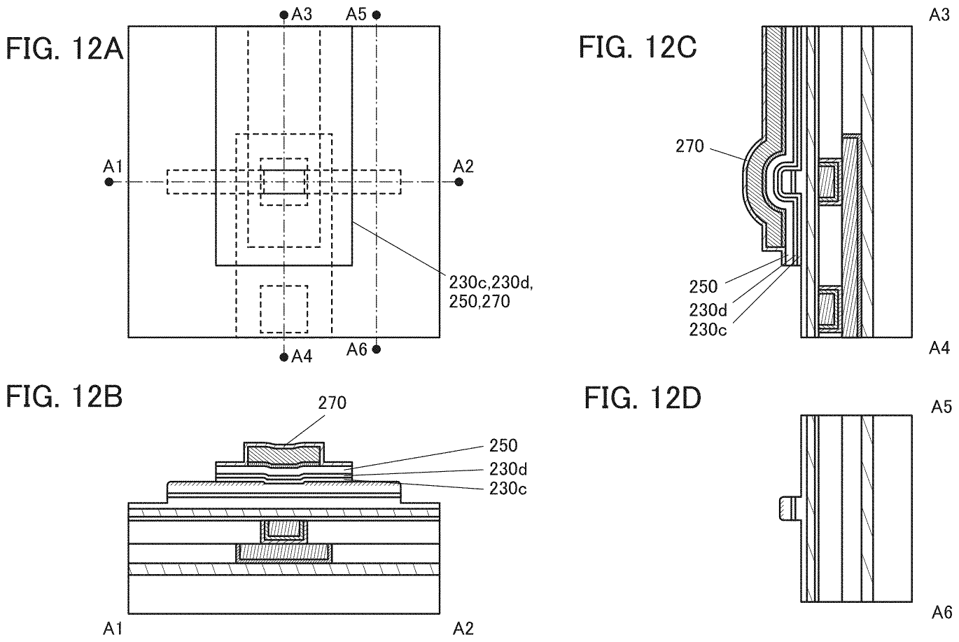

Next, a resist mask is formed over the insulating film by a photolithography method. Part of the insulating film, part of the insulating film 250A, part of the oxide film 230D, and part of the oxide film 230C are selectively removed using the resist mask, so that the barrier layer 270, the insulator 250, the oxide 230d, and the oxide 230c are formed (see FIG. 12).

Depending on the material used for the conductor 260, the resistance value of the conductor 260 might be increased by oxidation of the conductor 260 in a subsequent step of heat treatment, for example. Furthermore, in the case where excess oxygen is supplied to the oxide 230b and the oxide 230c, oxygen might be absorbed by the conductor 260. With the use of the barrier layer 270, the oxidization of the conductor 260 can be inhibited and the shortage of oxygen supplied to the oxide 230 can be inhibited.

Note that it is preferable to perform heat treatment after the barrier layer 270 is formed. Through the heat treatment, impurities in the oxide 230 are removed.

Subsequently, the insulator 280 is formed so as to cover the insulator 224, the oxide 230, the insulator 250, and the barrier layer 270.

The insulator 280 is an insulator containing oxygen, such as a silicon oxide film or a silicon oxynitride film. As a method for forming an insulator containing excess oxygen, a silicon oxide film or a silicon oxynitride film containing a large amount of oxygen can be formed by a CVD method or a sputtering method under the conditions that are set as appropriate.

Note that, to make the insulator 280 contain oxygen in excess, the insulator 280 may be deposited in an oxygen atmosphere, for example. Alternatively, a region containing oxygen in excess may be formed by introducing oxygen into the insulator 280 that has been deposited, and both the methods may be used in combination.

For example, oxygen (at least including any of oxygen radicals, oxygen atoms, and oxygen ions) is introduced into the insulator 280 that has been deposited, whereby a region containing oxygen in excess is formed. As a method for introducing oxygen, an ion implantation method, an ion doping method, a plasma immersion ion implantation method, plasma treatment, or the like can be used.

A gas containing oxygen can be used for the oxygen introduction treatment. As a gas containing oxygen, oxygen, dinitrogen monoxide, nitrogen dioxide, carbon dioxide, carbon monoxide, or the like can be used. A rare gas may be contained in the gas containing oxygen in the oxygen introduction treatment; for example, a mixed gas of carbon dioxide, hydrogen, and argon can be used.

Then, the insulator 282 (the insulator 282a and the insulator 282b) is formed over the insulator 280. The insulator 282a is preferably deposited with a sputtering apparatus. By using a sputtering method, an excess-oxygen region can be formed easily in the insulator 280 which is a lower layer of the insulator 282a.

During deposition by a sputtering method, ions and sputtered particles exist between a target and a substrate. For example, a potential E₀ is supplied to the target, to which a power source is connected. In addition, a potential E₁ such as a ground potential is supplied to the substrate. Note that the substrate may be electrically floating. Moreover, there is a region at a potential E₂ between the target and the substrate. The potential relationship is E₂>E₁>E₀.

The ions in plasma are accelerated by a potential difference E₂−E₀ and collide with the target, whereby the sputtered particles are ejected from the target. These sputtered particles are attached on a deposition surface and deposited thereover; as a result, a film is deposited. In addition, some ions recoil by the target and might be taken, as recoil ions, into the insulator 280 below the formed film, through the formed film. The ions in the plasma are accelerated by a potential difference E₂−E₁ and collide with the deposition surface. At that time, some ions of the ions reach the inside of the insulator 280. The ions are taken into the insulator 280; accordingly, a region into which the ions are taken is formed in the insulator 280. That is, an excess-oxygen region is formed in the insulator 280 in the case where the ions include oxygen.

Introduction of excess oxygen into the insulator 280 can form an excess-oxygen region. The excess oxygen in the insulator 280 is supplied to the oxide 230 and the oxygen can compensate for oxygen vacancies in the oxide 230.

Accordingly, when the deposition in an oxygen gas atmosphere with a sputtering apparatus is performed as means for depositing the insulator 282a, oxygen can be introduced into the insulator 280 while the insulator 282a is deposited. When aluminum oxide having a barrier property is used for the insulator 282a, for example, excess oxygen introduced into the insulator 280 can be effectively sealed on the transistor 200 side. Moreover, the substrate is preferably heated at least before or during the deposition of the insulator 282a because hydrogen contained in the insulator 280 can be removed. The substrate is preferably heated with a sputtering apparatus, particularly in a deposition chamber where the insulator 282a is deposited. In the case where the heat treatment cannot be performed with a sputtering apparatus, it is only necessary that heat treatment be performed using a furnace or an oven and the insulator 282a be formed immediately after the heat treatment.

The insulator 282b is preferably formed over the insulator 282a. It is preferable to use an ALD method, which is excellent in deposition coverage, to form the insulator 282b. By an ALD method, the insulator 282b having a uniform thickness even in a step portion caused by the oxide 230 and the conductor 260 can be formed. Furthermore, even when the insulator 282a has deposition defects such as portions which are not deposited in a pinhole and a step portion, they can preferably be covered with the insulator 282b.

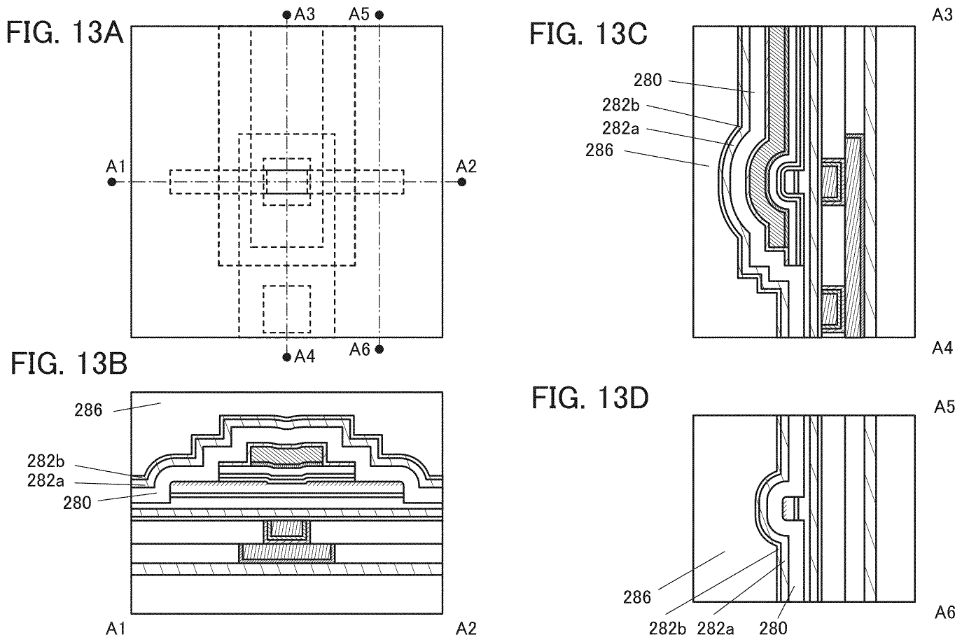

Subsequently, the insulator 286 is formed over the insulator 282 (see FIG. 13).

As the insulator 286, an insulator containing oxygen, such as a silicon oxide film or a silicon oxynitride film, is formed by a CVD method, for example. The permittivity of the insulator 286 is preferably lower than that of the insulator 282. When a material with a low dielectric constant is used for an interlayer film, the parasitic capacitance generated between wirings can be reduced.

Next, the openings reaching the oxide 230 are formed in the insulator 286, the insulator 282, and the insulator 280; the opening reaching the conductor 260 is formed in the insulator 286, the insulator 282, the insulator 280, and the barrier layer 270; and an opening reaching the conductor 207 is formed in the insulator 286, the insulator 282, the insulator 280, the insulator 224, the insulator 222, and the insulator 220. Note that in the case where the high-resistance layers 285 remain over the oxide 230 when the openings reaching the oxide 230 are formed, the openings are formed also in the layers 285. In contrast, in the case where the layers 285 have conductivity, it is only necessary that the openings reaching the layers 285 be formed.

Next, the barrier layer 276 is formed in each of the openings. For example, the barrier layer 276 is formed in such a manner that aluminum oxide is formed by an ALD method over the opening and the insulator 286 as an insulating film to be the barrier layer 276 and an unnecessary portion of the insulating film is removed. For example, the insulating film is subjected to etch-back processing until the oxide 230, the conductor 260, and the conductor 207 are exposed, whereby the barrier layer 276 can be formed.

Note that cleaning is preferably performed after the etch-back processing. An etching residue of the insulating film remaining in the opening can be removed by the cleaning. For the cleaning, an alkaline solution such as a resist stripping solution can be used, for example.

In some cases, another layer of an oxide or the like is formed on surfaces of the oxide 230, the conductor 260, and the conductor 207 which are exposed through the etching treatment. Note that the another layer is a layer containing a residue that includes the components of the insulators where the opening is formed and the component of the barrier layer 276, or a layer containing a product that includes the components of the oxide 230, the conductor 260, and the conductor 207. The another layer might be formed of a composite of the residue and the product. The another layer is preferably removed when having an insulating property because the contact resistance between the another layer and the oxide 230, the conductor 260, and the conductor 207 is reduced.

The formed another layer can be removed by wet etching, plasma treatment, or the like depending on its component or shape. For example, to remove another layer derived from aluminum oxide, plasma treatment is preferably performed in an atmosphere containing a rare gas such as argon (Ar). Furthermore, to remove another layer derived from tantalum nitride, plasma treatment is preferably performed in an atmosphere including a gas containing a halogen, such as CF₄, BCl₃, NF₃, or SF₆, that is less likely to generate a polymer, for example.

Moreover, at this time, the barrier layer 276 preferably covers the side surfaces of the opening at least in part of the insulator 280 and the insulator 282. With such a structure, the insulator 280 and the transistor 200 can be sealed. Thus, absorption of excess oxygen contained in the insulator 280 by the conductor 252 can be inhibited. Furthermore, the diffusion of hydrogen, which is an impurity, to the insulator 280 through the conductor 252 can be inhibited.

With the barrier layer 276, the oxide where the channel is formed in the transistor 200 can be an oxide semiconductor having a low density of defect states and stable characteristics. That is, a change in electrical characteristics of the transistor 200 can be reduced and the reliability can be improved.

In addition, with the barrier layer 276, excess oxygen can be supplied to the transistor 200 stably regardless of the shape or the position of the plug or the wiring provided in the semiconductor device or the number of plugs and wirings. Since oxygen defects are less likely to be formed when the diffusion of hydrogen is inhibited, generation of carriers can be inhibited. Thus, the transistor 200 can have stable electrical characteristics. Moreover, the design flexibility of the semiconductor device can be increased.

Next, the conductor 252 (the conductor 252a, the conductor 252b, the conductor 252c, and the conductor 252d) is formed. For example, the conductor 252 can be formed using a material and a method similar to those of the conductor 203 and the conductor 205. In this embodiment, a two-layer stacked structure of titanium nitride and tungsten can be used as the conductor 252. Alternatively, a three-layer stacked structure of tungsten, titanium nitride, and tungsten can be used. The material which can reduce the resistance of the oxide 230 connected to the conductor 252 is preferably used for the lowest layer of the conductor 252.

The conductor 256 electrically connected to the conductor 252 may be provided. The conductor 256 can be formed in such a manner that a conductive film to be the conductor 256 is formed over the insulator 286 and the conductor 252 and an unnecessary portion of the conductive film is removed by a lithography method.

Through the above steps, the semiconductor device of one embodiment of the present invention can be manufactured.

According to one embodiment of the present invention, it is possible to provide a semiconductor device having favorable electrical characteristics by stably reducing the resistance of a source region and a drain region of a transistor and increasing the purity of a channel formation region.

Alternatively, according to one embodiment of the present invention, it is possible to provide a semiconductor device that can be miniaturized or highly integrated. According to one embodiment of the present invention, it is possible to provide a semiconductor device having favorable electrical characteristics. According to one embodiment of the present invention, it is possible to provide a semiconductor device with high productivity.

According to one embodiment of the present invention, it is possible to provide a novel semiconductor device.

The structure, method, and the like described above in this embodiment can be used in an appropriate combination with the structures, methods, and the like described in the other embodiments.

### Embodiment 2

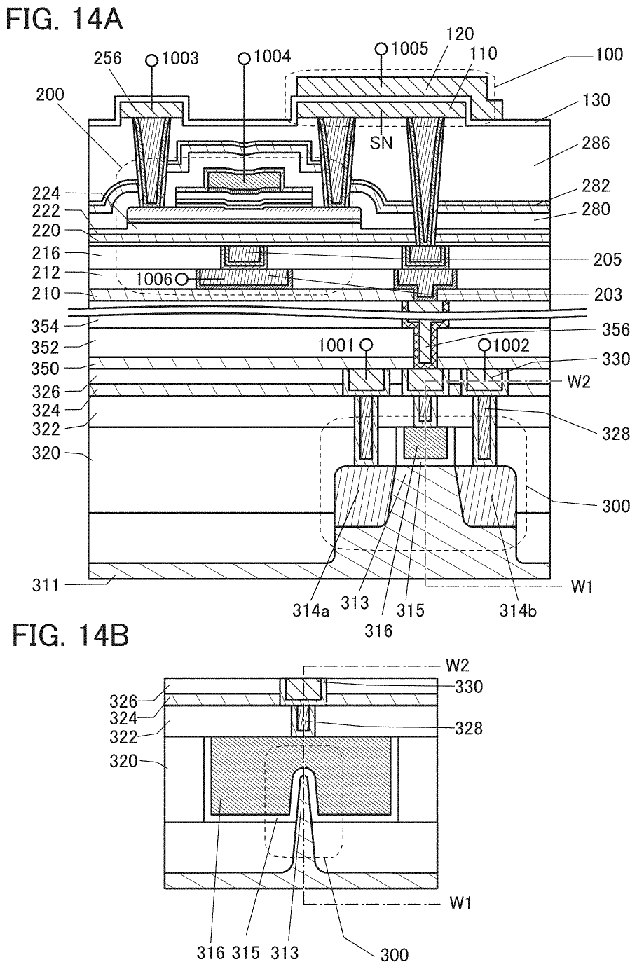

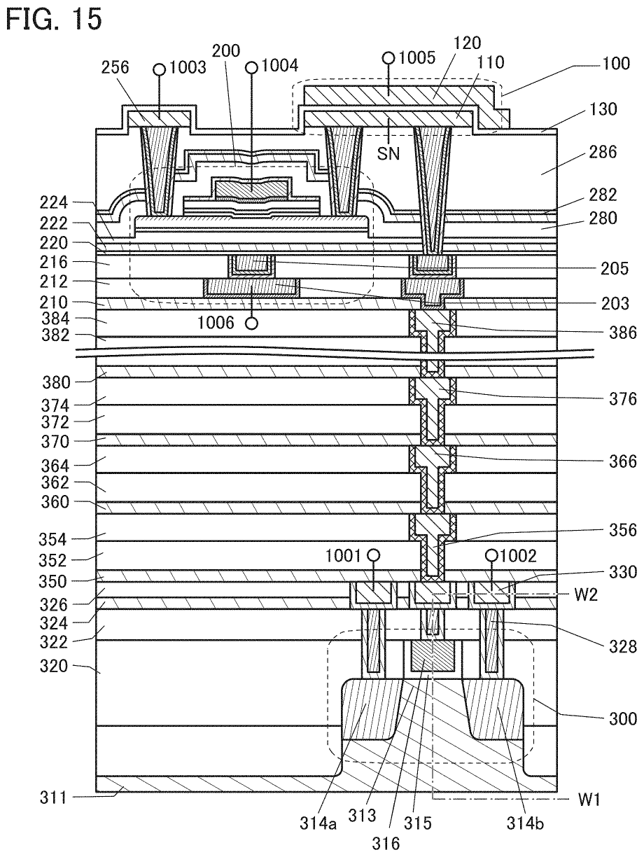

In this embodiment, one embodiment of a semiconductor device will be described with reference to FIG. 14 and FIG. 15.

### [Memory Device 1]

A memory device illustrated in FIG. 14(A) and FIG. 15 includes the transistor 200, a capacitor 100, and a transistor 300.

The transistor 200 is a transistor whose channel is formed in a semiconductor layer containing an oxide semiconductor. Since the off-state current of the transistor 200 is low, a memory device including the transistor 200 can retain stored data for a long time. In other words, such a memory device does not require refresh operation or has an extremely low frequency of the refresh operation, which leads to a sufficient reduction in power consumption of the memory device.

In the memory device illustrated in FIG. 14(A) and FIG. 15, a wiring 1001 is electrically connected to a source of the transistor 300. A wiring 1002 is electrically connected to a drain of the transistor 300. A wiring 1003 is electrically connected to one of a source and a drain of the transistor 200. A wiring 1004 is electrically connected to a top gate of the transistor 200. A wiring 1006 is electrically connected to a bottom gate of the transistor 200. A gate of the transistor 300 and the other of the source and the drain of the transistor 200 are electrically connected to one electrode of the capacitor 100. A wiring 1005 is electrically connected to the other electrode of the capacitor 100.

The memory device illustrated in FIG. 14(A) and FIG. 15 has a feature that the potential of the gate of the transistor 300 can be retained and thus enables writing, retaining, and reading of data as follows.

Writing and retaining of data are described. First, the potential of the wiring 1004 is set to a potential at which the transistor 200 is brought into a conduction state, so that the transistor 200 is brought into a conduction state. Accordingly, the potential of the wiring 1003 is supplied to a node SN where the gate of the transistor 300 and one electrode of the capacitor 100 are electrically connected to each other. That is, a predetermined charge is supplied to the gate of the transistor 300 (writing). Here, one of two kinds of charges providing different potential levels (hereinafter referred to as a low-level charge and a high-level charge) is supplied. After that, the potential of the wiring 1004 is set to a potential at which the transistor 200 is brought into a non-conduction state, so that the transistor 200 is brought into a non-conduction state. Thus, the charge is retained in the node SN (retaining).

In the case where the off-state current of the transistor 200 is low, the charge of the node SN is retained for a long time.

Next, reading of data is described. An appropriate potential (reading potential) is supplied to the wiring 1005 while a predetermined potential (constant potential) is supplied to the wiring 1001, whereby the potential of the wiring 1002 varies depending on the amount of charge retained in the node SN. This is because in the case of using an n-channel transistor as the transistor 300, an apparent threshold voltage V_{th_H} at the time when a high-level charge is supplied to the gate of the transistor 300 is lower than an apparent threshold voltage V_{th_L} at the time when a low-level charge is supplied to the gate of the transistor 300. Here, an apparent threshold voltage refers to the potential of the wiring 1005 which is needed to bring the transistor 300 into a “conduction state”. Thus, the potential of the wiring 1005 is set to a potential V₀ which is between V_{th_H} and V_{th_L}, whereby the charge supplied to the node SN can be determined. For example, in the case where a high-level charge is supplied to the node SN in writing and the potential of the wiring 1005 is V₀ (>V_{th_H}), the transistor 300 is brought into a “conduction state”. Meanwhile, in the case where a low-level charge is supplied to the node SN, the transistor 300 remains in a “non-conduction state” even when the potential of the wiring 1005 is V₀ (<V_{th_L}). Thus, the data retained in the node SN can be read by determining the potential of the wiring 1002.

### <Structure of Memory Device 1>

The memory device of one embodiment of the present invention includes the transistor 300, the transistor 200, and the capacitor 100 as illustrated in FIG. 14(A) and FIG. 15. The transistor 200 is provided above the transistor 300, and the capacitor 100 is provided above the transistor 300 and the transistor 200.

The transistor 300 is provided on a substrate 311 and includes a conductor 316, an insulator 315, a semiconductor region 313 that is a part of the substrate 311, and a low-resistance region 314a and a low-resistance region 314b functioning as a source region and a drain region.

The transistor 300 is either a p-channel transistor or an n-channel transistor.

It is preferable that a region of the semiconductor region 313 where a channel is formed, a region in the vicinity thereof, the low-resistance region 314a and the low-resistance region 314b functioning as the source region and the drain region, and the like contain a semiconductor such as a silicon-based semiconductor, further preferably single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is adjusted by applying stress to the crystal lattice and thereby changing the lattice spacing is used. Alternatively, the transistor 300 may be an HEMT (High Electron Mobility Transistor) with GaAs and GaAlAs, or the like.

The low-resistance region 314a and the low-resistance region 314b contain an element which imparts n-type conductivity, such as arsenic or phosphorus, or an element which imparts p-type conductivity, such as boron, in addition to the semiconductor material used for the semiconductor region 313.

The insulator 315 functions as a gate insulating film of the transistor 300.

For the conductor 316 functioning as a gate electrode, a semiconductor material such as silicon containing the element which imparts n-type conductivity, such as arsenic or phosphorus, or the element which imparts p-type conductivity, such as boron, or using a conductive material such as a metal material, an alloy material, or a metal oxide material.

Note that since the work function of a conductor depends on a material of the conductor, the threshold voltage can be adjusted by changing the material of the conductor. Specifically, it is preferable to use a material such as titanium nitride or tantalum nitride for the conductor. Furthermore, in order to ensure both the conductivity and embeddability, it is preferable to use a stacked layer of metal materials such as tungsten and aluminum for the conductor. It is particularly preferable to use tungsten in terms of heat resistance.

Note that the transistor 300 illustrated in FIG. 14(A) and FIG. 15 is an example and the structure is not limited thereto; an appropriate transistor may be used in accordance with a circuit configuration or a driving method.

Here, FIG. 14(B) shows a cross-sectional view of the transistor 300 in the W width direction denoted by W1-W2 in FIG. 14(A) and FIG. 15. As illustrated in FIG. 14(B), the transistor 300 has a protruding shape in the semiconductor region 313 (part of the substrate 311) where a channel is formed. Furthermore, the conductor 316 is provided so as to cover the top and side surfaces of the semiconductor region 313 with the insulator 315 positioned therebetween. Note that the conductor 316 may be formed using a material for adjusting the work function. The transistor 300 is also referred to as FIN-type transistors because they each utilize a protruding portion of the semiconductor substrate. An insulator functioning as a mask for forming the protruding portion may be provided in contact with the top portion of the protruding portion. Although the case where the protruding portion is formed by processing part of the semiconductor substrate is described here, a semiconductor film having a protruding shape may be formed by processing an SOI substrate.

An insulator 320, an insulator 322, an insulator 324, and an insulator 326 are stacked sequentially to cover the transistor 300.

For the insulator 320, the insulator 322, the insulator 324, and the insulator 326, for example, silicon oxide, silicon oxynitride, silicon nitride oxide, silicon nitride, aluminum oxide, aluminum oxynitride, aluminum nitride oxide, or aluminum nitride may be used.

The insulator 322 may function as a planarization film for eliminating a level difference caused by the transistor 300 or the like underlying the insulator 322. For example, the top surface of the insulator 322 may be planarized by planarization treatment using a chemical mechanical polishing (CMP) method or the like to improve planarity.

For the insulator 324, it is preferable to use a film having a barrier property that prevents hydrogen or impurities from the substrate 311, the transistor 300, or the like from diffusing to a region where the transistor 200 is provided.

For the film having a barrier property against hydrogen, silicon nitride formed by a CVD method can be used, for example. Here, the diffusion of hydrogen to a semiconductor element including an oxide semiconductor, such as the transistor 200, might degrade the characteristics of the semiconductor element. Therefore, a film that inhibits hydrogen diffusion is preferably provided between the transistor 200 and the transistor 300. The film that inhibits hydrogen diffusion is specifically a film from which a small amount of hydrogen is released.

The amount of released hydrogen can be measured by thermal desorption spectroscopy (TDS), for example. It is only necessary that the amount of hydrogen released from the insulator 324 that is converted into hydrogen atoms per area of the insulator 324 be less than or equal to 10×10¹⁵ atoms/cm², preferably less than or equal to 5×10¹⁵ atoms/cm², in the TDS analysis at a film surface temperature of 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 or less times that of the insulator 324, further preferably 0.6 or less times that of the insulator 324. In the case where a material with a low permittivity is used for an interlayer film, the parasitic capacitance between wirings can be reduced.

A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as a plug or a wiring. A plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and another part of the conductor functions as a plug.

As a material for each of plugs and wirings (e.g., the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

An insulator 210, an insulator 212, and an insulator 216 are stacked sequentially over an insulator 354 and a conductor 356. A substance having a barrier property against oxygen or hydrogen is preferably used for any of the insulator 210, the insulator 212, and the insulator 216.

For example, for the insulator 210, the insulator 212, and the insulator 216, it is preferable to use a film having a barrier property that prevents hydrogen or impurities from diffusing from the substrate 311, a region where the transistor 300 is provided, or the like to a region where the transistor 200 is provided. Therefore, a material similar to that for the insulator 324 can be used.

For the film having a barrier property against hydrogen, silicon nitride formed by a CVD method can be used, for example. Here, the diffusion of hydrogen to a semiconductor element including an oxide semiconductor, such as the transistor 200, might degrade the characteristics of the semiconductor element. Therefore, a film that inhibits hydrogen diffusion is preferably provided between the transistor 200 and the transistor 300. The film that inhibits hydrogen diffusion is specifically a film from which a small amount of hydrogen is released.

For the film having a barrier property against hydrogen used for the insulator 210, the insulator 212, and the insulator 216, for example, a metal oxide such as aluminum oxide, hafnium oxide, or tantalum oxide is preferably used.

In particular, aluminum oxide has an excellent blocking effect that prevents permeation of both oxygen and impurities such as hydrogen and moisture which cause a change in electrical characteristics of the transistor. Accordingly, the use of aluminum oxide can prevent the entry of impurities such as hydrogen and moisture into the transistor 200 in and after a manufacturing process of the transistor. In addition, release of oxygen from the oxide contained in the transistor 200 can be inhibited. Therefore, aluminum oxide is suitably used for a protective film of the transistor 200.

The insulator 212 and the insulator 216 can be formed using a material similar to that for the insulator 320, for example. In the case where a material with a relatively low permittivity is used for an interlayer film, the parasitic capacitance between wirings can be reduced. A silicon oxide film, a silicon oxynitride film, or the like can be used for the insulator 212 and the insulator 216, for example.

The conductor 203, the conductor 205, and the like, which are conductors included in the transistor 200, are embedded in the insulator 210, the insulator 212, and the insulator 216. Note that the conductor 203 and the conductor 205 each function as a plug or a wiring that electrically connects the transistor 200, the capacitor 100, and the transistor 300. The conductor 203 and the conductor 205 can be provided using a material similar to those for the conductor 328 and the conductor 330.

In particular, the conductor 203 in a region in contact with the insulator 210 and the insulator 212 is preferably a conductor having a barrier property against oxygen, hydrogen, and water. With this structure, the transistor 300 can be separated from the transistor 200 by a layer having a barrier property against oxygen, hydrogen, and water, so that the diffusion of hydrogen from the transistor 300 into the transistor 200 can be inhibited.

The transistor 200 is provided over the insulator 216. Note that the structure of the transistor 200 described in the above embodiment can be used as the structure of the transistor 200. Note that the transistor 200 illustrated in FIG. 14(A) is an example and the structure is not limited thereto; an appropriate transistor may be used in accordance with a circuit configuration or a driving method.

A wiring layer may be provided over the insulator 326 and the conductor 330. For example, in FIG. 15, an insulator 350, an insulator 352, and an insulator 354 are stacked sequentially. Furthermore, the conductor 356 is formed in the insulator 350, the insulator 352, and the insulator 354. The conductor 356 functions as a plug or a wiring. Note that the conductor 356 can be provided using a material similar to those for the conductor 328 and the conductor 330.

Note that the insulator 350 is preferably formed using an insulator having a barrier property against hydrogen, as with the insulator 324, for example. Furthermore, the conductor 356 preferably contains a conductor having a barrier property against hydrogen. In particular, the conductor having a barrier property against hydrogen is formed in an opening of the insulator 350 having a barrier property against hydrogen. With this structure, the transistor 300 and the transistor 200 can be separated by a barrier layer, so that the diffusion of hydrogen from the transistor 300 to the transistor 200 can be inhibited.

Note that as the conductor having a barrier property against hydrogen, tantalum nitride is preferably used, for example. The use of a stack including tantalum nitride and tungsten having high conductivity can inhibit the diffusion of hydrogen from the transistor 300 while the conductivity as a wiring remains. In that case, the tantalum nitride layer having a barrier property against hydrogen preferably has a structure in which the tantalum nitride layer is in contact with the insulator 350 having a barrier property against hydrogen.

A wiring layer may be provided over the insulator 354 and the conductor 356. For example, in FIG. 15, an insulator 360, an insulator 362, and an insulator 364 are stacked sequentially. Furthermore, a conductor 366 is formed in the insulator 360, the insulator 362, and the insulator 364. The conductor 366 functions as a plug or a wiring. Note that the conductor 366 can be provided using a material similar to those for the conductor 328 and the conductor 330.

Note that the insulator 360 is preferably formed using an insulator having a barrier property against hydrogen, as with the insulator 324, for example. Furthermore, the conductor 366 preferably contains a conductor having a barrier property against hydrogen. In particular, the conductor having a barrier property against hydrogen is formed in an opening of the insulator 360 having a barrier property against hydrogen. With this structure, the transistor 300 and the transistor 200 can be separated by a barrier layer, so that the diffusion of hydrogen from the transistor 300 to the transistor 200 can be inhibited.

A wiring layer may be provided over the insulator 364 and the conductor 366. For example, in FIG. 15, an insulator 370, an insulator 372, and an insulator 374 are stacked sequentially. Furthermore, a conductor 376 is formed in the insulator 370, the insulator 372, and the insulator 374. The conductor 376 functions as a plug or a wiring. Note that the conductor 376 can be provided using a material similar to those for the conductor 328 and the conductor 330.

Note that the insulator 370 is preferably formed using an insulator having a barrier property against hydrogen, as with the insulator 324, for example. Furthermore, the conductor 376 preferably contains a conductor having a barrier property against hydrogen. In particular, the conductor having a barrier property against hydrogen is formed in an opening of the insulator 370 having a barrier property against hydrogen. With this structure, the transistor 300 and the transistor 200 can be separated by a barrier layer, so that the diffusion of hydrogen from the transistor 300 to the transistor 200 can be inhibited.

A wiring layer may be provided over the insulator 374 and the conductor 376. For example, in FIG. 15, an insulator 380, an insulator 382, and an insulator 384 are stacked sequentially. Furthermore, a conductor 386 is formed in the insulator 380, the insulator 382, and the insulator 384. The conductor 386 functions as a plug or a wiring. Note that the conductor 386 can be provided using a material similar to those for the conductor 328 and the conductor 330.

Note that the insulator 380 is preferably formed using an insulator having a barrier property against hydrogen, as with the insulator 324, for example. Furthermore, the conductor 386 preferably contains a conductor having a barrier property against hydrogen. In particular, the conductor having a barrier property against hydrogen is formed in an opening of the insulator 380 having a barrier property against hydrogen. With this structure, the transistor 300 and the transistor 200 can be separated by a barrier layer, so that the diffusion of hydrogen from the transistor 300 to the transistor 200 can be inhibited.

The insulator 210, the insulator 212, and the insulator 216 are stacked sequentially over the insulator 384 and the conductor 386. Furthermore, the transistor 200 is provided above the insulator 216. In addition, the capacitor 100 is provided over the insulator 280, the insulator 282, and the insulator 286 which cover the transistor 200.

The capacitor 100 includes a conductor 110 formed using the same material as the conductor 256, an insulator 130, and a conductor 120. The conductor 110 is electrically connected to the gate of the transistor 300 and the other of the source and the drain of the transistor 200. Furthermore, the conductor 120 is provided to overlap with the conductor 110 with the insulator 130 provided therebetween. Here, the insulator 130 functions as a dielectric of the capacitor 100.

For the insulator 130 functioning as the dielectric, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or hafnium aluminate is used, which is provided in a stacked layer or a single layer. For example, a stacked-layer structure of a high-k material such as aluminum oxide and a material with high dielectric strength, such as silicon oxynitride, is preferable. With this structure, the capacitor 100 can have sufficient capacitance owing to a high-k material and increased dielectric strength owing to a material with high dielectric strength; thus, the electrostatic breakdown of the capacitor 100 can be inhibited, which leads to improvement in the reliability of the capacitor 100. In addition, the insulator 130 preferably has a stacked-layer structure in which hafnium oxide, aluminum oxide, and hafnium oxide are stacked sequentially because the capacitor 100 can have larger capacitance.

The conductor 120 is preferably positioned to cover the side surfaces of the conductor 110 with the insulator 130 positioned therebetween because the capacitance value can be increased. For example, at least one side of the conductor 120 is preferably longer than one side of the conductor 110. Meanwhile, the conductor 120 may be provided inside the conductor 110 when seen from the normal direction of the substrate.

Although FIG. 15 illustrates an example where four layers including a layer including the conductor 356, a layer including the conductor 366, a layer including the conductor 376, and a layer including the conductor 386 are provided between the conductor 330 and the insulator 210, this embodiment is not limited thereto. The layer provided between the conductor 330 and the insulator 210 may be only the layer including the conductor 356, or two layers, three layers, or five or more layers may be provided. Alternatively, a layer including a conductor is not necessarily provided between the conductor 330 and the insulator 210.

With the use of this structure, variation in electrical characteristics can be reduced and reliability can be improved in a semiconductor device using a transistor including an oxide semiconductor. Alternatively, a transistor including an oxide semiconductor and having a high on-state current can be provided. Alternatively, a transistor including an oxide semiconductor and having a low off-state current can be provided. Alternatively, a semiconductor device with reduced power consumption can be provided.

### <Memory Device 2>

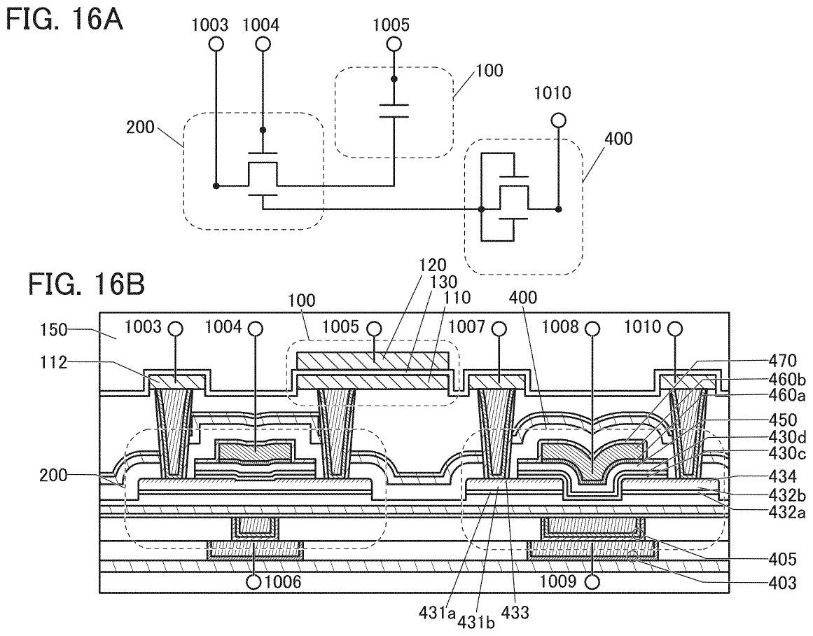

A semiconductor device illustrated in FIG. 16 is a memory device including a transistor 400, the transistor 200, and the capacitor 100. One embodiment of the memory device will be described below with reference to FIG. 16.

FIG. 16(A) is a circuit diagram showing an example of the connection relationship of the transistor 200, the transistor 400, and the capacitor 100 in the semiconductor device described in this embodiment. FIG. 16(B) is a cross-sectional view of the semiconductor device in which the wiring 1003 to a wiring 1010 and the like correspond to those in FIG. 16(A).

The transistor 200 and the transistor 400 which are formed over a substrate (not illustrated) have different structures. For example, the transistor 400 can have a structure in which a drain current is smaller than that of the transistor 200 when a bottom gate voltage and a top gate voltage are each 0 V. A structure is employed in which the transistor 400 is used as a switching element to control the potential of a bottom gate of the transistor 200. Thus, the loss of a charge at a node connected to the bottom gate of the transistor 200 can be inhibited by making the node connected to the bottom gate of the transistor 200 have a desired potential and then turning off the transistor 400.

As illustrated in FIG. 16, in the transistor 200, the gate is electrically connected to the wiring 1004, one of the source and the drain is electrically connected to the wiring 1003, and the other of the source and the drain is electrically connected to one electrode of the capacitor 100. The other electrode of the capacitor 100 is electrically connected to the wiring 1005. A drain of the transistor 400 is electrically connected to the wiring 1010. As illustrated in FIGS. 16(A) and 16(B), the bottom gate of the transistor 200 and a source, a top gate, and a bottom gate of the transistor 400 are electrically connected through the wiring 1006, the wiring 1007, the wiring 1008, and the wiring 1009.

The on/off state of the transistor 200 can be controlled by application of a potential to the wiring 1004. When the transistor 200 is in an on state to apply a potential to the wiring 1003, charges can be supplied to the capacitor 100 through the transistor 200. At this time, by making the transistor 200 in an off state, the charges supplied to the capacitor 100 can be held. By supply of a given potential to the wiring 1005, the potential of a connection portion between the transistor 200 and the capacitor 100 can be controlled by capacitive coupling. For example, when a ground potential is supplied to the wiring 1005, the charges are held easily. Furthermore, by application of a negative potential to the wiring 1010, the negative potential is supplied to the bottom gate of the transistor 200 through the transistor 400, whereby the threshold voltage of the transistor 200 can be higher than 0 V, the off-state current can be reduced, and I_{cut} can be noticeably reduced. Here, I_{cut} refers to a drain current when a voltage applied to the top gate is 0 V.

With a structure in which the top gate and the bottom gate of the transistor 400 are diode-connected to the source, and a source of the transistor 400 and the bottom gate of the transistor 200 are connected, the bottom gate voltage of the transistor 200 can be controlled by the wiring 1010. When the negative potential of the bottom gate of the transistor 200 is held, the voltage between the top gate and the source and the voltage between the bottom gate and the source of the transistor 400 are each 0 V. Since the I_{cut} of the transistor 400 is extremely small and the threshold voltage of the transistor 400 is higher than that of the transistor 200, the structure allows the negative potential of the bottom gate of the transistor 200 to be held for a long time without supply of power to the transistor 400.

Moreover, the negative potential of the bottom gate of the transistor 200 is held, in which case the I_{cut} of the transistor 200 can be noticeably reduced even without supply of power to the transistor 200. In other words, the charges can be held in the capacitor 100 for a long time even without supply of power to the transistor 200 and the transistor 400. For example, with the use of such a semiconductor device as a memory element, memory can be retained for a long time without power supply. Therefore, a memory device with a low refresh frequency or a memory device that does not need refresh operation can be provided.

Note that the connection relationship of the transistor 200, the transistor 400, and the capacitor 100 is not limited to that illustrated in FIGS. 16(A) and 16(B). The connection relationship can be modified as appropriate in accordance with a circuit configuration which is necessary.

### <Structure of Memory Device 2>

FIG. 16(B) is a cross-sectional view of a memory device including the capacitor 100, the transistor 200, and the transistor 400. Note that in the memory device illustrated in FIG. 16, components having the same functions as the components in the semiconductor device and the memory device described in the above embodiment and <Structure of memory device 1> are denoted by the same reference numerals.

The memory device of one embodiment of the present invention includes the transistor 200, the transistor 400, and the capacitor 100 as illustrated in FIG. 16. The transistor 200 and the transistor 400 are provided in the same layer, and the capacitor 100 is provided above the transistor 200 and the transistor 400.

Note that the capacitor and the transistor included in the semiconductor device and the memory device described in the above embodiment and with reference to FIG. 14(A) and FIG. 15 can be used as the capacitor 100 and the transistor 200. Note that the capacitor 100, the transistor 200, and the transistor 400 illustrated in FIG. 16 are examples and the structures are not limited thereto; an appropriate transistor may be used in accordance with a circuit configuration or a driving method.

The transistor 400 and the transistor 200 are formed in the same layer and thus can be manufactured in parallel. The transistor 400 includes a conductor 460 (a conductor 460a and a conductor 460b) functioning as a top gate electrode; a conductor 405 functioning as a bottom gate electrode; an insulator 470 covering the conductor 460; the insulator 220, the insulator 222, the insulator 224, and an insulator 450 functioning as a gate insulating layer; an oxide 430c and an oxide 430d each including a region where a channel is formed; an oxide 431a and an oxide 431b functioning as one of a source and a drain; and an oxide 432a and an oxide 432b functioning as the other of the source and the drain. Here, in the oxide 431a and the oxide 431b, at least a low-resistance region 433 is provided in the oxide 431b, and in the oxide 432a and the oxide 432b, at least a low-resistance region 434 is provided in the oxide 432b. The conductor 405 functioning as a bottom gate electrode is electrically connected to a conductor 403 functioning as a wiring.

In the transistor 400, the conductor 405 is in the same layer as the conductor 205. The oxide 431a and the oxide 432a are in the same layer as the oxide 230a, and the oxide 431b and the oxide 432b are in the same layer as the oxide 230b. The oxide 430c is in the same layer as the oxide 230c. The oxide 430d is in the same layer as the oxide 230d. The insulator 450 is in the same layer as the insulator 250. The conductor 460 is in the same layer as the conductor 260. The insulator 470 is in the same layer as the barrier layer 270.

In the oxide 430c and the oxide 430d functioning as an active layer of the transistor 400, oxygen vacancies and impurities such as water or hydrogen are reduced, as in the oxide 230 or the like. Accordingly, the threshold voltage of the transistor 400 can be higher than 0 V, the off-state current can be reduced, and the drain current when the bottom gate voltage and the top gate voltage are each 0 V can be noticeably reduced.

As described above, the oxide 431a and the oxide 432a are in the same layer as the oxide 230a, and the oxide 431b and the oxide 432b are in the same layer as the oxide 230b. Thus, the low-resistance region 433 and the low-resistance region 434 corresponding to the region 231a and the region 231b, respectively, are formed in the oxide 431a, the oxide 432a, the oxide 431b, and the oxide 432b.

With the use of this structure, variation in electrical characteristics can be reduced and reliability can be improved in a semiconductor device using a transistor including an oxide semiconductor. Alternatively, power consumption of a semiconductor device using a transistor including an oxide semiconductor can be reduced. Alternatively, a semiconductor device using a transistor including an oxide semiconductor can be miniaturized or highly integrated. Alternatively, a miniaturized or highly integrated semiconductor device can be provided with high productivity.

### <Memory Device 3>

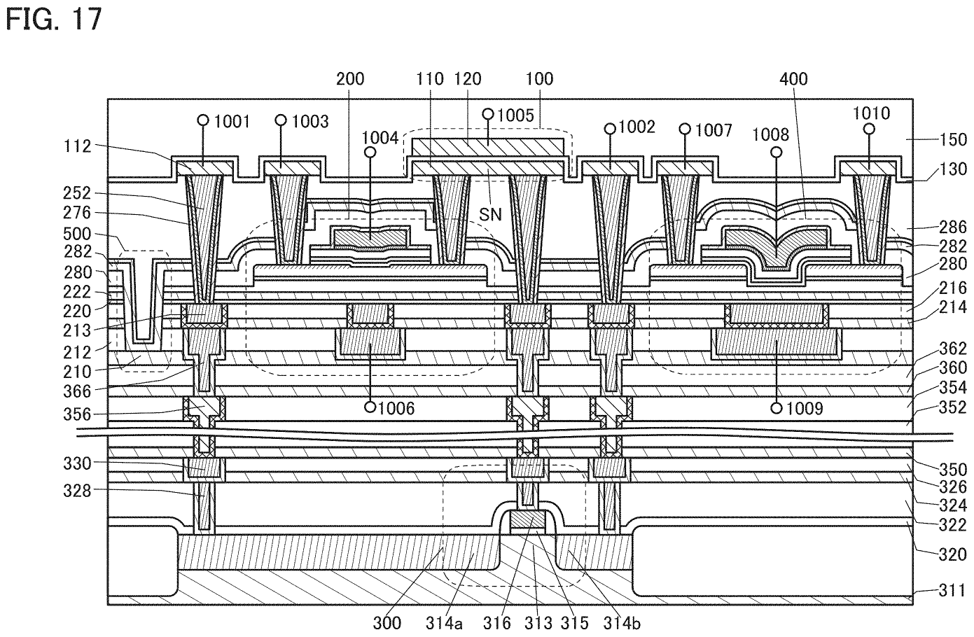

A semiconductor device illustrated in FIG. 17 is a memory device including the transistor 300, the transistor 400, the transistor 200, and the capacitor 100. One embodiment of the memory device will be described below with reference to FIG. 17.

The transistor 200 is a transistor whose channel is formed in a semiconductor layer containing an oxide semiconductor, and can be the transistor described in the above embodiment. Since the transistor described in the above embodiment can be formed with high yield even when it is miniaturized, the transistor 200 can be miniaturized. The use of such a transistor in a memory device allows miniaturization or high integration of the memory device. Since the off-state current of the transistor described in the above embodiment is low, a memory device including the transistor can retain stored data for a long time. In other words, such a memory device does not require refresh operation or has an extremely low frequency of the refresh operation, which leads to a sufficient reduction in power consumption of the memory device.

In FIG. 17, the wiring 1001 is electrically connected to the source of the transistor 300. The wiring 1002 is electrically connected to the drain of the transistor 300. The wiring 1003 is electrically connected to one of the source and the drain of the transistor 200. The wiring 1004 is electrically connected to the top gate of the transistor 200. The wiring 1006 is electrically connected to the bottom gate of the transistor 200. The gate of the transistor 300 and the other of the source and the drain of the transistor 200 are electrically connected to one electrode of the capacitor 100. The wiring 1005 is electrically connected to the other electrode of the capacitor 100. The wiring 1007 is electrically connected to the source of the transistor 400, the wiring 1008 is electrically connected to the top gate of the transistor 400, the wiring 1009 is electrically connected to the bottom gate of the transistor 400, and the wiring 1010 is electrically connected to the drain of the transistor 400. Here, the wiring 1006, the wiring 1007, the wiring 1008, and the wiring 1009 are electrically connected to each other.

The semiconductor device illustrated in FIG. 17 has a feature that the potential of the gate of the transistor 300 can be retained and thus enables writing, retaining, and reading of data as follows.

Writing and retaining of data are described. First, the potential of the wiring 1004 is set to a potential at which the transistor 200 is brought into a conduction state, so that the transistor 200 is brought into a conduction state. Accordingly, the potential of the wiring 1003 is supplied to the node SN where the gate of the transistor 300 and one electrode of the capacitor 100 are electrically connected to each other. That is, a predetermined charge is supplied to the gate of the transistor 300 (writing). Here, one of two kinds of charges providing different potential levels (hereinafter referred to as a low-level charge and a high-level charge) is supplied. After that, the potential of the wiring 1004 is set to a potential at which the transistor 200 is brought into a non-conduction state, so that the transistor 200 is brought into a non-conduction state. Thus, the charge is retained in the node SN (retaining).

In the case where the off-state current of the transistor 200 is low, the charge of the node SN is retained for a long time.

Next, reading of data is described. An appropriate potential (reading potential) is supplied to the wiring 1005 while a predetermined potential (constant potential) is supplied to the wiring 1001, whereby the potential of the wiring 1002 varies depending on the amount of charge retained in the node SN. This is because in the case of using an n-channel transistor as the transistor 300, an apparent threshold voltage V_{th_H} at the time when a high-level charge is supplied to the gate of the transistor 300 is lower than an apparent threshold voltage V_{th_L} at the time when a low-level charge is supplied to the gate of the transistor 300. Here, an apparent threshold voltage refers to the potential of the wiring 1005 which is needed to bring the transistor 300 into a “conduction state”. Thus, the potential of the wiring 1005 is set to a potential V₀ which is between V_{th_H} and V_{th_L}, whereby the charge supplied to the node SN can be determined. For example, in the case where a high-level charge is supplied to the node SN in writing and the potential of the wiring 1005 is V₀ (>V_{th_H}), the transistor 300 is brought into a “conduction state”. Meanwhile, in the case where a low-level charge is supplied to the node SN, the transistor 300 remains in a “non-conduction state” even when the potential of the wiring 1005 is V₀ (<V_{th_L}). Thus, the data retained in the node SN can be read by determining the potential of the wiring 1002.

### <Structure of Memory Device 3>

FIG. 17 is a cross-sectional view of a memory device including the capacitor 100, the transistor 200, the transistor 300, and the transistor 400. Note that in the memory device illustrated in FIG. 17, components having the same functions as the components in the semiconductor device and the memory device described in the above embodiment, <Structure of memory device 1>, and <Structure of memory device 2> are denoted by the same reference numerals.

The memory device of one embodiment of the present invention includes the transistor 300, the transistor 200, the transistor 400, and the capacitor 100 as illustrated in FIG. 17. The transistor 200 and the transistor 400 are provided above the transistor 300, and the capacitor 100 is provided above the transistor 300, the transistor 200, and the transistor 400.

Note that the capacitor and the transistor included in the semiconductor device and the memory device described in the above embodiment and with reference to FIG. 14 to FIG. 16 can be used as the capacitor 100, the transistor 200, the transistor 300, and the transistor 400. Note that the capacitor 100, the transistor 300, the transistor 200, and the transistor 400 illustrated in FIG. 17 are examples and the structures are not limited thereto; an appropriate transistor may be used in accordance with a circuit configuration or a driving method.

In the memory device illustrated in FIG. 17, an example is shown in which an opening 500 is provided in the insulator 212, an insulator 214, the insulator 216, the insulator 220, the insulator 222, the insulator 224, and the insulator 280, and the insulator 210 and the insulator 282 are connected to each other. With such a structure, the transistor 200 and the transistor 400 are surrounded by the insulator 210 and the insulator 282 and are therefore less likely to be affected by impurities such as water or hydrogen. In addition, release of oxygen in the oxide or the insulator to the outside is reduced. The memory device with such a structure is preferable because the reliability is improved. Note that the opening 500 is not necessarily provided.

With the use of this structure, variation in electrical characteristics can be reduced and reliability can be improved in a semiconductor device using a transistor including an oxide semiconductor. Alternatively, power consumption of a semiconductor device using a transistor including an oxide semiconductor can be reduced. Alternatively, a semiconductor device using a transistor including an oxide semiconductor can be miniaturized or highly integrated. Alternatively, a miniaturized or highly integrated semiconductor device can be provided with high productivity.

### <Structure of Memory Cell Array>

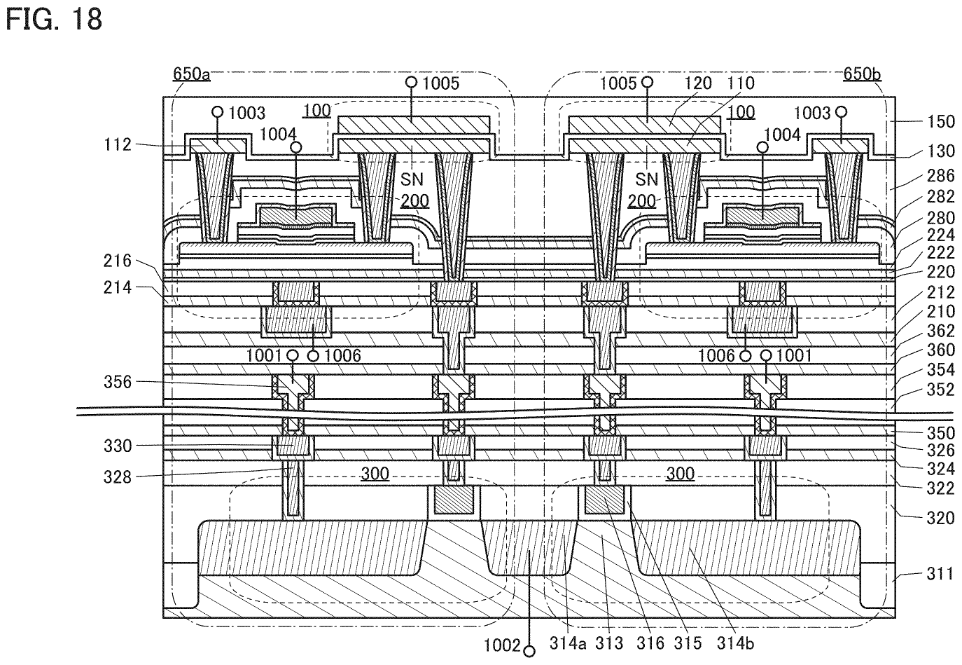

FIG. 18 illustrates an example of a memory cell array of this embodiment. When the transistors 200 are arranged as memory cells in a matrix, a memory cell array can be formed.

Note that the memory device illustrated in FIG. 18 is a semiconductor device constituting a memory cell array in which the memory devices illustrated in FIG. 14, FIG. 15, and FIG. 17 are arranged in a matrix. Note that one transistor 400 can control the bottom-gate voltages of the plurality of transistors 200. For this reason, the number of provided transistors 400 is preferably smaller than the number of transistors 200.

Accordingly, in FIG. 18, the transistor 400 illustrated in FIG. 17 is omitted. FIG. 18 is a cross-sectional view that illustrates part of a row in which the memory devices illustrated in FIG. 14 and FIG. 17 are arranged in a matrix.

The structure of the transistor 300 in FIG. 18 is different from that of the transistor 300 in FIG. 17. In the transistor 300 illustrated in FIG. 18, the semiconductor region 313 (part of the substrate 311) in which the channel is formed has a protruding shape. Furthermore, the conductor 316 is provided so as to cover the top and side surfaces of the semiconductor region 313 with the insulator 315 positioned therebetween. Note that the conductor 316 may be formed using a material for adjusting the work function. The transistor 300 is also referred to as FIN-type transistors because they each utilize a protruding portion of the semiconductor substrate. An insulator functioning as a mask for forming the protruding portion may be provided in contact with the top portion of the protruding portion. Although the case where the protruding portion is formed by processing part of the semiconductor substrate is described here, a semiconductor film having a protruding shape may be formed by processing an SOI substrate.

In the memory device illustrated in FIG. 18, a memory cell 650a and a memory cell 650b are arranged adjacent to each other. The transistor 300, the transistor 200, and the capacitor 100 are included and electrically connected to the wiring 1001, the wiring 1002, the wiring 1003, the wiring 1004, the wiring 1005, and the wiring 1006 in the memory cell 650a and the memory cell 650b. Also in the memory cell 650a and the memory cell 650b, a node where the gate of the transistor 300 and one electrode of the capacitor 100 are electrically connected to each other is referred to as the node SN. Note that the wiring 1002 is shared by the memory cell 650a and the memory cell 650b adjacent to each other.

Note that in the case where memory cells are arranged in an array, data of a desired memory cell needs to be read at the time of reading. For example, in the case where a memory cell array has a NOR-type structure, only data of a desired memory cell can be read by bringing the transistors 300 of memory cells from which data is not read into a non-conduction state. In that case, a potential at which the transistor 300 is brought into a “non-conduction state” regardless of the charge supplied to the node SN, that is, a potential lower than V_{th_H} is supplied to the wiring 1005 connected to the memory cells from which data is not read. Alternatively, in the case where a memory cell array has a NAND-type structure, for example, only data of a desired memory cell can be read by bringing the transistors 300 of memory cells from which data is not read into a conduction state. In that case, a potential at which the transistor 300 is brought into a “conduction state” regardless of the charge supplied to the node SN, that is, a potential higher than V_{th_L} is supplied to the wiring 1005 connected to the memory cells from which data is not read.

With the use of this structure, variation in electrical characteristics can be reduced and reliability can be improved in a semiconductor device using a transistor including an oxide semiconductor. Alternatively, power consumption of a semiconductor device using a transistor including an oxide semiconductor can be reduced. Alternatively, a semiconductor device using a transistor including an oxide semiconductor can be miniaturized or highly integrated. Alternatively, a miniaturized or highly integrated semiconductor device can be provided with high productivity.

The structure, composition, method, and the like described above in this embodiment can be used in an appropriate combination with the structures, compositions, methods, and the like described in the other embodiments.

### Embodiment 3

In this embodiment, an inverter circuit using the semiconductor device described in the above embodiment will be described. Note that in this specification, a high power supply voltage and a low power supply voltage are sometimes referred to as an H level (or VDD) and an L level (or GND), respectively.

### <Configuration Example of Inverter Circuit>

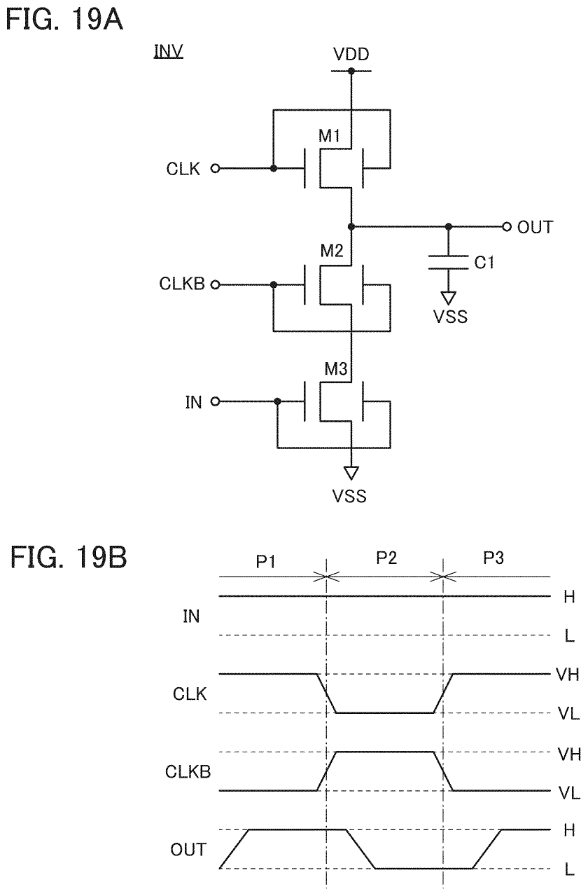

A circuit INV illustrated in FIG. 19(A) includes a capacitor C1, and a transistor M1, a transistor M2, and a transistor M3 which are connected in series. The circuit INV has a function of an inverter circuit.

The transistors M1 to M3 are n-channel transistors. The manufacturing cost of the circuit INV, which is configured with only n-channel transistors, can be reduced as compared to that of the inverter circuit, which is configured with CMOS transistors.

The transistor 200 described in the above embodiment is preferably used as each of the transistors M1 to M3.

The transistor M1 includes a first gate and a second gate which are electrically connected to each other. The first gate and the second gate include regions overlapping with each other with a semiconductor layer positioned therebetween. The same applies to the transistors M2 and M3. Note that the first gate and the second gate are sometimes referred to as a front gate and a back gate, respectively.

The circuit INV includes a terminal IN, a terminal OUT, a terminal CLK, and a terminal CLKB. The terminal IN functions as an input terminal, and the terminal OUT functions as an output terminal. A clock signal is input to the terminal CLK, and an inverted signal of the clock signal input to the terminal CLK is input to the terminal CLKB.

Moreover, the circuit INV is supplied with VDD and VSS as power supply voltages. The VDD, which is a high power supply voltage, is input to a drain of the transistor M1. The VSS, which is a low power supply voltage, is input to a source of the transistor M3.

In the transistor M1, the front gate and the back gate are electrically connected to the terminal CLK and a source is electrically connected to a drain of the transistor M2.

In the transistor M2, the front gate and the back gate are electrically connected to the terminal CLKB and a source is electrically connected to a drain of the transistor M3.

In the transistor M3, the front gate and the back gate are electrically connected to the terminal IN.

A first terminal of the capacitor C1 is electrically connected to the source of the transistor M1. The VSS is input to a second terminal of the capacitor C1.

The terminal OUT is electrically connected to the source of the transistor M1, the drain of the transistor M2, and the first terminal of the capacitor C1.

Note that parasitic capacitance of a wiring or gate capacitance of a transistor may be substituted for the capacitor C1. In that case, the area occupied by these semiconductor devices can be reduced.

Next, operation of the circuit INV will be described.

FIG. 19(B) is a timing chart for describing the operation of the circuit INV. Potential changes of terminals IN, CLK, CLKB, and OUT are each shown. In addition, FIG. 19(B) is divided into three periods of P1, P2, and P3.

An H level is supplied to the terminal IN during the periods P1 to P3. That is, during the periods P1 to P3, the transistor M3 is on.

In the period P1, a potential VH is input to the terminal CLK, and a potential VL is input to the terminal CLKB. The transistor M1 is turned on and the transistor M2 is turned off. At this time, the VDD is supplied to the capacitor C1 and the capacitor C1 starts to perform charge (precharge).

Note that the VH is preferably higher than a voltage (VDD+Vₜₕ) which is the sum of the VDD and the threshold voltage (Vₜₕ) of the transistor M1. Thus, the VDD can be accurately transmitted to the terminal OUT. It is only necessary that the VL be a power supply voltage (or GND). Note that the VH and the VL are sometimes referred to as a high potential and a low potential, respectively.

In the period P2, a VL is input to the terminal CLK, and a VH is input to the terminal CLKB. The transistor M1 is turned off and the transistor M2 is turned on. At this time, the transistor M3 is on; thus, the first terminal of the capacitor C1 and the source of the transistor M3 are each in a conduction state, so that the capacitor C1 starts to discharge. Finally, the terminal OUT outputs an L level. That is, the terminal OUT outputs an inverted signal of the signal input to the terminal IN.

In the period P3, a VH is input to the terminal CLK, and a VL is input to the terminal CLKB. The transistor M1 is turned on and the transistor M2 is turned off. The capacitor C1 starts to perform precharge again as in the period P1.

In the case where an input to the terminal IN in the periods P1 to P3 are each set to an L level, the terminal OUT outputs an H level in the period P2. That is, the terminal OUT outputs an inverted signal of the signal input to the terminal IN.

Thus, it is observed that the circuit INV performs precharge of the capacitor C1 when the terminal CLK is at a VH and operates as an inverter circuit when the terminal CLK is at a VL.

It is also observed that the circuit INV functions as a dynamic logic circuit that operates by repeating charge and discharge of the capacitor C1. The transistor M1 functions as a precharge transistor that charges the capacitor C1, and the transistor M2 functions as a discharge transistor that discharges the charges stored in the capacitor C1.

It is preferable to use transistors with a low off-state current for the transistors M1 to M3. Examples of the transistor with a low off-state current include a transistor using a metal oxide or an oxide semiconductor in a channel formation region (hereinafter referred to as an OS transistor). Note that here, a low off-state current refers to the off-state current of the transistor being preferably lower than or equal to 10⁻¹⁸ A/μm, further preferably lower than or equal to 10⁻²¹ A/μm, still further preferably lower than or equal to 10⁻²⁴ A/μm.

When an OS transistor is used as each of the transistors M1 to M3, the circuit INV can reduce a shoot-through current. As a result, the power consumption of the circuit INV can be reduced.

In addition, when an OS transistor is used as the transistors M1 to M3, loss of the charge precharged in the capacitor C1 due to leakage current can be prevented. As a result, the circuit INV can transmit data more accurately.

By electrical connection between the front gate and the back gate of the transistor M1, gate voltages of the front gate and the back gate can be applied to the semiconductor layer at the same time, whereby the on-state current can be increased. The same applies to the transistor M2 and the transistor M3. As a result, the circuit INV can achieve an inverter circuit with a high operation frequency.

In the circuit INV, the terminal IN may be electrically connected to the front gate and the back gate of the transistor M2 and the terminal CLKB may be electrically connected to the front gate and the back gate of the transistor M3.

The back gates of the transistors M1 to M3 may each be supplied with a potential different from that of the top gate. For example, the back gates of the transistors M1 to M3 may each be supplied with a common fixed potential. Thus, the circuit INV can control the threshold voltages of the transistors M1 to M3.

In addition, all of the back gates of the transistors M1 to M3 in the circuit INV may be omitted depending on circumstances. In that case, the manufacturing process of the circuit INV can be simplified.

As described above, the circuit INV can provide an inverter circuit which has low power consumption and is configured with transistors having the same conductivity type. In addition, the circuit INV can provide an inverter circuit which has high operation frequency and is configured with transistors having the same conductivity type.

The structure described in this embodiment can be used in an appropriate combination with the structures described in the other embodiments.

### Embodiment 4

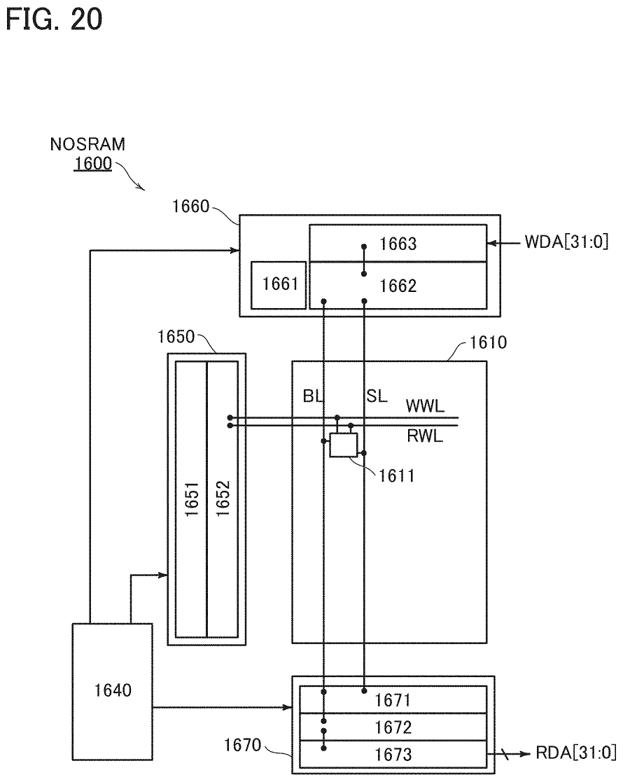

In this embodiment, a NOSRAM will be described as an example of a memory device, which is one embodiment of the present invention, including a transistor in which an oxide is used for a semiconductor (hereinafter referred to as an OS transistor) and a capacitor with reference to FIG. 20 to FIG. 22. A NOSRAM (registered trademark) is an abbreviation of “Nonvolatile Oxide Semiconductor RAM”, which indicates a RAM including a gain cell (2T or 3T) memory cell. Note that hereinafter, a memory device including an OS transistor, such as a NOSRAM, is referred to as an OS memory in some cases.

A memory device in which OS transistors are used in memory cells (hereinafter referred to as an “OS memory”) is used in a NOSRAM. The OS memory is a memory including at least a capacitor and an OS transistor that controls charge and discharge of the capacitor. The OS memory has excellent retention characteristics because the OS transistor has an extremely low off-state current and thus can function as a nonvolatile memory.

### <<NOSRAM>>

FIG. 20 illustrates a configuration example of a NOSRAM. A NOSRAM 1600 illustrated in FIG. 20 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL and RWL, bit lines BL, and source lines SL. The word lines WWL are write word lines and the word lines RWL are read word lines. In the NOSRAM 1600, one memory cell 1611 stores 3-bit (8-level) data.

The controller 1640 controls the NOSRAM 1600 as a whole and writes data WDA[31:0] and reads out data RDA[31:0]. The controller 1640 processes command signals from the outside (e.g., a chip enable signal and a write enable signal) to generate control signals of the row driver 1650, the column driver 1660, and the output driver 1670.

The row driver 1650 has a function of selecting a row to be accessed. The row driver 1650 includes a row decoder 1651 and a word line driver 1652.

The column driver 1660 drives the source lines SL and the bit lines BL. The column driver 1660 includes a column decoder 1661, a write driver 1662, and a DAC (digital-analog converter circuit) 1663.

The DAC 1663 converts 3-bit digital data into an analog voltage. The DAC 1663 converts 32-bit data WDA[31:0] into an analog voltage per 3 bits.

The write driver 1662 has a function of precharging the source lines SL, a function of bringing the source lines SL into an electrically floating state, a function of selecting a source line SL, a function of inputting a writing voltage generated in the DAC 1663 to the selected source line SL, a function of precharging the bit lines BL, a function of bringing the bit lines BL into an electrically floating state, and the like.

The output driver 1670 includes a selector 1671, an ADC (analog-digital converter circuit) 1672, and an output buffer 1673. The selector 1671 selects a source line SL to be accessed and transmits the voltage of the selected source line SL to the ADC 1672. The ADC 1672 has a function of converting an analog voltage into 3-bit digital data. The voltage of the source line SL is converted into 3-bit data in the ADC 1672, and the output buffer 1673 retains the data output from the ADC 1672.

Note that the configuration of the row driver 1650, the column driver 1660, and the output driver 1670 described in this embodiment is not limited to the above. The arrangement of the drivers and wirings connected to the drivers may be changed or the functions of the drivers and the wirings connected to the drivers may be changed or added, depending on the configuration, the driving method, or the like of the memory cell array 1610. For example, the bit lines BL may have part of a function of the source lines SL.

Note that although the amount of data retained in each of the memory cells 1611 is 3 bits in the above description, the structure of the memory device described in this embodiment is not limited thereto. The amount of data retained in each of the memory cells 1611 may be 2 bits or less or 4 bits or more. In the case where the amount of data retained in each of the memory cells 1611 is one bit, for example, the DAC 1663 and the ADC 1672 is not necessarily provided.

### <Memory Cell>

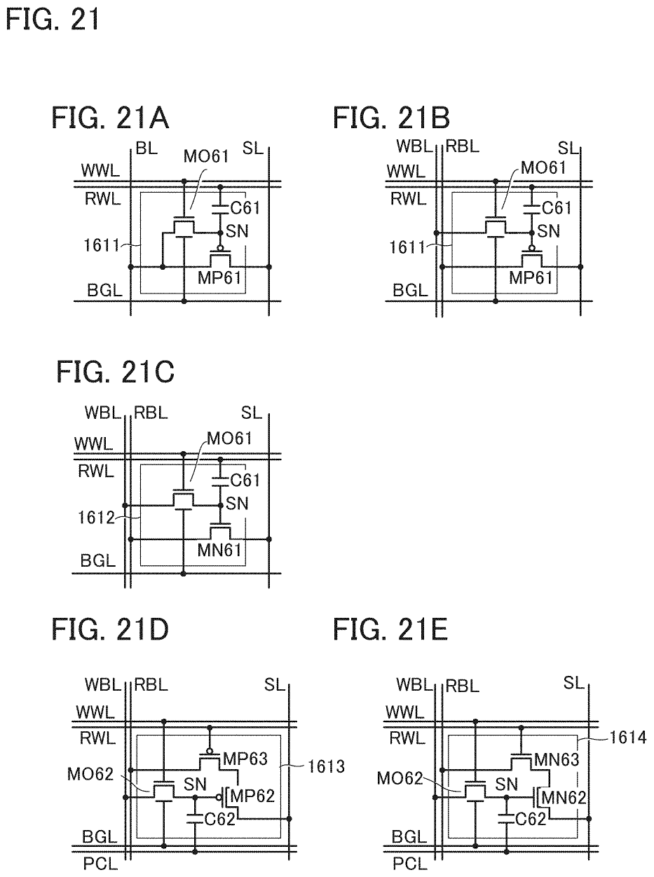

FIG. 21(A) is a circuit diagram showing a configuration example of the memory cell 1611. The memory cell 1611 is a 2T gain cell and the memory cell 1611 is electrically connected to the word lines WWL and RWL, the bit line BL, the source line SL, and a wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for retaining the voltage of the node SN. The node SN is a node for data retaining and corresponds to a gate of the transistor MP61 here.

The write transistor of the memory cell 1611 is formed using the OS transistor MO61; thus, the NOSRAM 1600 can retain data for a long time.

In the example of FIG. 21(A), write and read bit lines are a common bit line; however, as illustrated in FIG. 21(B), a bit line WBL functioning as a write bit line and a bit line RBL functioning as a read bit line may be provided.

FIG. 21(C) to FIG. 21(E) show other configuration examples of the memory cell. FIG. 21(C) to FIG. 21(E) show examples where the write bit line WBL and the read bit line RBL are provided; however, as in FIG. 21(A), a bit line shared in writing and reading may be provided.

A memory cell 1612 illustrated in FIG. 21(C) is a modification example of the memory cell 1611 where the read transistor is changed into an n-channel transistor (MN61). The transistor MN61 may be an OS transistor or a Si transistor.

In the memory cells 1611 and 1612, the OS transistor MO61 may be an OS transistor with no back gate.

A memory cell 1613 illustrated in FIG. 21(D) is a 3T gain cell and is electrically connected to the word lines WWL and RWL, the bit lines WBL and RBL, the source line SL, the wirings BGL, and wirings PCL. The memory cell 1613 includes the node SN, an OS transistor MO62, a transistor MP62, a transistor MP63, and a capacitor C62. The OS transistor MO62 is a write transistor. The transistor MP62 is a read transistor and the transistor MP63 is a selection transistor.

A memory cell 1614 illustrated in FIG. 21(E) is a modification example of the memory cell 1613 where the read transistor and the selection transistor are changed into n-channel transistors (MN62 and MN63). The transistors MN62 and MN63 may be OS transistors or Si transistors.

The OS transistors provided in the memory cell 1611 to the memory cell 1614 may each be a transistor with no back gate or a transistor with a back gate.

A so-called NOR memory device in which the memory cells 1611 or the like are connected in parallel is described above, but the memory device of this embodiment is not limited thereto. For example, a so-called NAND memory device in which memory cells 1615 described below are connected in series may be provided.

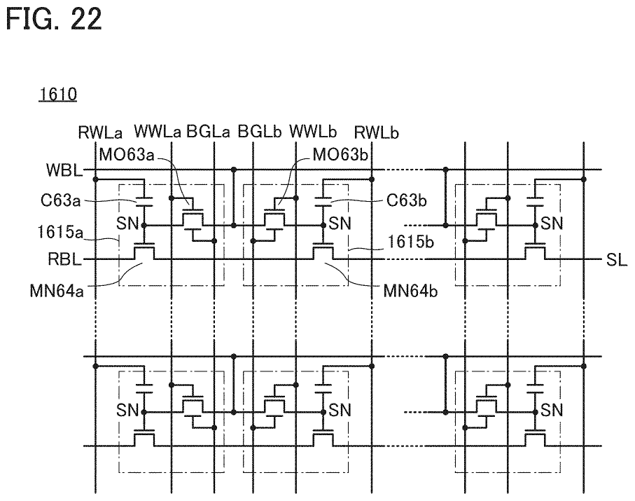

FIG. 22 is a circuit diagram showing a configuration example of the NAND memory cell array 1610. The memory cell array 1610 illustrated in FIG. 22 includes the source line SL, the bit line RBL, the bit line WBL, the word line WWL, the word line RWL, the wiring BGL, and the memory cell 1615. The memory cell 1615 includes the node SN, an OS transistor MO63, a transistor MN64, and a capacitor C63. Here, the transistor MN64 is an n-channel Si transistor, for example. The transistor MN64 is not limited thereto and may be a p-channel Si transistor or an OS transistor.

A memory cell 1615a and a memory cell 1615b, which are illustrated in FIG. 22, are described below as examples. Here, the character “a” or “b” is added to the reference numerals of the wirings and circuit elements connected to the memory cell 1615a or the memory cell 1615b.

In the memory cell 1615a, a gate of a transistor MN64a, one of a source and a drain of an OS transistor MO63a, and one electrode of a capacitor C63a are electrically connected to each other. The bit line WBL and the other of the source and the drain of the OS transistor MO63a are electrically connected to each other. A word line WWLa and a gate of the OS transistor MO63a are electrically connected to each other. A wiring BGLa and a back gate of the OS transistor MO63a are electrically connected to each other. A word line RWLa and the other electrode of the capacitor C63a are electrically connected to each other.

The memory cell 1615b can be provided to be symmetric to the memory cell 1615a with the use of a contact portion to the bit line WBL as a symmetry axis. Therefore, circuit elements of the memory cell 1615b are connected to wirings in a manner similar to that for the memory cell 1615a.

A source of the transistor MN64a of the memory cell 1615a is electrically connected to a drain of a transistor MN64b of the memory cell 1615b. A drain of the transistor MN64a of the memory cell 1615a is electrically connected to the bit line RBL. A source of the transistor MN64b of the memory cell 1615b is electrically connected to the source line SL through the transistors MN64 of the plurality of memory cells 1615. As described here, the plurality of transistors MN64 are connected in series between the bit line RBL and the source line SL in the NAND memory cell array 1610.

In a memory device including the memory cell array 1610 illustrated in FIG. 22, writing operation and reading operation are performed for every plurality of memory cells (hereinafter referred to as a memory cell column) connected to the same word line WWL (or the word line RWL). For example, the writing operation can be performed as follows. A potential at which the OS transistor MO63 is turned on is supplied to the word line WWL connected to a memory cell column on which writing is to be performed so that the OS transistors MO63 in the memory cell column on which writing is to be performed are turned on. Accordingly, the potential of the bit line WBL is supplied to the gates of the transistors MN64 and one electrode of the capacitors C63 in the selected memory cell column, whereby a predetermined charge is supplied to the gates. After that, when the OS transistors MO63 in the memory cell column are turned off, the predetermined charge supplied to the gates can be retained. Thus, data can be written to the memory cells 1615 in the selected memory cell column.

For example, the reading operation can be performed as follows. First, a potential at which the transistor MN64 is turned on is supplied to the word lines RWL not connected to a memory cell column on which reading is to be performed regardless of a charge supplied to the gates of the transistors MN64, so that the transistors MN64 in memory cell columns other than the memory cell column on which reading is to be performed are turned on. Then, a potential (reading potential) at which an on state or an off state of the transistor MN64 is selected is supplied to the word line RWL connected to the memory cell column on which reading is to be performed in accordance with a charge of the gates of the transistors MN64. After that, a constant potential is supplied to the source line SL and a reading circuit connected to the bit line RBL is operated. Here, the plurality of transistors MN64 between the source line SL and the bit line RBL are turned on except the transistor MN64 in the memory cell column on which reading is to be performed; therefore, the conductance between the source line SL and the bit line RBL depends on the state (an on state or an off state) of the transistor MN64 in the memory cell column on which reading is to be performed. Since the conductance of the transistor varies depending on the charge of the gate of the transistor MN64 in the memory cell column on which reading is to be performed, the potential of the bit line RBL varies accordingly. By reading the potential of the bit line RBL with the reading circuit, data can be read from the memory cell 1615 in the selected memory cell column.

There is theoretically no limitation on the number of rewriting operations of the NOSRAM 1600 because data is rewritten by charging and discharging the capacitor C61, the capacitor C62, or the capacitor C63; and writing and reading of data can be performed with low energy. Furthermore, since data can be retained for a long time, the refresh rate can be reduced.

In the case where the semiconductor device described in any of the above embodiments is used for the memory cells 1611, 1612, 1613, and 1614, the transistors 200 can be used as the OS transistors MO61, MO62, and MO63, the capacitors 100 can be used as the capacitors C61, C62, and C63, and the transistors 300 can be used as the transistors MP61, MP62, MP63, MN61, MN62, MN63, and MN64. Thus, the area occupied by one set consisting of a transistor and a capacitor can be reduced when seen from the above, so that the memory device of this embodiment can be further highly integrated. As a result, storage capacity per unit area of the memory device of this embodiment can be increased.

The structure described in this embodiment can be used in an appropriate combination with the structures described in the other embodiments.

### Embodiment 5

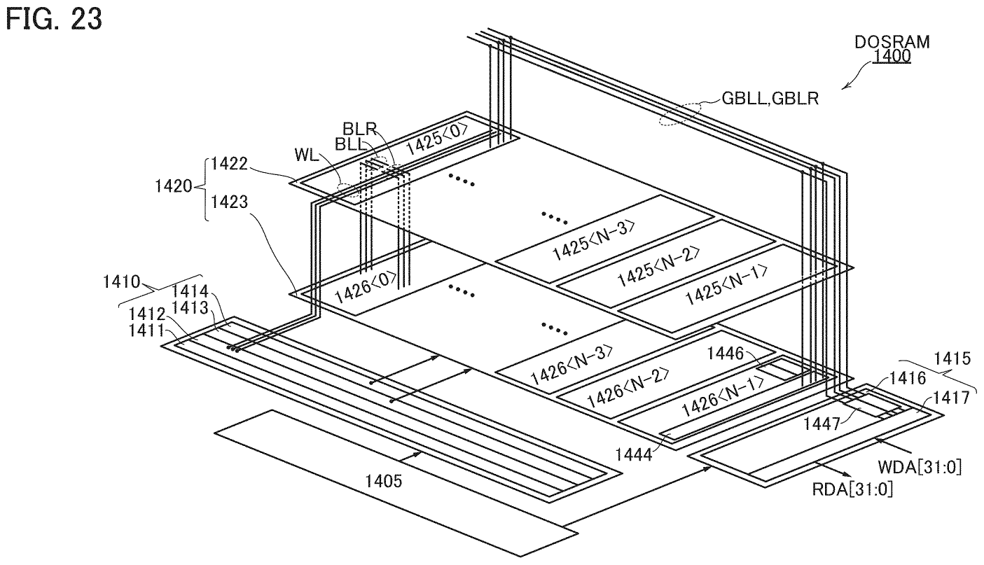

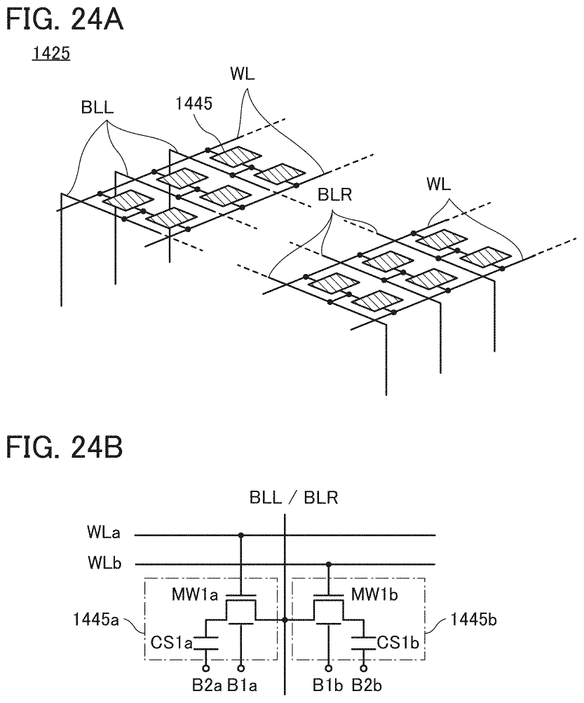

In this embodiment, a DOSRAM will be described as an example of the memory device of one embodiment of the present invention that includes an OS transistor and a capacitor, with reference to FIG. 23 and FIG. 24. A DOSRAM (registered trademark) is an abbreviation of “Dynamic Oxide Semiconductor RAM,” which is a RAM including a 1T (transistor) 1C (capacitor) memory cell. As in the NOSRAM, an OS memory is used in the DOSRAM.

### <<DOSRAM 1400>>

FIG. 23 shows a configuration example of the DOSRAM. As shown in FIG. 23, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1>, where N is an integer greater than or equal to 2. FIG. 24(A) illustrates a configuration example of the local memory cell array 1425. The local memory cell array 1425 includes a plurality of memory cells 1445, a plurality of word lines WL, and a plurality of bit lines BLL and BLR. In the example of FIG. 24(A), the local memory cell array 1425 has an open bit-line architecture but may have a folded bit-line architecture.

FIG. 24(B) shows a circuit configuration example of a pair of memory cells 1445a and 1445b connected to the same bit line BLL (BLR). The memory cell 1445a includes a transistor MW1a, a capacitor CS1a, and terminals B1a and B2a, and is connected to a word line WLa and the bit line BLL (BLR). The memory cell 1445b includes a transistor MW1b, a capacitor CS1b, and terminals B1b and B2b, and is connected to a word line WLb and the bit line BLL (BLR). Note that hereinafter, in the case where either the memory cell 1445a or the memory cell 1445b is not particularly limited, reference numerals without the letter “a” or “b” are used for the memory cell 1445 and its components, in some cases.

The transistor MW1a has a function of controlling the charging and discharging of the capacitor CS1a, and the transistor MW1b has a function of controlling the charging and discharging of the capacitor CS1b. A gate of the transistor MW1a is electrically connected to the word line WLa, a first terminal of the transistor MW1a is electrically connected to the bit line BLL (BLR), and a second terminal of the transistor MW1a is electrically connected to a first terminal of the capacitor CS1a. A gate of the transistor MW1b is electrically connected to the word line WLb, a first terminal of the transistor MW1b is electrically connected to the bit line BLL (BLR), and a second terminal of the transistor MW1b is electrically connected to a first terminal of the capacitor CS1b. In this way, the bit line BLL (BLR) is shared by the first terminal of the transistor MW1a and the first terminal of the transistor MW1b.

The transistor MW1 has a function of controlling charging and discharging of the capacitor CS1. A second terminal of the capacitor CS1 is electrically connected to the terminal B2. A constant voltage (e.g., a low power supply voltage) is input to the terminal B2.

In the case where the semiconductor device described in any of the above embodiments is used in the memory cells 1445a and 1445b, the transistor 200 can be used as the transistor MW1a or the transistor MW1b, and the capacitor 100 can be used as the capacitor CS1a or the capacitor CS1b. Thus, the area occupied by one set consisting of a transistor and a capacitor in the top view can be reduced, so that the memory device of this embodiment can be further highly integrated. As a result, storage capacity per unit area of the memory device of this embodiment can be increased.

The transistor MW1 includes a back gate, and the back gate is electrically connected to the terminal B1. This makes it possible to change the threshold voltage of the transistor MW1 with a voltage of the terminal B1. For example, the voltage of the terminal B1 is a fixed voltage (e.g., a negative constant voltage); alternatively, the voltage of the terminal B1 may be changed in response to the operation of the DOSRAM 1400.

The back gate of the transistor MW1 may be electrically connected to the gate, the source, or the drain of the transistor MW1. Alternatively, the back gate is not necessarily provided in the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a voltage difference between the bit line pair, and a function of retaining the voltage difference. The switch array 1444 has a function of selecting a bit line pair and bringing the selected bit line pair and a global bit line pair into a conduction state.

Here, a bit line pair refers to two bit lines which are compared by a sense amplifier at the same time. A global bit line pair refers to two global bit lines which are compared by a global sense amplifier at the same time. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signal from the sense amplifier driver circuit 1414, the plurality of local sense amplifier arrays 1426 are independently driven.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference between the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a target column. The local sense amplifier array 1426 amplifies the written data, and retains the amplified data. In the specified local memory cell array 1425, the word line WL of a target row is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified by an address signal. In the specified local memory cell array 1425, the word line WL of a target row is in a selected state, and data of the memory cell 1445 is written to the bit line. The local sense amplifier array 1426 detects a voltage difference between the bit line pair of each column as data, and retains the data. Among the data retained at the local sense amplifier array 1426, the data of a column specified by the address signal is written to the global bit line pair by the switch array 1444. The global sense amplifier array 1416 determines and retains the data of the global bit line pair. The data retained in the global sense amplifier array 1416 is output to the input/output circuit 1417. Thus, the data reading operation is completed.

There is theoretically no limitation on the number of rewriting operations of the DOSRAM 1400 because data is rewritten by charging and discharging of the capacitor CS1; and data can be written and read with low energy. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is much longer than that of a DRAM. This allows less frequent refresh, which can reduce the power needed for refresh operations. Thus, the DOSRAM 1400 is suitable for a memory device that rewrites a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which can reduce the storage capacitance of the memory cell 1445. In addition, providing the switch array 1444 in the local sense amplifier array 1426 can reduce the number of long bit lines. For the reasons described above, a driving load during access to the DOSRAM 1400 is reduced, enabling a reduction in power consumption.

The structure described in this embodiment can be used in an appropriate combination with the structures described in the other embodiments.

### Embodiment 6

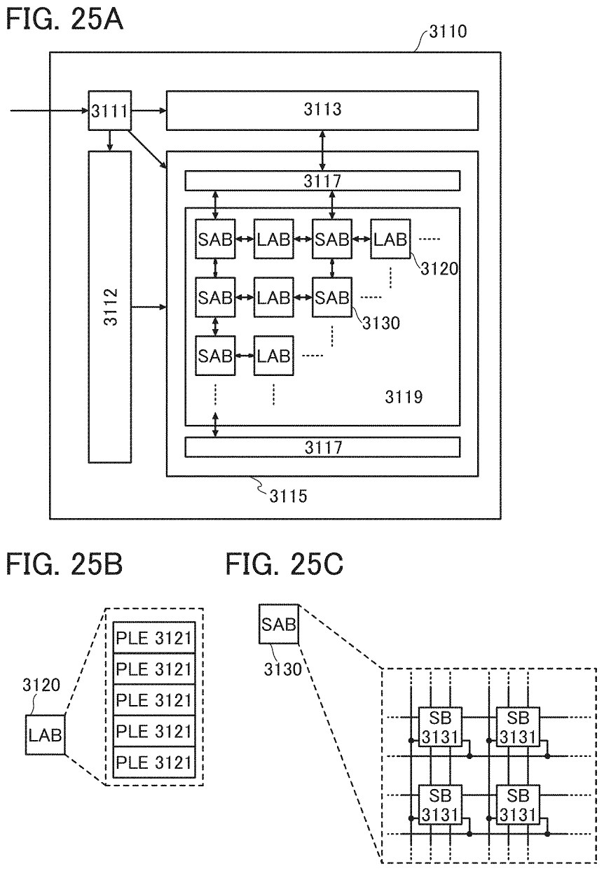

In this embodiment, an FPGA (field programmable gate array) will be described as an example of a semiconductor device of one embodiment of the present invention in which an OS transistor and a capacitor are used, with reference to FIG. 25 to FIG. 28. In the FPGA of this embodiment, an OS memory is used for a configuration memory and a register. Here, such an FPGA is referred to as an “OS-FPGA”.

<<OS-FPGA>>

FIG. 25(A) illustrates a configuration example of an OS-FPGA. An OS-FPGA 3110 illustrated in FIG. 25(A) is capable of NOFF (normally-off) computing that executes context switching by a multi-context configuration and fine-grained power gating. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 25(B) illustrates an example in which the LAB 3120 includes five PLEs 3121. As illustrated in FIG. 25(C), the SAB 3130 includes a plurality of switch blocks (SBs) 3131 arranged in an array. The LAB 3120 is connected to the LABs 3120 in four directions (on the left, right, top, and bottom sides) through its input terminals and the SABs 3130.

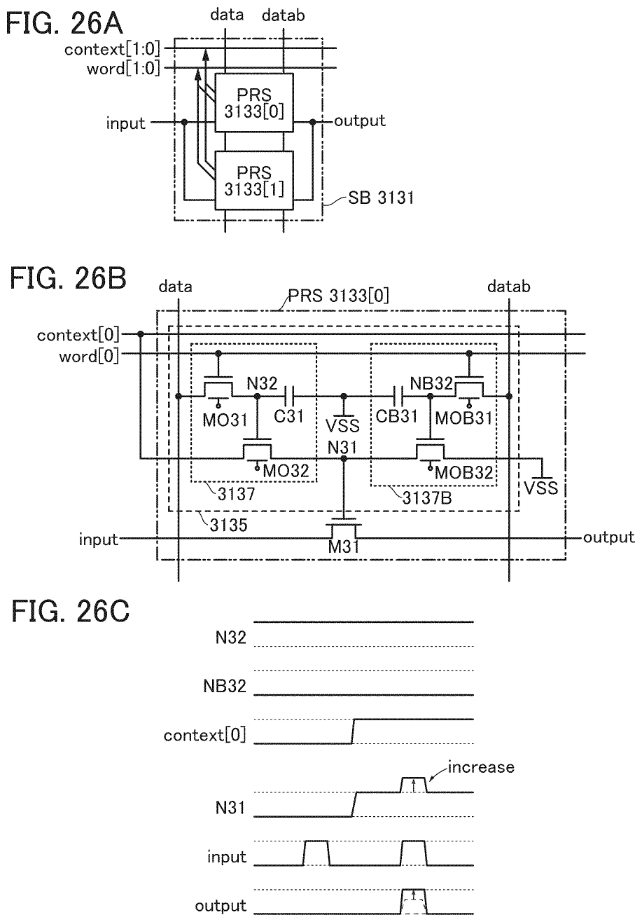

The SB 3131 will be described with reference to FIG. 26(A) to FIG. 26(C). To the SB 3131 illustrated in FIG. 26(A), data, datab, and signals context[1:0] and word[1:0] are input. The data and the datab are configuration data, and the logics of the data and the datab have a complementary relationship. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes PRSs (programmable routing switches) 3133[0] and 3133[1]. The PRSs 3133[0] and 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 26(B) illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal that are input. The signals context[0] and word[0] are input to the PRS 3133[0], and the signals context[1] and word[1] are input to the PRS 3133[1]. For example, in the SB 3131, when the signal context[0] is set to “H”, the PRS 3133[0] is activated.

The PRS 3133[0] includes a CM 3135 and a Si transistor M31. The Si transistor M31 is a pass transistor that is controlled by the CM 3135. The CM 3135 includes memory circuits 3137 and 3137B. The memory circuits 3137 and 3137B have the same circuit configuration. The memory circuit 3137 includes a capacitor C31 and OS transistors MO31 and MO32. The memory circuit 3137B includes a capacitor CB31 and OS transistors MOB31 and MOB32.

In the case where the semiconductor device described in any of the above embodiments is used in the SAB 3130, the transistor 200 can be used as the OS transistors MO31 and MOB31, and the capacitor 100 can be used as the capacitors C31 and CB31. Thus, the area occupied by one set consisting of a transistor and a capacitor in the top view can be reduced, so that the semiconductor device of this embodiment can be further highly integrated.

The OS transistors MO31, MO32, MOB31, and MOB32 each include a back gate, and each of these back gates are electrically connected to a power supply line that supplies a fixed voltage.

A gate of the Si transistor M31, a gate of the OS transistor MO32, and a gate of the OS transistor MOB32 correspond to a node N31, a node N32, and a node NB32, respectively. The node N32 and the node NB32 are each a charge retention node of the CM 3135. The OS transistor MO32 controls the conduction state between the node N31 and a signal line for the signal context[0]. The OS transistor MOB32 controls the conduction state between the node N31 and a low-potential power supply line VSS.

Data retained in the memory circuits 3137 and 3137B have a complementary relationship. Thus, either the OS transistor MO32 or MOB32 is turned on.

The operation example of the PRS 3133[0] will be described with reference to FIG. 26(C). Configuration data has already been written to the PRS 3133[0], and the node N32 is at “H” and the node NB32 is at “L” in the PRS 3133[0].

The PRS 3133[0] is inactive while the signal context[0] is at “L”. During this period, even when an input terminal of the PRS 3133[0] is transferred to “H”, the gate of the Si transistor M31 is kept at “L” and an output terminal of the PRS 3133[0] is also kept at “L”.

The PRS 3133[0] is active while the signal context[0] is at “H”. When the signal context[0] is transferred to “H”, the gate of the Si transistor M31 is transferred to “H” by the configuration data stored in the CM 3135.

When the input terminal is transferred to “H” during a period in which the PRS 3133[0] is active, the gate voltage of the Si transistor M31 is increased by boosting because the OS transistor MO32 of the memory circuit 3137 is a source follower. As a result, the OS transistor MO32 of the memory circuit 3137 loses the driving capability, and the gate of the Si transistor M31 is brought into a floating state.

In the PRS 3133 with a multi-context function, the CM 3135 also functions as a multiplexer.

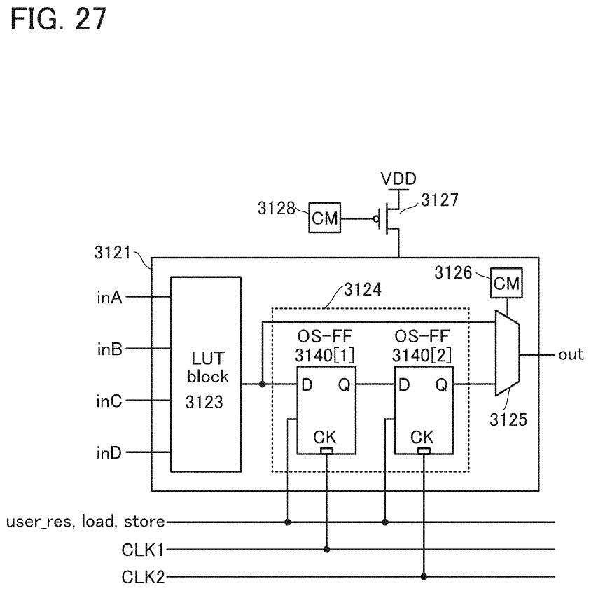

FIG. 27 illustrates a configuration example of the PLE 3121. The PLE 3121 includes an LUT (lookup table) block 3123, a register block 3124, a selector 3125, and a CM 3126. The LUT block 3123 is configured to multiplex an output of a pair of 16-bit CMs therein in accordance with inputs inA to inD. The selector 3125 selects an output of the LUT block 3123 or an output of the register block 3124 in accordance with the configuration stored in the CM 3126.

The PLE 3121 is electrically connected to a power supply line for a voltage VDD through a power switch 3127. Whether the power switch 3127 is turned on or off is determined in accordance with configuration data stored in a CM 3128. Providing the power switch 3127 for each PLE 3121 enables fine-grained power gating. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as [OS-FF]).

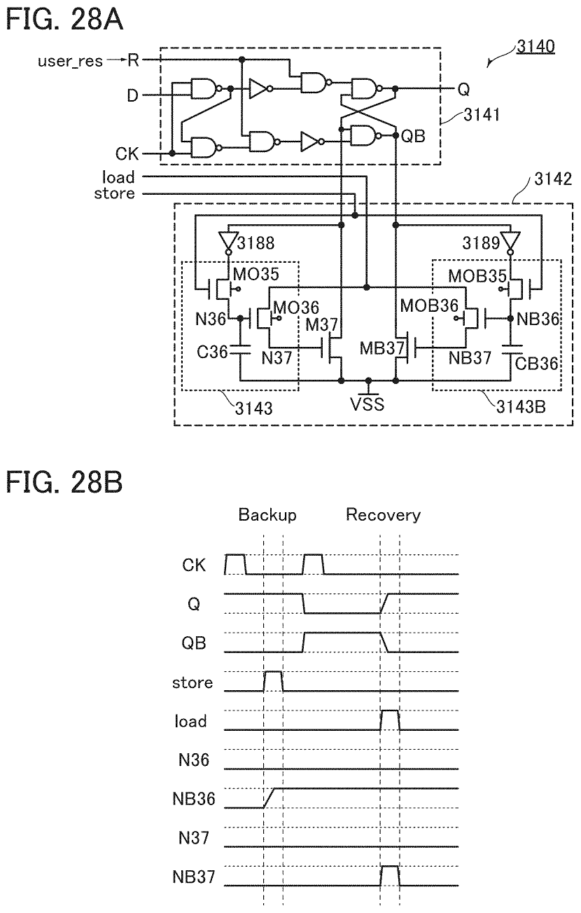

The register block 3124 includes OS-FFs 3140[1] and 3140[2]. Signals user_res, load, and store are input to the OS-FFs 3140[1] and 3140[2]. A clock signal CLK1 is input to the OS-FF 3140[1] and a clock signal CLK2 is input to the OS-FF 3140[2]. FIG. 28(A) illustrates a configuration example of the OS-FF 3140.

The OS-FF 3140 includes an FF 3141 and a shadow register 3142. The FF 3141 includes nodes CK, R, D, Q, and QB. A clock signal is input to the node CK. The signal user_res is input to the node R. The signal user_res is a reset signal. The node D is a data input node, and the node Q is a data output node. The logics of the node Q and the node QB have a complementary relationship.

The shadow register 3142 functions as a backup circuit of the FF 3141. The shadow register 3142 backs up data of the nodes Q and QB in response to the signal store and writes back the backed up data to the nodes Q and QB in response to the signal load.

The shadow register 3142 includes inverter circuits 3188 and 3189, Si transistors M37 and MB37, and memory circuits 3143 and 3143B. The memory circuits 3143 and 3143B each have the same circuit configuration as the memory circuit 3137 of the PRS 3133. The memory circuit 3143 includes a capacitor C36 and OS transistors MO35 and MO36. The memory circuit 3143B includes a capacitor CB36, an OS transistor MOB35, and an OS transistor MOB36. A node N36 and a node NB36 correspond to a gate of the OS transistor MO36 and a gate of the OS transistor MOB36, respectively, and are each a charge retention node. A node N37 and a node NB37 correspond to a gate of the Si transistor M37 and a gate of the Si transistor MB37, respectively.

In the case where the semiconductor device described in any of the above embodiments is used in the LAB 3120, the transistor 200 can be used as the OS transistors MO35 and MOB35, and the capacitor 100 can be used as the capacitors C36 and CB36. Thus, the area occupied by one set consisting of a transistor and a capacitor in the top view can be reduced, so that the semiconductor device of this embodiment can be further highly integrated.

The OS transistors MO35, MO36, MOB35, and MOB36 each include a back gate, and each of these back gates are electrically connected to a power supply line that supplies a fixed voltage.

An example of an operation method of the OS-FF 3140 will be described with reference to FIG. 28(B).

### (Backup)

When the signal store at “H” is input to the OS-FF 3140, the shadow register 3142 backs up data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the nodes Q and QB of the FF 3141 are lost, the shadow register 3142 retains the backed up data even when power supply is stopped.

### (Recovery)

The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 is recovered to a state at the backup operation.

A combination of the fine-grained power gating and backup/recovery operation of the OS-FF 3140 allows power consumption of the OS-FPGA 3110 to be effectively reduced.

As an error that might occur in a memory circuit, a soft error due to the entry of radiation is given. The soft error is a phenomenon in which a malfunction such as inversion of data stored in a memory is caused by electron-hole pair generation when a transistor is irradiated with a rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory using an OS transistor has a high soft-error tolerance. Therefore, the OS-FPGA 3110 with high reliability can be provided when an OS memory is included therein.

The structure described in this embodiment can be used in an appropriate combination with the structures described in the other embodiments.

### Embodiment 7

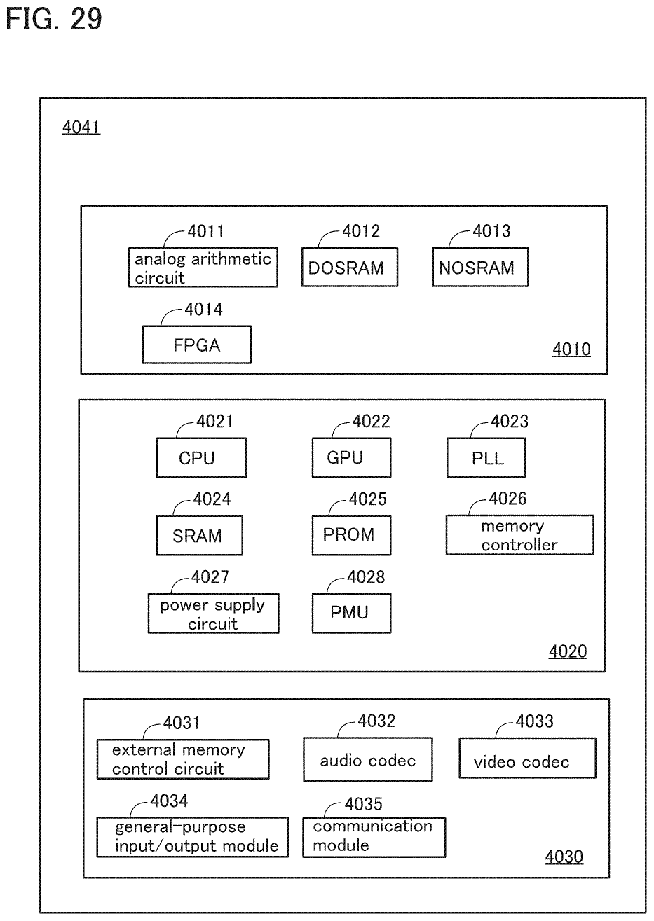

In this embodiment, an AI system in which the semiconductor device of any of the above embodiments is used will be described with reference to FIG. 29.

FIG. 29 is a block diagram illustrating a configuration example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiment can be used as the DOSRAM 4012, the NOSRAM 4013, and the FPGA 4014, respectively.

The control portion 4020 includes a CPU (Central Processing Unit) 4021, a GPU (Graphics Processing Unit) 4022, a PLL (Phase Locked Loop) 4023, an SRAM (Static Random Access Memory) 4024, a PROM (Programmable Read Only Memory) 4025, a memory controller 4026, a power supply circuit 4027, and a PMU (Power Management Unit) 4028.

The input/output portion 4030 includes an external memory control circuit 4031, an audio codec 4032, a video codec 4033, a general-purpose input/output module 4034, and a communication module 4035.

The arithmetic portion 4010 can execute learning or inference by a neural network.

The analog arithmetic circuit 4011 includes an A/D (analog/digital) converter circuit, a D/A (digital/analog) converter circuit, and a product-sum operation circuit.

The analog arithmetic circuit 4011 is preferably formed using an OS transistor. The analog arithmetic circuit 4011 using an OS transistor includes an analog memory and can execute a product-sum operation necessary for the learning or inference with low power consumption.

The DOSRAM 4012 is a DRAM formed using an OS transistor, and the DOSRAM 4012 is a memory that temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data have to be stored piece by piece because of the circuit area limitation and small storage capacity of the SRAM. The DOSRAM 4012 has a larger storage capacity than an SRAM because the memory cells can be highly integrated even in a limited circuit area. Therefore, the DOSRAM 4012 can efficiently store the input data.

The NOSRAM 4013 is a nonvolatile memory using an OS transistor. The NOSRAM 4013 consumes less power in writing data than the other nonvolatile memories such as a flash memory, a ReRAM (Resistive Random Access Memory), and an MRAM (Magnetoresistive Random Access Memory). Furthermore, unlike a flash memory and a ReRAM in which elements deteriorate by data writing, there is no limitation on the number of times of data writing.

Furthermore, the NOSRAM 4013 can store multilevel data of two or more bits as well as one-bit binary data. The multilevel data storage in the NOSRAM 4013 leads to a reduction in the memory cell area per bit.

Furthermore, the NOSRAM 4013 can store analog data as well as digital data. Thus, the analog arithmetic circuit 4011 can use the NOSRAM 4013 as an analog memory. The NOSRAM 4013 can store analog data as it is, and thus a D/A converter circuit and an A/D converter circuit are not necessary. Therefore, the area of a peripheral circuit for the NOSRAM 4013 can be reduced. Note that in this specification, analog data refers to data having a resolution of three bits (eight levels) or more. The above-described multilevel data is included in the analog data in some cases.

Data and parameters used in the neural network calculation can be once stored in the NOSRAM 4013. The data and parameters may be stored in a memory provided outside the AI system 4041 via the CPU 4021; however, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA using an OS transistor. With the use of the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), or a deep belief network (DBN) described later, with a hardware. Establishing the connection of the neural network with a hardware enables higher speed performance.

The FPGA 4014 is an FPGA including an OS transistor. An OS-FPGA can have a smaller memory area than an FPGA including an SRAM. Thus, addition of a context switching function only causes a small increase in area. Moreover, an OS-FPGA can transmit data and parameters at high speed by boosting.

In the AI system 4041, the analog arithmetic circuit 4011, the DOSRAM 4012, the NOSRAM 4013, and the FPGA 4014 can be provided on one die (chip). Thus, the AI system 4041 can execute calculation of the neural network quickly with low power consumption. In addition, the analog arithmetic circuit 4011, the DOSRAM 4012, the NOSRAM 4013, and the FPGA 4014 can be fabricated through the same manufacturing process. Therefore, the AI system 4041 can be fabricated at low cost.

Note that the arithmetic portion 4010 does not necessarily include all of the following: the DOSRAM 4012, the NOSRAM 4013, and the FPGA 4014. One or more memories selected from the DOSRAM 4012, the NOSRAM 4013, and the FPGA 4014 are provided in accordance with a problem that is desired to be solved by the AI system 4041.

The AI system 4041 can execute a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for executing at least one of these methods. Furthermore, part or the whole of the program may be stored in the NOSRAM 4013.

Most of the existing programs used as libraries are premised on processing with a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be executed at high speed.

The power supply circuit 4027 generates not only a low power supply potential for a logic circuit but also a potential for an analog operation. The power supply circuit 4027 may use an OS memory. When a reference potential is stored in the OS memory, the power consumption of the power supply circuit 4027 can be reduced.

The PMU 4028 has a function of temporarily stopping the power supply to the AI system 4041.

The CPU 4021 and the GPU 4022 preferably include OS memories as registers. By including the OS memories, the CPU 4021 and the GPU 4022 can retain data (logic values) in the OS memories even when power supply is stopped. As a result, the AI system 4041 can save the power.

The PLL 4023 has a function of generating a clock. The AI system 4041 performs an operation on the basis of the clock generated by the PLL 4023. The PLL 4023 preferably includes an OS memory. By including the OS memory, the PLL 4023 can retain an analog potential with which the clock oscillation frequency is controlled.

The AI system 4041 may store data in an external memory such as a DRAM. For this reason, the AI system 4041 preferably includes the memory controller 4026 functioning as an interface with the external DRAM. Furthermore, the memory controller 4026 is preferably positioned near the CPU 4021 or the GPU 4022. Thus, data transmission can be performed at high speed.

Some or all of the circuits illustrated in the control portion 4020 can be formed on the same die as the arithmetic portion 4010. Thus, the AI system 4041 can execute the neural network calculation at high speed with low power consumption.

Data used for the neural network calculation is stored in an external storage device (such as an HDD (Hard Disk Drive) or an SSD (Solid State Drive)) in many cases. Therefore, the AI system 4041 preferably includes the external memory control circuit 4031 functioning as an interface with the external storage device.

Because the neural network often deals with audio and video for learning and inference, the AI system 4041 includes the audio codec 4032 and the video codec 4033. The audio codec 4032 encodes and decodes audio data, and the video codec 4033 encodes and decodes video data.

The AI system 4041 can perform learning or inference using data obtained from an external sensor. For this reason, the AI system 4041 includes the general-purpose input/output module 4034. The general-purpose input/output module 4034 includes a USB (Universal Serial Bus) or an I2C (Inter-Integrated Circuit), for example.

The AI system 4041 can perform learning or inference using data obtained via the Internet. For this reason, the AI system 4041 preferably includes the communication module 4035.

The analog arithmetic circuit 4011 may use a multi-level flash memory as an analog memory. However, the flash memory has a limitation on the number of rewriting times. In addition, it is extremely difficult to embed the multi-level flash memory (to form the arithmetic circuit and the memory on the same die).

Alternatively, the analog arithmetic circuit 4011 may use a ReRAM as an analog memory. However, the ReRAM has a limitation on the number of rewriting times and also has a problem in storage accuracy. Moreover, the ReRAM is a two-terminal element, and thus has a complicated circuit design for separating data writing and data reading.

Further alternatively, the analog arithmetic circuit 4011 may use an MRAM as an analog memory. However, the MRAM has a problem in storage accuracy because of its low magnetoresistive ratio.

In consideration of the above, the analog arithmetic circuit 4011 preferably uses an OS memory as an analog memory.

The structure described in this embodiment can be used in an appropriate combination with the structures described in the other embodiments.

### Embodiment 8

### <Application Example of AI System>

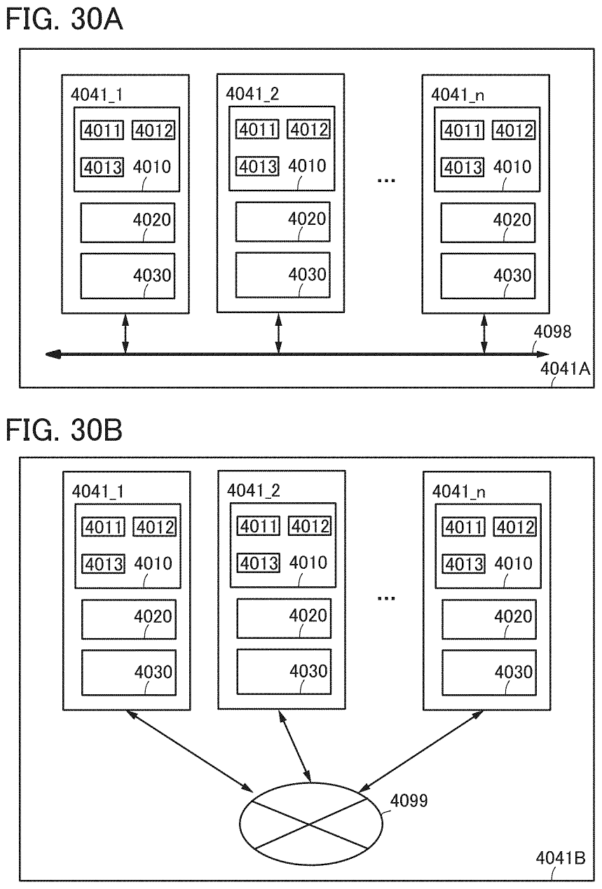

In this embodiment, application examples of the AI system described in the above embodiment will be described with reference to FIG. 30.

FIG. 30(A) illustrates an AI system 4041A in which the AI systems 4041 described with FIG. 29 are arranged in parallel and a signal can be transmitted between the systems via a bus line.

The AI system 4041A illustrated in FIG. 30(A) includes a plurality of AI systems 4041_1 to 4041_n (n is a natural number). The AI system 4041_1 to the AI system 4041_n are connected to each other via a bus line 4098.

FIG. 30(B) illustrates an AI system 4041B in which the AI systems 4041 described with FIG. 29 are arranged in parallel as in FIG. 30(A) and a signal can be transmitted between the systems via a network.

The AI system 4041B illustrated in FIG. 30(B) includes the plurality of AI systems 4041_1 to 4041_n. The AI system 4041_1 to the AI system 4041_n are connected to each other via a network 4099.

It is only necessary that a structure in which a communication module is provided in each of the AI systems 4041_1 to 4041_n to perform wireless or wired communication via the network 4099 be employed. A communication module can communicate via an antenna. For example, the communication can be performed in such a manner that an electronic device is connected to a computer network such as the Internet that is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA 2000 (Code Division Multiple Access 2000), or W-CDMA (registered trademark), or a communications standard developed by IEEE such as Wi-Fi (registered trademark), Bluetooth (registered trademark), or ZigBee (registered trademark).

With the configuration illustrated in FIG. 30(A) or 30(B), analog signals obtained with external sensors or the like can be processed by different AI systems. For example, analog signals containing biological information such as brain waves, a pulse, blood pressure, and body temperature obtained with a variety of sensors such as a brain wave sensor, a pulse wave sensor, a blood pressure sensor, and a temperature sensor can be processed by different AI systems. Since each of the AI systems performs signal processing or learning, the amount of information processed by each AI system can be reduced. Accordingly, the signal processing or learning requires a smaller amount of arithmetic processing. As a result, recognition accuracy can be increased. The information obtained with each AI system is expected to enable instant understanding of collective biological information that irregularly changes.

The structure described in this embodiment can be used in an appropriate combination with the structures described in the other embodiments.

### Embodiment 9

In this embodiment, an example of an IC into which the AI system described in the above embodiment is incorporated will be described.

In the AI system described in the above embodiment, a digital processing circuit such as a CPU that includes a Si transistor, an analog arithmetic circuit that uses an OS transistor, an OS-FPGA, and an OS memory such as a DOSRAM or a NOSRAM can be integrated into one die.

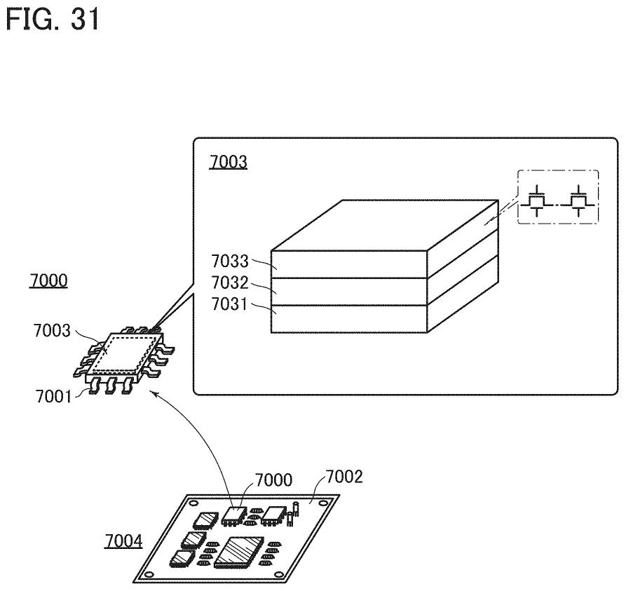

FIG. 31 illustrates the example of the IC into which the AI system is incorporated. An AI system IC 7000 illustrated in FIG. 31 includes a lead 7001 and a circuit portion 7003. The AI system IC 7000 is mounted on a printed circuit board 7002, for example. A plurality of such IC chips are combined and electrically connected to each other on the printed circuit board 7002; thus, a board on which electronic components are mounted (a circuit board 7004) is completed. In the circuit portion 7003, the various circuits described in the above embodiment are provided on one die. The circuit portion 7003 has a stacked-layer structure as described in the above embodiment, and is broadly divided into a Si transistor layer 7031, a wiring layer 7032, and an OS transistor layer 7033. Since the OS transistor layer 7033 can be provided to be stacked over the Si transistor layer 7031, the size of the AI system IC 7000 can be easily reduced.

Although a QFP (Quad Flat Package) is used as a package of the AI system IC 7000 in FIG. 31, the embodiment of the package is not limited thereto.

The digital processing circuit such as a CPU, the analog arithmetic circuit that uses an OS transistor, the OS-FPGA, and the OS memory such as a DOSRAM or a NOSRAM can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly the AI system can be incorporated into the IC at low cost.

The structure described in this embodiment can be used in an appropriate combination with the structures described in the other embodiments.

### Embodiment 10

### <Electronic Device>

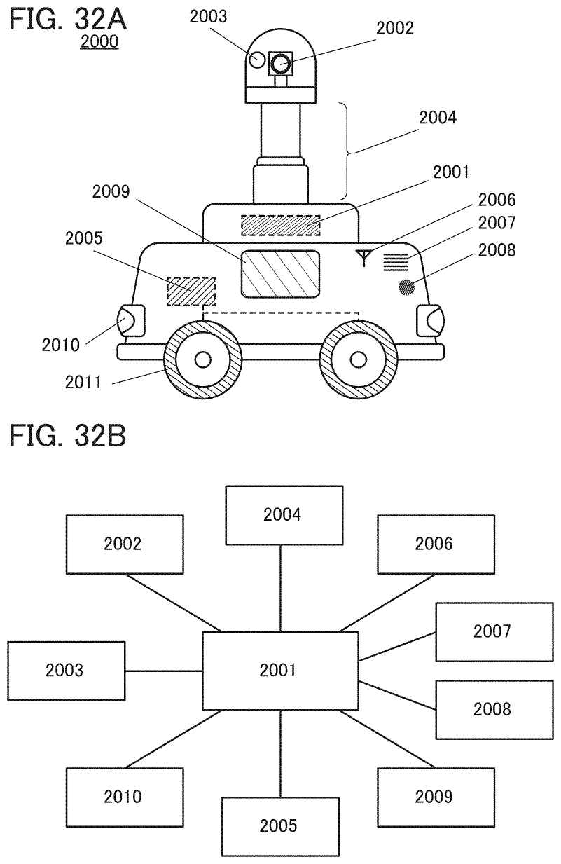

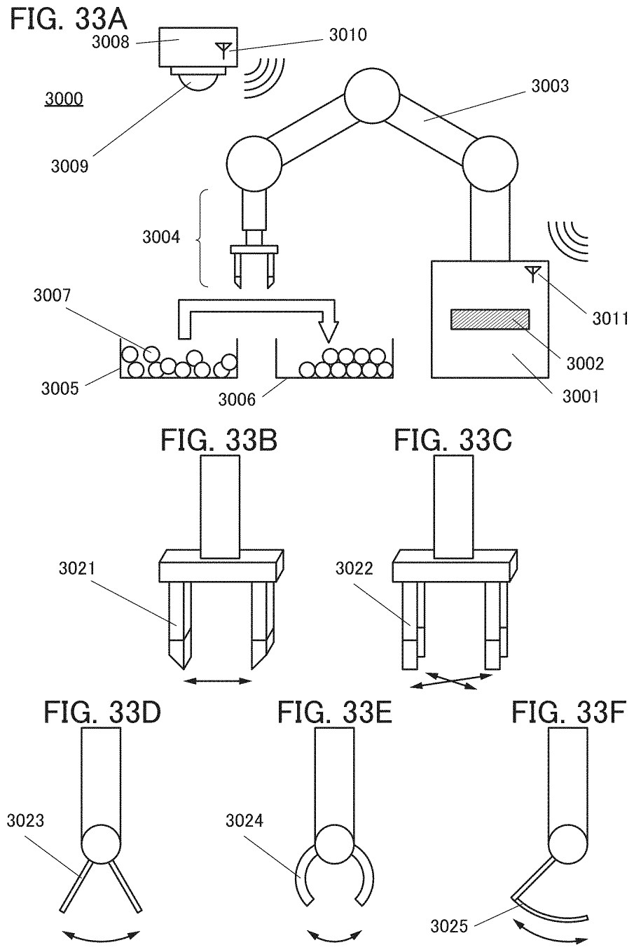

A semiconductor device of one embodiment of the present invention can be used for a variety of electronic devices. FIG. 32 and FIG. 33 illustrate specific examples of the electronic devices using the semiconductor device of one embodiment of the present invention.

A robot 2000 illustrated in FIG. 32(A) includes an arithmetic device 2001, a sensor 2002, a light 2003, a lift 2004, a driver portion 2005, and a moving mechanism 2011, and can take a still image and a moving image while moving. Such a robot can be used for a security system or a monitoring system.

The robot 2000 may further include a communication means 2006, a speaker 2007, a microphone 2008, a display portion 2009, a light-emitting portion 2010, and the like.

In the arithmetic device 2001, the semiconductor device of one embodiment of the present invention can be used. As the arithmetic device 2001, an IC in which the AI system of one embodiment of the present invention is incorporated can be used. The sensor 2002 functions as a camera which takes photographs of surroundings of the robot 2000. The light 2003 can be used as light when the photographs of the surroundings of the robot 2000 are taken by the sensor 2002. When a photograph of a still image is taken by the sensor 2002, the light 2003 preferably functions as a flashlight. The sensor 2002 is connected to a main body of the robot via the lift 2004. The height of the sensor 2002 can be adjusted by the lift 2004. The lift 2004 is preferably telescopic. Alternatively, the lift 2004 may be a foldable lift composed of a plurality of booms. The robot 2000, which is provided with the driver portion 2005 and the moving mechanism 2011 connected to the driver portion 2005, is preferable because an imaging range of the sensor 2002, that is, a monitoring range, is expanded.

The communication means 2006 can send data taken by the sensor 2002 to a manager or the server owned by the manager. In addition, when the occurrence of an emergency such as a crime, an accident, or a fire is judged after the arithmetic device 2001 analyzes the data taken by the sensor 2002, the communication means 2006 can report to the security company, the police, the fire station, the medical institution, or the owner of the land or the building. The speaker 2007 can transmit information such as an alert to a criminal, a call to an injured person or an emergency patient, and evacuation guidance, to the surroundings of the robot. The microphone 2008 can be used to obtain sounds around the robot 2000. The use of the communication means 2006 and the speaker 2007 enables the robot 2000 to function as a telephone. A person around the robot 2000 can have a conversation with the manager or a given person. The display portion 2009 can display given data. In emergency, the disaster information and the evacuation route can be displayed. The use in combination with the communication means 2006, the speaker 2007, and the microphone 2008 enables the robot 2000 to function as the videophone. A person around the robot 2000 can have a conversation with the manager or a given person while seeing the display portion 2009.

The light-emitting portion 2010 emits light or displays characters to show the direction of movement and the stopped state of the robot 2000. In addition, emergency may also be shown.

FIG. 32(B) is a block diagram illustrating a configuration of the robot 2000. The arithmetic device 2001 adjusts turning on or off and the brightness of the light 2003 from data such as an image obtained by the sensor 2002. In addition, the height of the lift 2004 is adjusted or the driver portion 2005 is controlled to align the positions of the robot 2000 and the sensor 2002.

The operating condition of the driver portion 2005 can be shown by using the light-emitting portion 2010. With the communication means 2006, information around the robot 2000 obtained from the sensor 2002 and the microphone 2008 can be transmitted to the manager or the server owned by the manager. Depending on the judgement of the arithmetic device 2001 or the manager, information can be sent to the surroundings of the robot 2000 with the speaker 2007 and the display portion 2009.

In the case where a sensor that can take an image even in dark surroundings is used as a sensor used as the sensor 2002, the light 2003 is not necessarily provided. As such a sensor, an image sensor using selenium (Se) in the light receiving portion can be used.

Such a robot 2000 can be used in commercial facilities and for security of the office. Data obtained from the sensor 2002 and the microphone 2008 is stored in the arithmetic device 2001 or the server. The stored data is analyzed by an AI system to check whether there is an anomaly situation such as loss or damage of an object, entry of suspicious individual, or disaster such as a fire. For the data analysis, deep learning may be used. When there is an anomaly situation, the robot 2000 reports to the manager and transmits information to the surroundings, and records the conditions of the surroundings.

The robot 2000 may be used for monitoring the growing conditions of the crops. The robot 2000 placed in a rice field or a field monitors the shapes, the sizes, or the colors of leaves or fruit of the crops by the sensor 2002 to check whether the crops are damaged or not or whether the crops are harmed by pests or not. Since the moving mechanism 2011 is provided for the robot 2000, the growing conditions of the crops can be monitored in a wide range. In addition, since the robot 2000 is provided with the lift 2004, the leaves and fruit at a certain height can be monitored regardless of the kind of crops and the growing conditions. The monitoring results are transmitted to a grower using the communication means 2006, and the grower can determine the kind, the amount, and the spraying timing of fertilizer and agricultural chemicals necessary for the crops. Alternatively, the monitoring results may be analyzed with an AI system using the arithmetic device 2001, and the kind, the amount, and the spraying timing of fertilizer and agricultural chemicals necessary for the crops may be determined and reported to the grower. Deep learning may be used for analysis of the monitoring results.

FIG. 33(A) illustrates a sorting system 3000 using a robot 3001. The robot 3001 includes an arithmetic device 3002, a boom 3003, and an arm 3004. The robot 3001 may further include a wired or wireless communication means 3011. In addition, the sorting system 3000 includes a housing 3008 including a sensor 3009. The housing 3008 includes a communication means 3010. The housing 3008 is provided for a ceiling, a wall, or a beam (not illustrated) of the sorting system 3000 or a sorting operation area. The housing 3008 may be provided in the robot 3001. For example, the housing 3008 may be provided for the boom 3003 or the arm 3004. In the case where the housing 3008 is provided in the robot 3001, data obtained by the sensor 3009 may be transmitted to the arithmetic device 3002 without passing through the communication means 3010 and the communication means 3011, and processed.

The boom 3003 is movable, and the arm 3004 can be placed at a desired position. The arm 3004 may be telescopic. After the arm placed over a desired object 3007 is stretched to grab the desired object 3007 and the arm 3004 is shortened, the arm 3004 may be moved by the boom 3003.

The sorting system 3000 can transfer the object 3007 in a container 3005 to a container 3006. The container 3005 and the container 3006 may have the same shape or different shapes. Furthermore, a plurality of objects 3007 put in one container 3005 may be sorted and moved to a plurality of containers 3006.

As the container 3005 and the container 3006, a container, a cardboard box, a box for packing a product, a case, a film, a bag, a tray for storing foods, a lunch box, or the like is used. Furthermore, at least one of the container 3005 and the container 3006 may be cooking utensils such as a pot or a frying pan.

In the arithmetic device 3002, the semiconductor device of one embodiment of the present invention can be used. As the arithmetic device 3002, an IC in which the AI system of one embodiment of the present invention is incorporated can be used.

The sensor 3009 reads the positions of containers 3005, the positions of containers 3006, the state of the inside of the container 3005, and the state of the object 3007 in the container 3005 and transmits the data to the arithmetic device 3002 using the communication means 3010. Transmission of data is performed with or without a wire. Alternatively, the data may be transmitted through a wire without the communication means 3010. The arithmetic device 3002 analyzes the transmitted data. Here, the state of the object 3007 indicates the shape or the number of objects 3007, the overlap between the objects 3007, or the like. The arithmetic device 3002 performs analyzation on the basis of information from the sensor 3009 and obtains detailed information of the object 3007. The three-dimensional shape and hardness (or softness) of the object 3007 are obtained by comparison with the data stored in the arithmetic device 3002 or the server that can be communicated with the robot 3001. Depending on the three-dimensional shape and hardness (or softness) of the object 3007, the shape of the arm 3004 can be changed.

To obtain the detailed data of the object 3007, analysis using an AI system can be utilized. For the data analysis, deep learning may be used.

FIG. 33(B) illustrates an arm in which a pair of plates 3021 can move in the horizontal direction to pick up the object 3007. The pair of plates 3021 moves toward the center horizontally, whereby the object 3007 can be picked up. Such an arm can hold the object 3007 by the surfaces, and is suitable for picking up the object 3007 with a columnar shape, such as a cube or a rectangular solid. FIG. 33(C) is an arm in which a plurality of bars 3022 can move in the horizontal direction to pick up the object 3007. The plurality of bars 3022 move toward the center horizontally, whereby the object 3007 can be picked up. Such an arm can pinch the object 3007 by the points, and is suitable for picking up the object 3007 in a spherical shape or in a non-fixed shape, that is, the object 3007 in an irregular shape. Note that although the number of bars 3022 is four in FIG. 33(C), this embodiment is not limited thereto. The number of bars 3022 may be three or five or more. FIG. 33(D) illustrates an arm in which a pair of plates 3023 rotates around the common axis to be closer to each other to pick up the object 3007. Such an arm can hold the object 3007 by the surfaces, and is suitable for picking up the object 3007 with a thin-film shape, such as paper or films. FIG. 33(E) is an arm in which a pair of crook-shaped plates 3024 rotates around the common axis such that the ends of them are closer to each other to pick up the object 3007. Such an arm can pinch the object 3007 by the points or the sides, and is suitable for picking up the object 3007 with a thin-film shape, such as paper or films, or the object 3007 with a finer-grained shape. As illustrated in FIG. 33(F), a spatula 3025 may be attached to the tip of the arm, and the object 3007 with a finer-grained shape may be scooped.

The arms illustrated in FIGS. 33(A) to 33(F) are just examples and one embodiment of the present invention is not limited to these shapes. In addition, the application of the arms is just an example and one embodiment of the present invention is not limited thereto.

The robot 3001 moves the boom 3003 to move the arm 3004 to a position over the desired object 3007 in the container 3005. In the case of using the telescopic arm 3004, the arm 3004 is stretched, and the tip of the arm 3004 is brought down to a position on the level of the object 3007. The tip of the arm is moved to catch the desired object 3007. The arm is shortened while catching the object 3007. The boom 3003 is moved again to transfer the arm 3004 to the desired position in the container 3006. The arm 3004 is stretched to place the object 3007 in the container 3006, and the arm 3004 releases the object 3007. The above operation is repeated, so that the object 3007 can be moved from the container 3005 to the container 3006.

Since the positional information on the container 3005 and the container 3006 and the state of the object 3007 are analyzed using the AI system, the object 3007 can be moved surely regardless of the shape or hardness of the object 3007. Examples of the object 3007 include not only an object packed in a box with a shape of a cube or a rectangular solid but also shaped processed foods such as egg, hamburger steak, and croquettes, vegetables with an irregular shape such as a potato and a tomato, machine parts such as a screw and a nut, a thin film of a paper or a film, and the like. Since in the sorting system 3000 described in this embodiment, the shape of the arm can be changed in consideration of the shape and the hardness of the object 3007, the objects 3007 given above as examples can be transferred from the container 3005 to the container 3006 regardless of the shape and the hardness.

For example, a memory device using the semiconductor device of one embodiment of the present invention can retain control data, a control program, or the like of the above-described electronic device for a long time. With the use of the semiconductor device of one embodiment of the present invention, a highly reliable electronic device can be achieved.

An IC in which the above AI system is incorporated can be used for the arithmetic device or the like of the above-described electronic device, for example. Accordingly, the electronic device of this embodiment can perform optimal operations depending on circumstances with low power consumption by utilizing the AI system.

This embodiment can be implemented in an appropriate combination with the structures described in the other embodiments, examples, and the like.

### Example 1

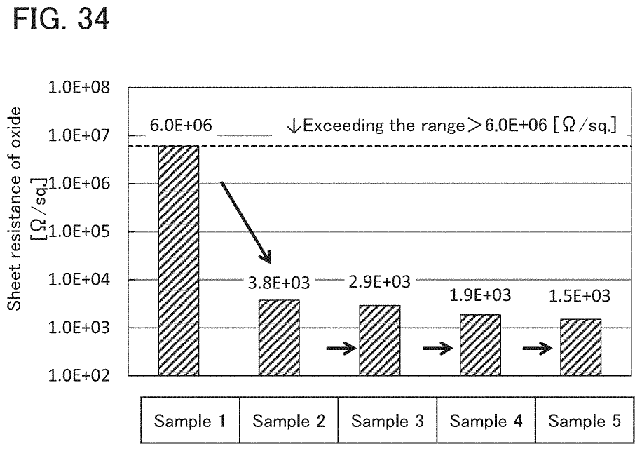

In this example, a change in the sheet resistance of an oxide when a metal compound was formed over the oxide was measured. A sheet resistance measurer whose measurement upper limit was 6.0×10⁶ Ω/sq was used. The change in the sheet resistance of the oxide is shown in FIG. 34. Samples used for evaluating the change in the sheet resistance will be described below.

A method for fabricating Sample 1 will be described. A surface of a substrate containing silicon was subjected to heat treatment in a hydrogen chloride (HCl) atmosphere, and a 100-nm-thick silicon oxide film was formed over the substrate. Next, over the silicon oxide film, a 5-nm-thick oxide was formed using a target with In:Ga:Zn=1:3:4 [atomic ratio] and further a 15-nm-thick oxide was formed using a target with In:Ga:Zn=4:2:4.1 [atomic ratio] by a sputtering method. Next, the formed oxide was subjected to heat treatment in a nitrogen atmosphere at 400° C. for one hour and then successively subjected to another heat treatment in an oxygen atmosphere at 400° C. for one hour. It was observed that the sheet resistance of the oxide in Sample 1 exceeded the range; the sheet resistance of the oxide was higher than 6.0×10⁶ Ω/sq.

Next, a method for fabricating Sample 2 will be described. As in Sample 1, the silicon oxide film and the oxide were formed over the substrate and the heat treatment was performed. After the heat treatment, a 2-nm-thick metal compound was formed over the oxide in an atmosphere containing nitrogen, using a target with Ti:Al=1:1 [atomic ratio], by a sputtering method. The obtained metal compound contained titanium, aluminum, and nitrogen and thus can be represented by TiAlNₓ or TiAlₓA_{y} (x and y are any numbers). The sheet resistance of the oxide in Sample 2 was observed to be 3.8×10³ Ω/sq. The metal compound was formed over the oxide, whereby the sheet resistance value of the oxide was reduced.

Next, a method for fabricating Sample 3 will be described. As in Sample 2, the silicon oxide film and the oxide were formed over the substrate and the heat treatment was performed. After the heat treatment, a metal compound was formed over the oxide. After the formation of the metal compound, heat treatment was performed in a nitrogen atmosphere at 400° C. for one hour. The sheet resistance of the oxide in Sample 3 was observed to be 2.9×10³ Ω/sq. Although there is almost no change in the sheet resistance value of the oxide, which was reduced by the formation of the metal compound, the sheet resistance value of the oxide in Sample 3 was reduced as compared with that in Sample 2.

Next, a method for fabricating Sample 4 will be described. As in Sample 3, the silicon oxide film and the oxide were formed over the substrate and the heat treatment was performed. After the heat treatment, a metal compound was formed over the oxide. After the formation of the metal compound, heat treatment was performed. After the heat treatment, a 20-nm-thick aluminum oxide was formed in an atmosphere containing argon and oxygen, using a target containing aluminum oxide (Al₂O₃), by a sputtering method. It is presumable that oxygen (excess oxygen) is supplied to the oxide by the formation of the aluminum oxide. Here, in some cases, the supply of oxygen to the oxide increases the resistance value of the oxide and thus the oxide gets close to an i-type semiconductor. The sheet resistance of the oxide in Sample 4 was observed to be 1.9×10³ Ω/sq. Note that in Sample 4, the sheet resistance of the oxide was observed after the removal of the aluminum oxide. There was no increase in the sheet resistance value by the formation of the aluminum oxide in the oxide whose sheet resistance value was reduced by the formation of the metal compound, and the sheet resistance value of the oxide in Sample 4 was reduced as compared with that in Sample 3.

Next, a method for fabricating Sample 5 will be described. As in Sample 4, the silicon oxide film and the oxide were formed over the substrate and the heat treatment was performed. After the heat treatment, a metal compound was formed over the oxide. After the formation of the metal compound, heat treatment was performed. After the heat treatment, aluminum oxide was formed. After the formation of the aluminum oxide, heat treatment in a nitrogen atmosphere at 400° C. for one hour and then successively another heat treatment in an oxygen atmosphere at 400° C. for one hour were performed. It is presumable that oxygen contained in the aluminum oxide diffuses to the oxide by the heat treatment. The sheet resistance of the oxide in Sample 5 was observed to be 1.5×10³ Ω/sq. Note that in Sample 5, the sheet resistance of the oxide was observed after the removal of the aluminum oxide. There was no increase in the sheet resistance value by the formation of the aluminum oxide and the heat treatment in the oxide whose sheet resistance value was reduced by the formation of the metal compound. The sheet resistance value of the oxide in Sample 5 was reduced as compared with those in Sample 3 and Sample 4.

This example can be implemented in an appropriate combination with the structures described in the other embodiments and the like.

### Example 2

In this example, an interface between an oxide and a layer containing a metal element provided thereover was evaluated. For the evaluation, the following samples were used: Sample 6 in which a layer containing a metal element is formed over an oxide and Sample 7 in which heat treatment was performed in a nitrogen atmosphere after the layer containing a metal element was formed over the oxide as in Sample 6.

A method for fabricating Sample 6 will be described. As the oxide, a 50-nm-thick oxide was formed over a substrate, using a target with In:Ga:Zn=4:2:4.1 [atomic ratio], by a sputtering method. Next, the formed oxide was subjected to heat treatment in a nitrogen atmosphere at 400° C. for one hour and then successively subjected to another heat treatment in an oxygen atmosphere at 400° C. for one hour. After the heat treatment, as the layer containing a metal element, a 20-nm-thick layer containing a metal element was formed over the oxide in an atmosphere containing nitrogen, using a target with Ti:Al=1:1 [atomic ratio], by a sputtering method. The obtained layer containing a metal element contained titanium, aluminum, and nitrogen and thus can be represented by TiAlNₓ or TiAlₓA_{y} (x and y are any numbers).

Next, a method for fabricating Sample 7 will be described. As the oxide, a 50-nm-thick oxide was formed over a substrate, using a target with In:Ga:Zn=4:2:4.1 [atomic ratio], by a sputtering method. Next, the formed oxide was subjected to heat treatment in a nitrogen atmosphere at 400° C. for one hour and then successively subjected to another heat treatment in an oxygen atmosphere at 400° C. for one hour. After the heat treatment, as the layer containing a metal element, a 20-nm-thick layer containing a metal element was formed over the oxide in an atmosphere containing nitrogen, using a target with Ti:Al=1:1 [atomic ratio], by a sputtering method. The obtained layer containing a metal element contained titanium, aluminum, and nitrogen and thus can be represented by TiAlNₓ or TiAlₓN_{y}. After the formation of the layer containing a metal element, heat treatment was performed in a nitrogen atmosphere at 400° C. for one hour.

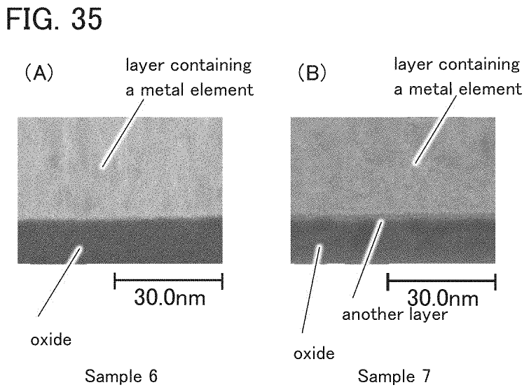

A cross section of the interface between the oxide and the layer containing a metal element of each of Sample 6 and Sample 7 was observed. Note that the cross-sectional observation was performed with a scanning transmission electron microscope (STEM). As an apparatus for the observation, HD-2700 manufactured by Hitachi High-Technologies Corporation was used. FIG. 35(A) shows the cross-sectional STEM observation result of Sample 6. FIG. 35(B) shows the cross-sectional STEM observation result of Sample 7.

It was observed that a compound layer (another layer) was formed between the oxide and the layer containing a metal element in FIG. 35(B) from the comparison with FIG. 35(A). This was presumably formed by the heat treatment after the formation of the layer containing a metal element.

This example can be implemented in an appropriate combination with the structures described in the other embodiments and the like.

### REFERENCE NUMERALS

100: capacitor, 110: conductor, 120: conductor, 130: insulator, 200: transistor, 203: conductor, 203a: conductor, 203b: conductor, 205: conductor, 207: conductor, 208: insulator, 210: insulator, 212: insulator, 214: insulator, 216: insulator, 220: insulator, 222: insulator, 224: insulator, 230: oxide, 230a: oxide, 230A: oxide film, 230b: oxide, 230B: oxide film, 230c: oxide, 230C: oxide film, 230d: oxide, 230D: oxide film, 231: region, 231a: region, 231b: region, 239: dashed line, 240: dashed line, 250: insulator, 250A: insulating film, 252: conductor, 252a: conductor, 252b: conductor, 252c: conductor, 252d: conductor, 256: conductor, 260: conductor, 260a: conductor, 260A: conductive film, 260b: conductor, 260B: conductive film, 270: barrier layer, 276: barrier layer, 280: insulator, 282: insulator, 282a: insulator, 282b: insulator, 285: layer, 285A: film, 286: insulator, 287: insulator, 286: insulator, 289: barrier layer, 290: compound layer, 300: transistor, 311: substrate, 313, semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 360: insulator, 362: insulator, 364: insulator, 366: conductor, 370: insulator, 372: insulator, 374: insulator, 376: conductor, 380: insulator, 382: insulator, 384: insulator, 386: conductor, 400: transistor, 403: conductor, 405: conductor, 430c: oxide, 430d: oxide, 431a: oxide, 431b: oxide, 432a: oxide, 432b: oxide, 433: low-resistance region, 434: low-resistance region, 450: insulator, 460: conductor, 460a: conductor, 460b: conductor, 470: insulator, 500, opening, 650a: memory cell, 650b: memory cell, 1001: wiring, 1002: wiring, 1003: wiring, 1004: wiring, 1005: wiring, 1006: wiring, 1007: wiring, 1008: wiring, 1009: wiring, 1010: wiring, 1400: DOSRAM, 1405: controller, 1410: row circuit, 1411: decoder, 1412: word line driver circuit, 1413: column selector, 1414: sense amplifier driver circuit, 1415: column circuit, 1416: global sense amplifier array, 1417: input/output circuit, 1420: sense amplifier array, 1422: memory cell array, 1423: sense amplifier array, 1425: local memory cell array, 1426: local sense amplifier array, 1444: switch array, 1445: memory cell, 1445a: memory cell, 1445b: memory cell, 1446: sense amplifier, 1447: global sense amplifier, 1600: NOSRAM, 1610: memory cell array, 1611: memory cell, 1612: memory cell, 1613: memory cell, 1614: memory cell, 1615: memory cell, 1615a: memory cell, 1615b: memory cell, 1640: controller, 1650: row driver, 1651: row decoder, 1652: word line driver, 1660: column driver, 1661: column decoder, 1662: driver, 1663: DAC, 1670: output driver, 1671: selector, 1672: ADC, 1673: output buffer, 2000: robot, 2001: arithmetic device, 2002: sensor, 2003: light, 2004: lift, 2005: driver portion, 2006: communication means, 2007: speaker, 2008: microphone, 2009: display portion, 2010: light-emitting portion, 2011: moving mechanism, 3000: system, 3001: robot, 3002: arithmetic device, 3003: boom, 3004: arm, 3005: container, 3006: container, 3007: object, 3008: housing, 3009: sensor, 3010: communication means, 3011: communication means, 3021: plate, 3022: bar, 3023: plate, 3024: plate, 3025: spatula, 3110: OS-FPGA, 3111: controller, 3112: word driver, 3113: data driver, 3115: programmable area, 3117: JOB, 3119: core, 3120: LAB, 3121: PLE, 3123: LUT block, 3124: register block, 3125: selector, 3126: CM, 3127: power switch, 3128: CM, 3130: SAB, 3131: SB, 3133: PRS, 3135: CM, 3137: memory circuit, 3137B: memory circuit, 3140: OS-FF, 3141: FF, 3142: shadow register, 3143: memory circuit, 3143B: memory circuit, 3188: inverter circuit, 3189: inverter circuit, 4010: arithmetic portion, 4011: analog arithmetic circuit, 4012: DOSRAM, 4013: NOSRAM, 4014: FPGA, 4020: control portion, 4021: CPU, 4022: GPU, 4023: PLL, 4025: PROM, 4026: memory controller, 4027: power supply circuit, 4028: PMU, 4030: input/output portion, 4031: external memory control circuit, 4032: audio codec, 4033: video codec, 4034: general-purpose input/output module, 4035: communication module, 4041: AI system, 4041_n: AI system, 4041_1: AI system, 4041A: AI system, 4041B: AI system, 4098: bus line, 4099: network, 7000: AI system IC, 7001: lead, 7003: circuit portion, 7031: Si transistor layer, 7032: wiring layer, 7033: OS transistor layer

1. A semiconductor device comprising a transistor, the transistor comprising:
a first oxide;
a second oxide over the first oxide;
an insulator over the second oxide; and
a conductor over the insulator,
wherein the first oxide comprises a channel formation region and a first region and a second region positioned so that the channel formation region is sandwiched therebetween,
wherein the second oxide is provided so as to be in contact with the channel formation region, part of the first region, and part of the second region, and
wherein the first region and the second region have lower concentrations of oxygen than the channel formation region.

2.-15. (canceled)

16. The semiconductor device according to claim 1, wherein the first oxide comprises In, an element M (M is Al, Ga, Y, or Sn), and Zn.

17. The semiconductor device according to claim 16, wherein, in the first oxide, a proportion of the number of atoms of In is higher than the element M in an atomic ratio.

18. The semiconductor device according to claim 1, wherein the first region and the second region each comprise at least one of aluminum, ruthenium, titanium, tantalum, chromium, and tungsten.

19. The semiconductor device according to claim 1, wherein the first region and the second region each further comprise nitrogen.

20. The semiconductor device according to claim 1, wherein the channel formation region has a lower concentration of hydrogen than the first region and the second region.

21. The semiconductor device according to claim 1, wherein the transistor is a normally-off transistor.

22. A semiconductor device comprising a transistor, a first insulator covering the transistor, and a first conductor and a second conductor electrically connected to the transistor, the transistor comprising:
a first oxide;
a first layer and a second layer each containing a metal element and oxygen over the first oxide;
a second oxide over the first oxide, the first layer, and the second layer;
a second insulator over the second oxide; and
a third conductor over the second insulator,
wherein the first oxide comprises a channel formation region and a first region and a second region positioned so that the channel formation region is sandwiched therebetween,
wherein the first region is provided so as to be in contact with the first layer,
wherein the second region is provided so as to be in contact with the second layer,
wherein the second oxide is provided so as to be in contact with the channel formation region, part of the first layer, and part of the second layer,
wherein the first insulator and the first layer comprise a first opening exposing the first region,
wherein the first conductor is provided in the first opening and electrically connected to the first region,
wherein the first insulator and the second layer comprise a second opening exposing the second region,
wherein the second conductor is provided in the second opening and electrically connected to the second region, and
wherein the first region and the second region have lower concentrations of oxygen than the channel formation region.

23. The semiconductor device according to claim 22, wherein the metal element comprises at least one of aluminum, ruthenium, titanium, tantalum, chromium, and tungsten.

24. The semiconductor device according to claim 22, wherein the first layer and the second layer each further comprise nitrogen.

25. The semiconductor device according to claim 22, wherein film thicknesses of the first layer and the second layer are each greater than or equal to 0.5 nm and less than 5 nm.

26. The semiconductor device according to claim 22, wherein the first oxide comprises In, an element M (M is Al, Ga, Y, or Sn), and Zn.

27. The semiconductor device according to claim 26, wherein, in the first oxide, a proportion of the number of atoms of In is higher than the element M in an atomic ratio.

28. The semiconductor device according to claim 22, wherein the first region and the second region each comprise at least one of aluminum, ruthenium, titanium, tantalum, chromium, and tungsten.

29. The semiconductor device according to claim 22, wherein the first region and the second region each further comprise nitrogen.

30. The semiconductor device according to claim 22, wherein the channel formation region has a lower concentration of hydrogen than the first region and the second region.

31. The semiconductor device according to claim 22, wherein the transistor is a normally-off transistor.

32. A method for manufacturing a semiconductor device, comprising the steps of:
forming a first layer containing a metal element over a first oxide;
processing the first oxide into an island shape using the first layer as a mask;
processing the first layer over the first oxide which is processed into the island shape to expose a first region of the first oxide and form a second layer over a second region of the first oxide and a third layer over a third region of the first oxide;
performing first heat treatment at least on the first oxide, the second layer, and the third layer in an atmosphere containing nitrogen to extract oxygen contained in the second region to the second layer and extract oxygen contained in the third region to the third layer;
forming a second oxide over the first oxide;
forming an insulator over the second oxide; and
forming a conductor over the insulator.

33. The method for manufacturing a semiconductor device according to claim 32, wherein the first layer is formed by a sputtering method, using one or both of argon and nitrogen.

34. The method for manufacturing a semiconductor device, according to claim 32, wherein the first layer and the second layer are removed after the first heat treatment.

35. The method for manufacturing a semiconductor device, according to claim 32, wherein second heat treatment is further performed after the first heat treatment.
